(19) United States
(12) Patent Application Publication
(10) Pub. No.: US 2024/0402233 A1
(43) Pub. Date: Dec. 5, 2024

(54) CABLE MONITORING APPARATUS AND METHOD

(71) Applicant: C-KORE SYSTEMS LIMITED, York (GB)

(72) Inventors: Timothy Mark OVERFIELD, York (GB); Gregory James SMITH, York (GB)

(21) Appl. No.: 18/691,137

(22) PCT Filed: Sep. 13, 2022
(86) PCT No.: PCT/GB2022/052311

§ 371 Date: Mar. 12, 2024

(30) Foreign Application Priority Data
Sep. 14, 2021 (GB) 2113129.7

(51) Int. Cl. G01R 31/08; G01K 11/3206; G01L 1/24; G01R 1/04; G01R 31/11; G01R 31/58; G02B 6/50; H01B 11/22; H02G 1/10; H02G 9/00

(52) U.S. Cl. CPC G01R 31/083; G01K 11/3206; G01L 1/246; G01R 1/04; G01R 31/11; G01R 31/58; G02B 6/506; H01B 11/22; H02G 1/10; H02G 9/00

(57) ABSTRACT

A measurement apparatus is disclosed for connection to an end of a cable (1) having at least one of: at least one electrically conductive core (11) for carrying electrical current and/or electrical signals along the cable; at least one electromagnetic waveguide (12) for carrying electromagnetic signals along the cable; and at least one bore (13) for conveying a fluid along the cable. The measurement apparatus comprises: connection means (4) for connecting to the end in an above-water or out-of-water environment to make at least one of: at least one respective electrical connection (41) to at least one core, at least one respective waveguide connection (42) to at least one waveguide for sending an electromagnetic signal along the waveguide, and at least one respective fluid or hydraulic connection (43) to at least one bore; and measuring means (5) connected to the connection means and operable to perform at least one measurement, via the connection means, on a connected cable. The measurement apparatus is deployable, when connected to an end of the cable, with the cable end to an underwater location for a period of time, and recoverable with the connected cable end after the period of time to an above-water or out-of-water location. The measuring means is operable to perform the measurement(s) while the measurement apparatus is connected to the cable end and at least while submerged with the connected cable end and/or after recovery with the connected cable end from the underwater location to the above-water or out-of-water location.

### FIELD OF THE INVENTION

Certain aspects of the present invention relate to interconnecting cables for renewable energy generation systems and other apparatus and the testing of such apparatus, and in particular, although not exclusively, to the testing of interconnecting apparatus for providing electrical, optical, and/or fluid connection between one piece of apparatus or equipment and another that may or may not be in a subsea environment.

Certain aspects relate to measurement apparatus for connection to cables, and operable underwater to perform measurements on the attached cables.

Certain aspects of the present invention relate in particular, although not exclusively, to a pulling head for attachment to, and pulling of, a cable, such as a cable for attaching to off-shore power generation apparatus, or a sub-sea umbilical.

### BACKGROUND TO THE INVENTION

Offshore infrastructure (for example wind generation turbines and associated structures, tidal power generation systems and/or wave power generation systems, and oil and gas production platforms and related components) typically requires interconnection, that interconnection being provided often in the form of a physical cable. Such infrastructure may be provided on the surface or underwater, or a combination of both, and/or may be installed into, or onto, the seabed or lake bottom. It may be secured from the seabed or lake bottom, or can be floating on the sea or lake surface. Underwater infrastructure may be termed “sub-sea”, which is a well-known term used to refer to equipment, methods and technology used at underwater locations, and particularly at locations on or close to the seabed for various applications. The ocean floor or seabed at which subsea equipment is used may be at a relatively shallow location (shallow in this context being at depths less than 300 m) or at a deep water location (generally meaning water depths in the range 300 to 3000 m, or deeper).

The interconnection required for the particular application can be between two elements, such as the infrastructure and a vessel (e.g. the vessel laying a cable), the infrastructure and the shore, or the infrastructure and another element of infrastructure. The interconnection cable may comprises some or all of the following: one or more electrical cores insulated from each other, for carrying electrical current and/or electrical signals along the cable; one or more optical fibres isolated from each other with suitable sheathing, for carrying optical signals; and one or more conduits, hoses, pipes, or tubes with bores for carrying fluids or gases.

A highly schematic cross section of an interconnection cable 1 suitable for use with embodiments of the invention is shown in FIG. 1. An inner portion P of the cable comprises a plurality of cables adapted to carry three phases of high current generated by a wind turbine (or other power generation means). Each of those cables comprises a conductive core 11a, 11b, 11c for carrying the current, surrounded by a respective layer of insulation 111. The inner portion P of the cable further comprises a pair of signal carrying wires, again, each having a respective conductive core 11d. 11e surrounded by a respective insulating sheath or outer layer 111. The inner portion P also comprises a waveguide in the form of an optical fibre cable having a core 12 comprising a plurality of optical fibres surrounded by a sheath 121. The inner portion P also comprises a pipe or tube 131, having a bore 13 for carrying a fluid along the length of the cable. Surrounding the inner portion there P is provided an armour layer 14 comprising a plurality of high strength metal wires 141 arranged to provide strength to the cable and protection to the components in the inner portion. Surrounding the armour layer 14 is an outer jacket 10, arrange to provide further strength to the cable and provide further protection. It will be appreciated that the cable may comprise further material 15 arranged to fill in the space around the labelled components. Again, the figure is highly schematic and is presented merely to illustrate the typical components of a cable to which the present invention relates.

A term commonly used to refer to one type of such an interconnection cable is “umbilical”. Such an umbilical (or other such interconnection cable) may be conveyed to an underwater (sub-sea) location, (which is termed “deploying”), and then connected to infrastructure, or may be required to remain at that location for some time before it is installed (i.e. connected to another piece of subsea or surface equipment). In general, the interconnection cable is deployed in a process that places one end at a first point, at or near the first element (such as a first infrastructure, the vessel, or shore), and the cable is then progressively deployed from that first point to a second point, at or near the second element (such as a second infrastructure, a vessel, or shore). The interconnection cable is generally deployed from a cable lay vessel which may contain/carry one or more lengths of the interconnection cable. The cable lay vessel may carry a single pre-cut length of cable for a particular application (e.g. for a long interconnection, such as from infrastructure to shore), a long continuous length of cable from which a suitable length is cut as it is deployed into position, or several individual lengths pre-cut to suit an intended sequence of deployments. The cable may be spooled onto the vessel at or near to the cable manufacturing plant, or may be supplied pre-spooled. Before deployment, the cut ends of the cable are typically installed into an arrangement that protects the end of the cable from seawater and also incorporates a means to assist the handling of the cable during deployment and subsequently. This arrangement is commonly called a pulling head, pull-in head, or pull head. Once the cut ends are encapsulated in this way (in a pulling head, or other encapsulation), access to the internal components of the cable is no longer possible; in other words, it is not possible to perform test measurements on the conductors, optical fibres, or fluid-conveying bores.

Pulling heads are known in a variety of designs, typically dependent on the cable (line) being installed. For example, a pulling head for an oil flow line may be dramatically different to one pulling a 33 kV Interfield umbilical. A pulling head interface to the cable may be either rigid or flexible. One known pulling head 2, shown in highly schematic form in FIG. 2, comprises a pulling eye arrangement (comprising pulling member 6, having an eye 62 extending through it), to which pulling tension is applied for positioning, connected to the cable via a rigid arrangement, such as a metal tube 200, the end of which constrains an end portion 100 of the cable 1 and contains a mechanical arrangement (not shown in the figure) to lock the cable into the tube. The space within the rigid arrangement can be utilised to protect the end of the cable. With a flexible interface pulling head, there may be provided a flexible tube, strong enough to transfer the pulling force from the pulling eye to the cable, between the pulling eye and a mechanical arrangement that locks the cable to the pulling head.

The encapsulated ends of the cable are then typically pulled into the intended infrastructure by means of a cable or rope attached (coupled) to the interconnection cable via the pulling head (e.g. attached pulling eye) or similar. The cable or rope can then be used to pull in the interconnection cable by means of a winch or similar (or indeed any suitable apparatus able to provide the necessary pulling force).

During the above-described deployment process, the cable will typically be subject to external forces that are planned to be within the specification of the cable. However, in some circumstances the deployment forces could exceed the cable specification, which may result in damage. This damage may not cause symptoms or failure noticeable until sometime after deployment and/or the interconnection cable is put into use. Thus, it is possible that the cable could be subject to damage at any point between manufacture, spooling, un-spooling, storage (at any location, including sub-sea locations), deployment, and/or connection into the infrastructure. Furthermore, the cable may have a latent manufacturing defect that is not problematic until it is exposed to water/pressure.

A particular problem is that electrical cores may be damaged or degraded, especially those for high current/high power applications such as those for conveying wind or tidal-generated power between infrastructure elements, or from such elements to shore (where the lengths of cables involved are considerable, ranging from 100s to 1000s of metres), Local damage to the current carrying cores, such as damage resulting from locally high strain during the pulling/deployment process, often across potentially problematic uneven and/or debris-strewn sub-sea surfaces, may render the cable unusable, but in the past this would only have become apparent after the cable had been installed (i.e. with connections made to each end at the respective pieces of infrastructure), and after the cable-laying vessel had gone (e.g. to be deployed elsewhere).

Thus, a particular problem with cables for offshore power generation, which are typically long and required to carry high currents, is that any damage or reduction in performance or capability resulting from handling (especially, but not exclusively, the pulling of the cable prior to installation) of the cable may not be detected until the cable is installed and connected.

As further background, offshore wind farms are a well-known form of renewable energy system and are formed by a collection of one or more wind turbines that may be interconnected in some manner. The energy generated is typically conveyed to shore via a cable system. This also applies to other forms of renewable energy systems, such as wave or tidal powered systems. The wind turbines can be installed into the seabed bed or alternatively may be floating, tethered in place by lines. In larger installations the individual turbines (or smaller groups of turbines) may be connected to a central hub that converts the electrical energy generated to a higher voltage more suitable for transmitting longer distances. Consequently, there is typically a complex array of interconnection cables that must be installed and connected to the turbines and other apparatus in a way that ensures mechanical and electrical integrity is maintained. These cables may be configured to enable power transmission, and/or to enable data transmission, for example for control purposes. Thus, the cables may be related to power transmission, and/or to data transmission, for example for control.

There may be some period between the manufacture of the cable(s), transport to the site, deployment to the seabed, pull-in (recovery), and connection to the turbine(s) and/or apparatus and final connection. The present inventors have determined that, during some or all of this period, it would be advantageous to monitor the cable's mechanical and/or electrical integrity, and/or the conditions to which the cable is exposed so that any events that might cause failure in the short or longer term are detected.

Currently, cables are typically delivered to site wound as a continuous length on a large spool (drum or reel) and are then cut to the length required on site, sealed, and deployed with no monitoring. Recently however, there have been rising levels of cable failures that are expensive to resolve and/or replace. The present inventors' experience in the oil and gas industry suggests that in-field terminations have a high rate of failure compared to terminations made under ideal conditions within the suppliers' premises.

With this in mind, the present inventors have determined that it may be desirable to supply interconnection cables with factory installed terminations. These terminations may take the form of connectors that can withstand immersion in considerable water depth but which are mated in in the dry environment within the wind turbine (or other related apparatus).

Use of pre-installed dry-mate interconnections may provide the advantages of better reliability, faster installation, and less need for skilled personnel in a marine environment. The nature of a dry mate interconnection (or termination or connector) makes it easier to temporarily install monitoring equipment at any stage of the cable's journey from supplier to turbine. One aspect of the present invention provides monitoring equipment for attachment to the end of a cable with dry-mate connectors, and may take the form of a protective cap or dummy connector fitted to the end of the cable and may be removed at a suitable point (e.g. in a dry environment, prior to connecting the cable to other apparatus).

### SUMMARY OF THE INVENTION

Certain embodiments of the invention aim to address one or more of the problems associated with the prior art.

It is an object of certain embodiments of the invention to provide a pulling head, having means to perform at least one measurement (i.e. testing) on the attached cable while it is being pulled, spooled, or un-spooled, or after a period of storage, such that faults, damage, and/or degradation can be identified early, and before the pulled end of the cable has been installed.

A first aspect of the invention provides a pulling head (2) for attachment to, and pulling of, a cable (1) (e.g. an umbilical, sub-sea umbilical, pipe, tube, rope, hawser, interconnector, or other such elongate member) having at least one of: an electrically conductive core (11) (e.g. an electrical conductor/wire/cable or bunch of electrical conductors/wires/cables) for carrying electrical current and/or electrical signals along the cable; an electromagnetic waveguide (12) (e.g. an optical fibre/cable or bundle of fibres/cables) for carrying electromagnetic signals along the cable; and a bore (13) for conveying a fluid along the cable, the pulling head comprising:
attachment means (3) for mechanically attaching the pulling head to the cable (e.g. to an end, or end portion of the cable) to enable a pulling force to be applied to the cable via the pulling head (the attachment means may also be referred to as gripping, clamping, holding, or securing means, for gripping, clamping, holding, or securing an end, or end portion, of the cable, respectively);
connection means (4) for making at least one of an electrical connection (41) to said core, a waveguide connection (42) to said waveguide for sending an electromagnetic signal along the waveguide, and a hydraulic connection (43) to said bore (in other words, the connection means may comprise at least one of an electrical connector, a waveguide connector, and a fluidic/hydraulic connector for connecting to a core, waveguide, or bore, respectively, of an attached cable);
measuring means (5) (monitoring means) connected to the connection means and operable to perform at least one measurement, via the connection means, on a connected said cable; and
coupling means (6) (a coupling, a pulling means, e.g. a pulling eye) for coupling to (engagement by) a means for providing a pulling force (or, in other words, pulling means to which a pulling force may be applied to pull an attached said cable).

Advantageously, a pulling head in accordance with the present invention is able to perform at least one measurement on a conductive core, waveguide, or fluid carrying bore of the cable to which it is attached, thereby enabling at least one component of the attached cable to be monitored before, during, or after deployment, and before the pulling head needs to be disconnected and the previously encapsulated end of the cable is installed in its final position (i.e. connected to the desired piece of infrastructure). Faults resulting from handling in particular may be identified as soon as they occur, for example during the pulling process, and appropriate action taken, thereby enabling more efficient use of resources such as cable laying vessels and associated personnel, thereby saving costs.

In certain embodiments the connection means is adapted to provide a plurality of electrical connections to a respective plurality of electrically conductive cores of an attached said cable (e.g. the connection means may comprise a plurality of electrical connectors, each for connecting to a respective core, and each electrical connector may comprise a respective terminal, plug, or socket to which the respective core is attached, either directly or by means of a corresponding terminal, socket, or plug provided on/attached to the end of the respective core) to form the electrical connection).

In such embodiments, the measuring means may comprise a multiplexer (or multiplexing means, or switching means) operable to selectively connect to each electrical connector, for connecting the respective core to measurement circuitry of the measuring means.

In certain embodiments, the connection means is adapted to provide a plurality of waveguide connections to a respective plurality of waveguides of an attached said cable (e.g. the connection means may comprise a plurality of waveguide connectors, each for connecting to a respective waveguide of the cable, and each waveguide connector may comprise a respective terminal, plug, or socket to which the respective waveguide is attached, either directly or by means of a corresponding terminal, socket, or plug provided on/attached to the end of the respective waveguide) to form the waveguide connection). In such embodiments, the measuring means may comprise a multiplexer (or multiplexing means, or switching means) operable to selectively connect to each waveguide connector, for connecting the respective waveguide to measurement circuitry/components of the measuring means.

In certain embodiments, the connection means is adapted to provide a plurality of fluidic/hydraulic connections to a respective plurality of bores of an attached said cable (e.g. the connection means may comprise a plurality of fluid/hydraulic connectors, each for connecting to a respective bore of the cable, and each fluid connector may comprise a respective terminal, plug, or socket to which the respective bore is attached, either directly or by means of a corresponding terminal, socket, or plug provided on/attached to the end of the respective bore) to form the fluid/hydraulic connection). In such embodiments, the measuring means may comprise a multiplexer (or multiplexing means, or switching means) operable to selectively connect to each fluid/hydraulic connector, for connecting the respective bore to measurement circuitry/components of the measuring means.

Thus, a pulling head embodying the invention may be arranged to perform tests on one component, a plurality of components, or indeed all electrical, waveguide, and fluid carrying components of an attached cable, so as to provide comprehensive monitoring capability on the cable while it is being pulled and deployed. The pulling head may be an integrated battery powered measuring and datalogging system.

In certain embodiments, the at least one measurement comprises measuring an electrical resistance between a respective pair of said cores.

In certain embodiments, the at least one measurement comprises measuring an electrical capacitance between a respective pair of said cores.

In certain embodiments, the at least one measurement comprises measuring an electrical inductance.

In certain embodiments, the pulling head comprises a terminal (electrode) arranged to make electrical connection to a fluid in which the pulling head may be immersed. In such embodiments, the at least one measurement comprises measuring an electrical resistance between a said core and said terminal.

In certain embodiments, the at least one measurement comprises measuring an electrical capacitance between a said core and said terminal.

In certain embodiments, the at least one measurement comprises measuring a continuity of at least one core, waveguide, or bore of an attached cable. Advantageously, breaks in one of these components may be identified while the cable is being pulled and appropriate action taken.

In certain embodiments, the at least one measurement comprises a Time Domain Reflectometry (TDR) measurement on at least one core, waveguide, or bore of an attached cable.

In certain embodiments, the at least one measurement comprises measuring temperature at at least one position along an attached cable by means of a sending an electromagnetic signal along said waveguide to interact with a respective temperature sensor (e.g. Bragg grating) at each said position.

In certain embodiments, the at least one measurement comprises measuring strain at at least one location along an attached cable by means of a sending an electromagnetic signal along said waveguide to interact with a respective strain sensor (e.g. Bragg grating) at each said location. Advantageously, strain measurements may be made in this way at a plurality of locations distributed along the cable, so that locally high strains may be identified and optionally further measurements may be made on the attached cable to cheque weather such locally high strains have resulted in damage of the electrical, waveguide, or fluid-conveying components.

In certain embodiments, the at least one measurement comprises applying a pressure via said hydraulic connection to a bore of an attached said cable and measuring pressure of fluid within said bore. Thus, the pressure of fluid within the bore may be measured as a function of time, and a decay in that pressure may be used as an indication of potential problems with the fluid carrying pipe or other such conduit.

In certain embodiments, the measuring means is operable to perform said at least one measurement on a connected said cable while said cable is being pulled via the pulling head.

In certain embodiments, the pulling head further comprises a memory (data storage means) and the pulling head is further arranged to store results of at least one said measurement, and optionally results of each said measurement, in the memory. In other words, the measurement data may be logged As the cable is being pulled, spooled, or unspooled.

In certain embodiments, the measuring means is arranged to monitor results of at least one said measurement, and optionally results of each said measurement, and generate an alert signal according to said results. The alert signal may be generated, for example, in response to one or more of the measurement results exceeding a predetermined threshold. The generation of the alert signal may. be in addition to, or an alternative to the logging of data

In certain embodiments, the pulling head further comprises indicating means for indicating, at the pulling head, generation of said alert signal, and/or means for transmitting said alert signal to a remote location (e.g. by a wired connection to the pulling head, or wirelessly, e.g. acoustically, magnetically, capacitively, or by electromagnetic radiation). This, an operator of the apparatus providing the pulling force may be provided with an alert signal or warning when measurement results indicate potential damage to the cable being pulled, and/or the alert signal may be provided to personnel at a more remote location. Providing the alert signal in this way again enables appropriate action to be taken quickly, enabling efficient use of resources.

In certain embodiments, the pulling head further comprises data transmission means (e.g. a transmitter) for transmitting results (e.g. while the cable is being pulled via the pulling head) of at least one said measurement, and optionally results of each said measurement, to a remote location (e.g. by a wired connection to the pulling head, or wirelessly, e.g. acoustically, magnetically, capacitively, or by electromagnetic radiation).

In certain embodiments, the pulling head further comprises at least one strain sensor arranged to sense (monitor, detect) at least one of a strain resulting from a pulling force applied to the coupling means and a strain resulting from a bending of the pulling head, and wherein the measuring means is connected to the at least one strain sensor and is operable to perform at least one strain measurement of at least one of said strains. Thus, in addition to, or as an alternative to monitoring strain at one or more locations along the attached cable, the pulling head may be arranged to monitor tensile strain and/or or bending strain of the pulling head itself, thereby being able to monitor the total pulling force being applied to the cable at a particular point in time, and/or monitor bending of the pulling head as it is pulled along the deployment path, perhaps through tight bends, and so providing an early indication of potentially problematic bending strains to which the attached cable would subsequently be exposed.

In certain embodiments, the measuring means is operable to perform said at least one strain measurement while the pulling head is being pulled via the coupling means. Thus, the strain measurements may be performed in real time during the pulling process.

In certain embodiments, the pulling head further comprises a memory (data storage means) and the pulling head is further arranged to store results of at least one said strain measurement, and optionally results of each said strain measurement, in the memory. Thus, the pulling head may store strain measurements indicative of the strain history of the pulling head and/or attached cable, and that history may be correlated with measurement results on the other aspects and components of the attached cable, for example to identify when damaging events potentially occurred.

In certain embodiments, the measuring means is arranged to monitor results of at least one said strain measurement, and optionally results of each said strain measurement, and generate a strain alert signal according to said strain measurement results. Thus, the alert signal may indicate to an operator of the pulling apparatus when tensile strain or bending strain of the pulling head or cable has exceeded pre-set safe limits.

In certain embodiments, the pulling head further comprises indicating means for indicating, at the pulling head, generation of said strain alert signal, and/or means for transmitting said strain alert signal to a remote location (e.g. by a wired connection to the pulling head, or wirelessly, e.g. acoustically, magnetically, capacitively, or by electromagnetic radiation).

In certain embodiments, the pulling head further comprises data transmission means (e.g. a transmitter) for transmitting results (e.g. while the cable is being pulled via the pulling head) of at least one said strain measurement, and optionally results of each said strain measurement, to a remote location (e.g. by a wired connection to the pulling head, or wirelessly, e.g. acoustically, magnetically, capacitively, or by electromagnetic radiation).

In certain embodiments, the pulling head further comprises a housing, the measuring means being housed inside said housing. In certain embodiments, at least a portion of said housing is flexible. In certain embodiments, at least a portion of said housing is rigid.

In certain embodiments, said housing comprises a plurality of housing sections (which may also be referred to as modules, portions, segments, components), the measuring means being housed inside at least one of said sections). In such embodiments, at least one said housing section may be flexible and/or at least one said housing section may be rigid. Additionally, or alternatively, the pulling head may further comprise at least one articulated connection connecting an adjacent pair of said housing sections.

In certain embodiments, the housing is waterproof, arranged to prevent water contacting the measuring means when the pulling head is submerged (for example at a depth of 10 m, 100 m, 1000 m or more).

In certain embodiments comprising a plurality of housing sections, at least one of said housing sections is waterproof, arranged to prevent water contacting the measuring means when the pulling head is submerged (for example at a depth of 10 m, 100 m, 1000 m or more).

In certain embodiments, the pulling head further comprises sealing means arranged to form a seal to an attached said cable to prevent or inhibit ingress of water into at least one component of the attached cable (for example into an end of the attached cable) when submerged (for example at a depth of 10 m, 100 m, 1000 m or more).

In certain embodiments, the pulling head further comprises energy storage means (e.g. at least one battery, rechargeable battery, fuel cell) arranged to power the measuring means (and, for example) any other component requiring electrical power.

In certain embodiments, the measuring means comprising a programmable processor, the processor being operable to control said measurements.

in certain embodiments, the pulling head further comprises an input socket (wired interface) and/or a data receiver (wireless interface) for receiving data to program said processor.

In certain embodiments, the attachment means is arranged to grip a surface (e.g. an outer surface) of an end portion of the cable or of a component of said end portion. In such embodiments, the attachment means may comprise a woven tubular mesh for gripping said surface, and at least a portion of the connection means is arranged to extend axially, along a portion of a length of the woven tubular mesh, inside said woven tubular mesh.

Thus, in certain embodiments, the attachment means may comprise at least one pulling sock. Pulling socks, also known as towing socks (or stockings), Chinese Fingers, pulling stockings, and cable grips, are known for use in various applications that require a pulling load to be applied to a cable, pipe, tube, or similar object. Known pulling socks include arrangements comprising a wire mesh tube, with a collar and at least one eye at one end. They may be woven using high tensile wire (e.g. galvanised steel wire), and the woven arrangement is such that the harder the pulling force applied to the eye end, the tighter the gripping force applied to a cable inserted into the open end of the tubular mesh. Advantageously, they add little to the outside diameter of the object being pulled, and although they are typically used for pulling cables and other objects with generally cylindrical outer surfaces, they can also be used for pulling non-cylindrical objects (i.e. objects not necessarily having uniform circular cross sections/perimeters along at least an end length).

In certain embodiments, the attachment means is arranged to grip at least one internal component of the cable. In such embodiments, the attachment means may be arranged to grip at least a portion of a layer of armour of said cable.

Another aspect of the invention provides an assembly comprising a pulling head, in accordance with the above-mentioned aspect or any one of its embodiments, attached to a said cable.

Another aspect of the invention provides a pulling head assembly for attachment to, and pulling of, a cable (e.g. an umbilical, sub-sea umbilical, pipe, tube, rope, hawser, interconnector, or other such elongate member) having at least one of: an electrically conductive core (e.g. an electrical conductor/wire/cable or bunch of electrical conductors/wires/cables) for carrying electrical current along the cable; an electromagnetic waveguide (e.g. an optical fibre/cable or bundle of fibres/cables) for carrying electromagnetic signals along the cable; and a bore for conveying a fluid along the cable, the pulling head assembly comprising:
a pulling module comprising attachment means, for mechanically attaching the pulling head to the cable to enable a pulling force to be applied to the cable via the pulling head, and coupling means (a coupling, a pulling means, e.g. a pulling eye), for coupling to (engagement by) a means for providing a pulling force (or, in other words, pulling means to which a pulling force may be applied to pull an attached said cable); and a measurement module comprising connection means, for making at least one of:
an electrical connection to said core; a connection to said waveguide for sending an electromagnetic signal along the waveguide; and a hydraulic connection to said bore, and measuring means (monitoring means) connected to the connection means and operable to perform at least one measurement, via the connection means, on a connected said cable.

Another aspect of the invention provides a measurement module for a pulling head assembly in accordance with the immediately preceding paragraph.

Another aspect of the invention provides a method of handling a cable (1) (e.g. an umbilical, sub-sea umbilical, pipe, tube, rope, hawser, interconnector, or other such elongate member) having at least one of: an electrically conductive core (11) (e.g. an electrical conductor/wire/cable or bunch of electrical conductors/wires/cables) for carrying electrical current and/or electrical signals along the cable; an electromagnetic waveguide (12) (e.g. an optical fibre/cable or bundle of fibres/cables) for carrying electromagnetic signals along the cable; and a bore (13) for conveying a fluid along the cable, the method comprising:
providing a said cable;
   making, with connection means, at least one of an electrical connection (41) to said core, a connection (42) to said waveguide for sending an electromagnetic signal along the waveguide, and a hydraulic connection (43) to said bore at an end of said cable;
   connecting measuring means (5) to the connection means, the measuring means being operable to perform at least one measurement, via the connection means, on the connected said cable;
   pulling, spooling, or un-spooling said cable; and
   performing, at least one of before, after, and while performing said pulling, spooling, or unspooling, said at least one measurement, via the connection means, on the connected said cable.

In certain embodiments, the method further comprises at least one of:
storing results of said at least one measurement in memory means of the measuring means;
transmitting results of said at least one measurement for reception at a remote location;
comparing results of said at least one measurement with at least one criteria; and
   generating an alert signal depending on the results of said comparing.

In a certain embodiments, the method further comprises:
deploying said end of said cable with connected measuring means to a sub-sea (underwater) location;
keeping said end of said cable with connected measuring means in said location for a period of time; and
operating said measuring means to perform said at least one measurement on the attached cable at said location, after said period of time, before moving said end of said cable from said location or connecting said end to other apparatus.

In certain embodiments, said connection means and measuring means are components of a pulling head or a pulling head assembly in accordance with any one of the above described aspects and embodiments, and the method further comprises attaching the attachment means to said cable.

In certain embodiments, said pulling, spooling, or un-spooling of said cable comprises applying a pulling force to said coupling means.

Another aspect of the invention provides a method of handling a cable (1) (e.g. an umbilical, sub-sea umbilical, pipe, tube, rope, hawser, interconnector, or other such elongate member) having at least one of: an electrically conductive core (11) (e.g. an electrical conductor/wire/cable or bunch of electrical conductors/wires/cables) for carrying electrical current and/or electrical signals along the cable; an electromagnetic waveguide (12) (e.g. an optical fibre/cable or bundle of fibres/cables) for carrying electromagnetic signals along the cable; and a bore (13) for conveying a fluid along the cable, the method comprising:
providing a said cable;
attaching and connecting a pulling head or a pulling head assembly in accordance with any one of the above-described aspects and embodiments, to said cable;
pulling, spooling, or un-spooling said cable; and
performing with the measuring means, at least one of before, after, and while performing said pulling, spooling, or unspooling, said at least one measurement, via the connection means, on the connected said cable.

In certain embodiments, said performing of at least one measurement comprises performing, while pulling, spooling, or un-spooling said cable, a plurality of said measurements (e.g. at regular intervals).

in certain embodiments, said plurality of measurements comprise a first plurality of measurements of strain and/or bending of the cable.

In certain embodiments, said plurality of measurements comprise a second plurality of measurements, said second plurality of measurements being on parameters/characteristics other than strain or bending.

In certain embodiments, the method further comprises performing, while pulling, spooling, or un-spooling said cable, measurements of strain and/or bending of the pulling head or pulling head assembly.

In certain embodiments, the method further comprises increasing a frequency of said plurality of measurements according to the results of said measurements of strain and/or bending of the cable and/or of the pulling head or pulling head assembly. Thus, measurements may be concentrated around situations in time where tensile strain and or bending strain become dangerously high.

For example, cables for conveying power from offshore power generation apparatus (e.g. offshore wind farms) are typically pulled-in via a J tube and have conventional hardwire connections above the water line. It may be desirable to perform a concentrated plurality of measurements (i.e. at small time intervals) while the pulling head, and then a leading portion of the attached cable, is pulled through the J-tube.

Another aspect provides a method of handling a cable (1) (e.g. a cable for subsea transmission of electrical power) having at least one of: at least one electrically conductive core (11) for carrying electrical current and/or electrical signals along the cable; at least one electromagnetic waveguide (12) (e.g. one or more optical fibres; one or more optical cables or optical sub-cables, i.e. optical cable components of the overall cable) for carrying electromagnetic signals along the cable; and at least one bore (13) for conveying a fluid (i.e. a gas or a liquid, e.g. gaseous hydrogen, liquid hydrogen, or other liquid or gaseous product of an energy generation system) along the cable, the method comprising:
providing a said cable having an end;
attaching measurement apparatus to said end in an above-water or out-of-water (e.g. dry) environment such that the measurement apparatus makes at least one of: at least one respective electrical connection to at least one said core; at least one respective connection to at least one said waveguide for sending an electromagnetic signal along the waveguide; and at least one respective fluid or hydraulic connection to at least one said bore;
deploying (e.g. laying) the cable such that said end, with the measurement apparatus attached, is submerged in water (i.e. is underwater) for a period of time;
after said period of time, recovering (e.g. pulling) said end and attached measurement apparatus to an above-water or out-of-water (e.g. dry) location; and
while the measurement apparatus is attached to said end, operating the measurement apparatus to perform at least one measurement on the attached cable (e.g. performing a measurement at at least one time before, during, and/or after said deploying, and/or before, during, and/or after said recovering, such as between deploying and recovering, and/or during said recovering, or after a period of storage (e.g. at a sub-sea deployed location) then before and during a pulling operation to take the cable end up to a surface vessel or installation for dry-connection to other apparatus).

Another aspect provides measurement (e.g. monitoring) apparatus for connection to an end of a cable (1) (e.g. to an unterminated end, or to an already-terminated end (e.g. terminated by a termination assembly or structure, and/or at least one connector), of a cable for subsea transmission of electrical power) having at least one of: at least one electrically conductive core (11) for carrying electrical current and/or electrical signals along the cable; at least one electromagnetic waveguide (12) for carrying electromagnetic signals along the cable; and at least one bore (13) for conveying a fluid along the cable, the measurement apparatus comprising:
connection means (4) for connecting to said end in an above-water or out-of-water (e.g. dry) environment to make at least one of: at least one respective electrical connection (41) to at least one said core, at least one respective waveguide connection (42) to at least one said waveguide for sending an electromagnetic signal along the waveguide, and at least one respective fluid or hydraulic connection (43) to at least one said bore; and
measuring means (5) connected to the connection means and operable to perform at least one measurement, via the connection means, on a connected said cable,
   wherein the measurement apparatus is deployable, when connected to an end of said cable, with said cable end to an underwater location for a period of time, and recoverable with said connected cable end after said period of time to an above-water or out-of-water (e.g. dry) location, and
wherein the measuring means is operable to perform said at least one measurement while the measurement apparatus is connected to said cable end and at least while submerged with said connected cable end and/or after recovery with said connected cable end from said underwater location to said above-water or out-of-water location.

The measurement apparatus may be a smart pulling head, incorporating coupling means for coupling to a source of pulling force, and/or may be a smart protection cap, providing a degree of protection to the end of the cable, as well as measurement/monitoring capabilities.

A Smart Protection Cap embodying the invention may contain electronic monitoring systems.

It may be in the form of a water tight cap that fits over the end of a cable/umbilical destined to be installed under water or in other hostile environments.

The Smart Protection Cap may form an environmental seal between the surrounding environment and the functional components within the cable that may (or may not) be exposed to the environment.

In addition to an environmental seal, the Smart Protection Cap may have a physical restraint system that interfaces to the cable such that the cap cannot be accidentally removed during normal use.

The Smart Protection Cap may directly interface to a connector system previously installed onto the cable. The connector may be dry mate or wet mate.

The Smart Protection Cap may fit directly to a preinstalled connector termination with no other interface to the cable.

The Smart Protection Cap may be in the form of a mating connector or it may interface to the pre-installed connector functional connections-electro/optical/hydraulic etc.—via a method other than the normal design of a mating connector, i.e. it may be a simple cap with connection means to the cable or pre-installed connector.

The Smart Protection Cap may be equally functional above water where it might lay on the ground or be buried beneath it.

The Smart Protection Cap may be equally functional suspended in the air.

The Smart Protection Cap may fit to a cable without any form of mating connector.

The Smart Protection Cap may fit to a cable that has been simply cut from a longer length.

The Smart Protection Cap may interface to a cable that has been pre-prepared for final connection in some manner (such as being provided with termination eyes)

The Smart Protection Cap may comprise a restraint system that may grip the outer sheath of the cable and/or internal strength members.

The restraint system may fit to a pre-installed connector.

The Smart Protection Cap may comprise/contain a measuring means connected to the functional cores of the cable via a connector or some other means to provide at least one of electrical, optical, and fluid connection between the two.

The measurement apparatus may be a smart monitoring cap, adapted to be connected to the cable to be monitored so as to provide at least one of electrical, optical, and fluid connection between the smart monitoring cap and the cable under test, the smart monitoring cap being deployable with the cable to a subsea location and perform a measurement at the subsea location on the cable and provide an indication of a result of the measurement from the subsea location to an underwater vehicle or diver, and/or transmit the measurement result(s) for remote reception, and/or log (i.e. store) the measurement result(s) (e.g. for transmission, export, interrogation at a later time).

The smart monitoring cap may have a connector system that allows the attachment of a removeable measuring means that can be easily swapped between smart monitoring caps (or Smart Protection Caps).

The connector system may be ‘wet-mate’ in that the measuring means can be connected/disconnected underwater, and/or “dry mate”.

Further features of aspects and embodiments of the present invention will be appreciated from the following detailed description. It will be appreciated that any feature, or any combination of features, of one aspect or embodiment may be incorporated in any other aspect or embodiment, and will provide corresponding advantage(s).

### BRIEF DESCRIPTION OF THE DRAWINGS

Embodiments of the invention will now be described with reference to the accompanying drawings, of which:

FIG. 1 is a highly schematic cross section of a cable to which a pulling head or pulling head assembly embodying the present invention may be attached;

FIG. 2 is a highly schematic representation of a known pulling head attached to a cable;

FIG. 3 is a highly schematic representation of a pulling head embodying an aspect of the invention and connected to a cable;

FIG. 4 is a block diagram illustrating components of the measuring means of a pulling head according to an embodiment of the invention;

FIG. 5 is a schematic cross section of another pulling head embodying the invention attached to a cable;

FIG. 6 is a schematic cross section of another pulling head embodying an aspect of the invention;

FIG. 7 is a schematic representation of another pulling head, or pulling head assembly, embodying an aspect of the invention;

FIG. 8 is a highly schematic representation of a pulling head assembly embodying an aspect of the invention;

FIG. 9 is another highly schematic representation of a pulling head assembly embodying an aspect of the invention;

FIG. 10 is a flow chart illustrating certain steps in a method embodying an aspect of the present invention;

FIG. 11 illustrates examples of terminated cables;

FIG. 12 illustrates a pulling head attached to a cable;

FIG. 13 illustrates another terminated end of a cable;

FIG. 14 illustrates a smart pulling head attached to a terminated cable end;

FIG. 15 illustrates another terminated end of a cable;

FIG. 16 illustrates another smart pulling head attached to a terminated cable;

FIG. 17 illustrates a terminated cable end with measurement apparatus attached;

FIG. 18 illustrates a terminated cable end and smart measuring apparatus or smart pulling head;

FIG. 19 illustrates a terminated cable end and smart measuring apparatus or smart protection cap;

FIG. 20 illustrates a cable end with attached smart pulling head;

FIG. 21 illustrates 8 terminated cable end with measurement apparatus attached;

FIG. 22 illustrates another terminated cable end with measurement apparatus attached;

FIG. 23 illustrates a terminated cable end with a plurality of measurement apparatus attached;

FIG. 24 illustrates a cable end attached two and protected by a smart protection cap;

FIG. 25 illustrates a terminated cable end with smart measuring apparatus or smart protection cap attached;

FIG. 26 illustrate steps in a method embodying an aspect of the invention;

FIG. 27 illustrates steps in a data logging method used in embodiments; and

FIGS. 28 to 35 illustrates steps and corresponding apparatus configurations in methods embodying and/or usable in embodiments of aspects of the invention.

### DETAILED DESCRIPTION OF EMBODIMENTS OF THE INVENTION

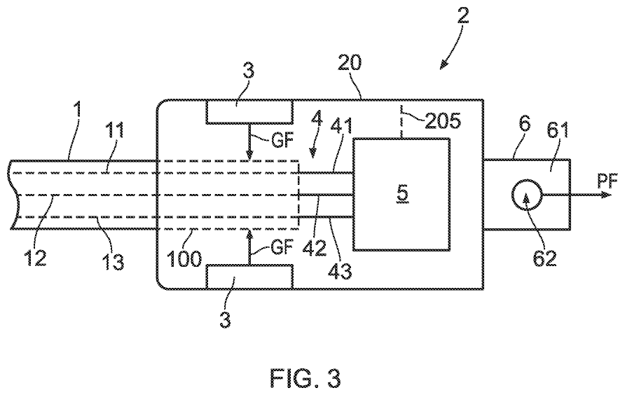

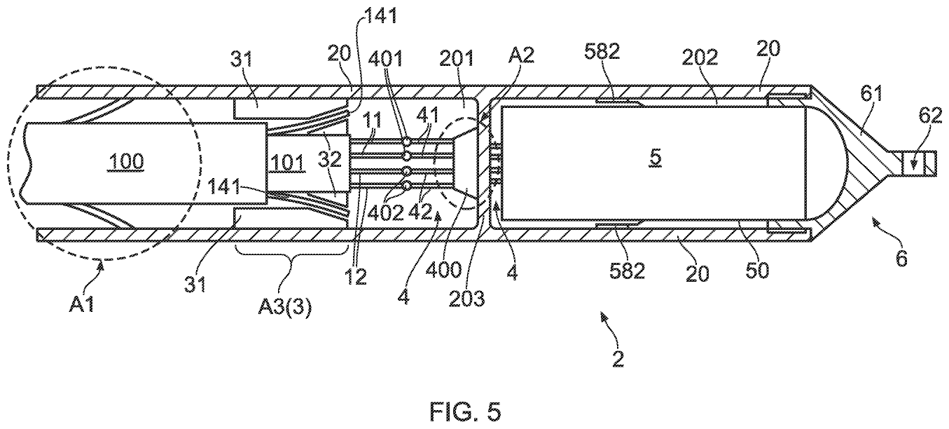

Referring now to FIG. 3, this is a highly schematic representation of a pulling head embodying an aspect of the invention and attached to a cable 1. The pulling head 2 comprises a housing 20 inside which there is provided mechanical attachment means 3 for applying a gripping force GF to an end portion 100 of the cable 1 inserted inside the housing 20. The details of the mechanical arrangement of the attachment means 3 are not shown in the figure, and the invention is not limited to any particular form of attachment means. However, generally speaking, the attachment means in this embodiment is attached or coupled to the housing 20 and is configured to apply the gripping force, GF (which may also be referred to as a clamping force), to the inserted end portion 100 of the cable. In particular, in this example the attachment means 3 provides the gripping force to an outer surface of the inserted cable end 100. In this example the cable comprises an electrically conductive core 11 for carrying electrical current and/or electrical signals along the cable, a waveguide in the form of an optical fibre 12 for carrying optical signals along the cable (and/or for enabling distributed measurements of temperature and or strain along the cable to be measured by means of suitable sensors, such as gratings, provided at a plurality of locations along the optical fibre 12), and a bore 13 provided inside a pipe or tubular component of the cable. In alternative embodiments, however, it will be appreciated that the cable may comprise just one or more electrical cores, just one or more waveguides, just one or more fluid conveying bores, or any combination comprising two or more elements selected from such cores, waveguides, and bores. Although not shown in the figure, pulling heads embodying this (and other) aspects of the invention may also comprise one or more pulling head strain sensors (such as those illustrated in FIGS. 5, 6, and 7). For example, at least one strain sensor may be arranged/located on the inside of housing 20, such as on the inside of the long edge in the figure, or indeed at any location suitable for enabling the strain sensor to detect/sense strain of the pulling head.

The pulling head further comprises measurement means 5 arranged inside the housing 20 and coupled to the housing 20 by means of support means 205, which maybe rigid or flexible. The pulling head also comprises connection means 4 comprising an electrical connector 41 connecting the measurement means 5 to the conductive core 11, a waveguide connector 42 connecting the measurement means 5 to the optical fibre 12, and a fluid connector 43 connecting the measurement means 5 to the bore 13. In use, the measurement means 5 is operable to perform measurements on the core 11, optical fibre 12, and bore 13 of the attached cable via the connection means 4. The pulling head further comprises coupling means 6 in the form of a strong, rigid coupling member 61 in which (or through which) a coupling eye 62 is provided. A pulling rope, cable, or wire, or a suitable fitting at the end of such a pulling member can be coupled to the coupling means 6 through the eye 62 and then used to apply a pulling force, indicated generally by the arrow labelled PF in the figure, to the pulling head 2 and thus to the attached cable 1 as a result of the mechanical attachment or grip provided between the pulling head 2 and cable 1 by the attachment means 3.

In this example the measurement means 5 is operable to perform measurements on the attached cable (or, more specifically on components, i.e. the core(s), waveguide(s), and/or bore(s), of the attached cable) while the cable is being pulled via the pulling head 2.

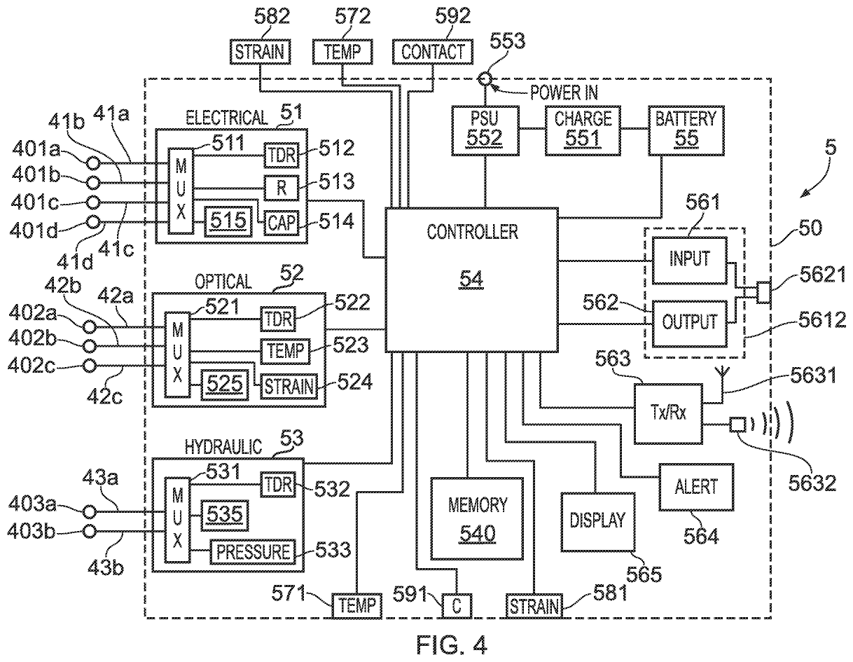

FIG. 4 illustrates in more detail components of the measuring means 5 of another pulling head embodying an aspect of the invention. Although many of the components in FIG. 5 are illustrated as being parts of the measuring means 5, it will be appreciated that in alternative embodiments one or more of such components may be provided elsewhere within the pulling head or pulling head assembly, i.e. they may not necessarily be part of the measurement means 5 as such.

Referring to FIG. 4, this illustrates measuring means 5 adapted for use in a pulling head for a cable comprising a plurality of conductive cores, a plurality of waveguides, and a plurality of fluid carrying bores. The measuring means comprises an electrical measurement module 51, an optical measurement module 52, and a hydraulic measurement module 53. The electrical measurement module 51 comprises a multiplexer 511 (which may also be referred to as multi plexing means, or switching means) operable to selectively connect to one or more of four electrical connectors 41a-d. Each electrical connector 41 is terminated by a respective terminal, plug, or socket 401a-d, and in use, these terminals 401 may be connected to respective conductive cores of the cable to be pulled. The electrical measurement module 51 further comprises a Time Domain Reflectometry (TDR) module 512 operable to perform TDR measurements on electrical cores of an attached cable, a resistance measurement module 513 operable to perform resistance measurements between pairs of cores of an attached cable, or between an attached core and some other element such as a fluid in which the apparatus is immersed. In other words, the resistance module 513 can be used to measure insulation integrity of an attached cable, or, for example, the continuity of connection through a pair of conductors connected (or looped, shorted, etc.) at the far end of the cable. The module 51 further comprises a capacitance measuring module 514, arranged to measure capacitance between a selective pair of attached conductive cores, or between one such core and another component of the cable or environment. The module 51 further comprises a further measurement module 515 adapted to perform additional electrical measurements (e.g. inductance measurements) on the attached cable and its components. It will be appreciated that the elements of the electrical testing module 51 are under the control of a controller 54 of the measuring means.

The optical measurement module 52 similarly comprises a multiplexer 521 for making selected connections to one or more of three optical connectors 42a-c, each terminated by a respective optical terminal, plug, or socket 402a-c. The optical module 52 comprises an optical TDR module 522 for making TDR measurements on optical fibres of an attached cable via the connectors 42. The module 52 further comprises a temperature measurement module 523 arranged to perform measurements of temperature at a plurality of locations along an attached cable by means of interrogating optical temperature sensors provided at a plurality of locations distributed along that cable and provided within the optical fibres. Similarly, the optical module 52 also incorporates a strain measurement module 524 operable to perform strain measurements at a plurality of locations along the attached cable, again by suitably arranged optical strain sensors provided within the optical waveguides of the attached cable. Finally, a further module 525 is operable to make further optical measurements on the optical components of an attached cable.

The hydraulic module 53 again comprises a multiplexer 531 controllable to make selected connections to one or more of a plurality of bores in the attached cable by means of fluid connectors 43a and 43b, again each provided with a respective terminal, plug, or socket 403a-b. The hydraulic module 53 also includes a TDR module 532 for performing TDR measurements on bores of the attached cable by means of sending pressure pulses along the attached bores and monitoring reflections. The hydraulic module 53 also comprises a pressure measurement module 533 operable to pressurise a fluid inside a bore of an attached cable and/or monitor pressure within such a bore, for example as that pressure changes as a function of time. Although this embodiment includes a hydraulic/fluidic multiplexer, certain alternative embodiments comprise no such multiplexer and instead provided a separate pressure sensor for direct connection to each bore. Yet further embodiments comprise a hydraulic multiplexer and at least one such separate pressure sensor.

In this example, the measuring means 5 further comprises a temperature sensor 571 arranged inside a housing 52 of the measuring means, and a temperature sensor 572 arranged outside that housing 50. These temperature sensors may be interrogated by the controller 54 so as to provide an indication of temperature at a plurality of locations inside and outside the pulling head during use. The measuring means also includes a strain sensor 581 arranged inside the housing 50 and a strain sensor 582 arranged outside the housing 50. In use, the controller 54 may interrogate these strain sensors appropriately, for example to determine tensile strain or bending strain of the pulling head or pulling head assembly, or of its components, during operation. The measuring means further comprises an electrical contact 591 for providing electrical contact to a fluid or other medium in which the housing 50 is immersed, and a further contact 592 arranged at a location outside the housing 50. It will be appreciated that such contacts may be suitably arranged to enable the measuring means to perform electrical measurements in particular between respective cores or other components of an attached cable and an environment in which the pulling head is situated or immersed. The measuring means 5 further comprises a rechargeable battery 55 operable to power the controller and other electrical components of the measuring means. It also includes a power supply unit 552 arranged to receive power from an external source via a power connector 553. The power supply unit 552 is operable to power the measuring means when connected to an external power source and to charge the battery 55 via charging circuitry 551. Thus, when the pulling head is at a suitable location, power may be supplied to it from an external source, but during use, particularly when submerged, the battery or other suitable energy storage means may power all of its measurement operations.

The measuring means also comprises input means 561 for providing input signals or commands to the controller 54, and an output unit 562 for outputting data. The input and output modules 561 and 562 may be incorporated in a single input/output module 5612, connected to connector 5621 via which the controller may be programmed and/or its measurement results may be accessed (for example after recovery from a subsea location).

The measuring means 5 further comprises a memory 540 for storing results of measurements performed on an attached cable, and indeed other measurements performed by the measuring means during use, and also for storing Instructions for operating the controller and other components. In other words, the measuring means 5 may be programmed, and the programming code for operating the measuring means may be stored in the memory 540. The apparatus further comprises a display 565, controlled by the controller 54, and operable to display measurement data and any other data useful/necessary for operation of the apparatus. The apparatus further comprises an alert signal generating module 564, again under the control of the controller 54, for emitting an alert signal in response to results of one or more measurements exceeding predetermined criteria. Lastly, the apparatus further comprises a transmitter/receiver module 563 (or transceiver) for transmitting data, such as measurement data, for reception at a remote location via an antenna 5631 and or an acoustic transducer 5632. The antenna and transducer may each be arranged also to receive wireless signals from a remote source, for example for controlling or programming the operations of the measuring means 5. Although an electrical antenna and ultrasonic transducer are shown in the figure, it will be appreciated that the transmitting/receiving unit 563 may be arranged to transmit and/or receive data and/or instructions via any other suitable wireless means in alternative embodiments of the invention.

Referring now to FIG. 5, this shows another pulling head. Here the housing 20 is generally cylindrical, it has a transverse wall 203 dividing the interior space into a rear portion 201 into which the cable is inserted, and a forward space 202 in which the measuring means 5 is located. Arrow A3 generally indicates an arrangement to couple the armour layer of the attached cable or umbilical into the pulling head. As seen in the figure, components, such as wires 141, of the armour layer are clamped by (e.g. between) clamping means 31 and 32 so as to grip the inserted end portion 100 of the cable. In this example the cable is a subsea umbilical. Arrow A1 indicates a mechanical arrangement for umbilical stabilisation and bend restriction. A plurality of umbilical electrical cores and/or optical cores (also referred to as waveguides) 11, 12 are exposed at the end of the cable inside housing 20 and are shown attached, via respective connectors or joints 401, 402 to a plurality of electrical connectors 41 and optical connectors 42. Those connectors pass through a penetrator or feedthrough or water block member 400 from the volume 201 and into the forward space 202 where they connect to the measuring means 5. The measuring means also comprises a pair of strain measurement transducers 582 attached to interior surfaces of the pulling head body. Those strain sensors are able to monitor tensile strain of the pulling head body and/or bending strain of the body. An end of the forward volume 202 is sealed by the coupling means body 6, comprising a rigid member 61 having a pulling eye 62 provided at a forward end. The measuring means 5 may have the general configuration shown in FIG. 4, or may have any other suitable configuration, for performing measurements on elements of an attached cable during pulling and other operations involving that cable.

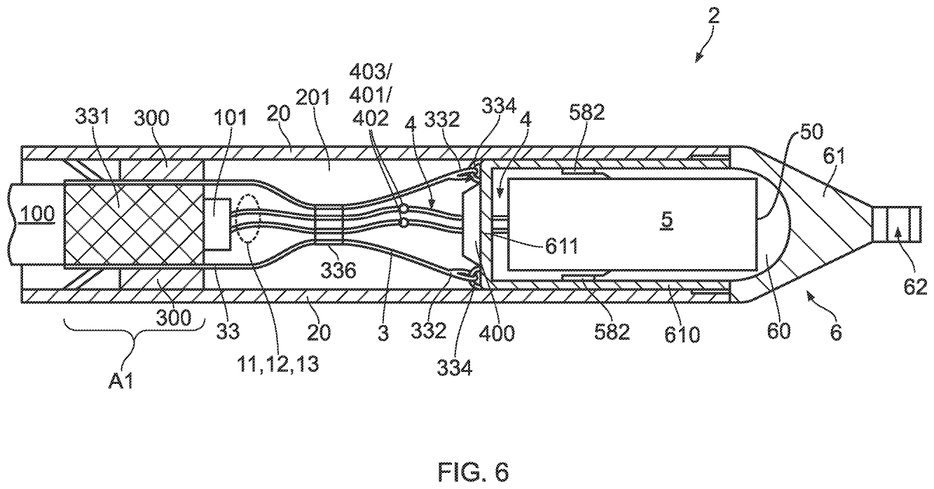

Referring now to FIG. 6, this shows another pulling head embodying an aspect of the invention. Again, the pulling head comprises a generally cylindrical housing 20, a forward end of which is attached to and sealed by a pulling means body 61 which defines an internal volume 60 in which the measurement means 5 is located. A rear end of the cylindrical body 20 receives the end portion 100 of the cable to be pulled and monitored. Inside that rear portion there is provided a cable stabilisation and bend restrictor arrangement, including spacer members 300. The attachment means 3 in this example comprises a tubular mesh of suitably woven wires 331, having the form generally known as a pulling sock. Under tension, the strands 331 of the pulling sock provide a strong grip on an outer surface of the cable. The woven strands are gathered together and pass through a collar 336, and at a forward end the strands are formed into a plurality of loops 332, each of which is anchored to the pulling head, and in particular to a surface of the coupling means body 61, by attachment loops, hooks (or other suitable attachment members) 334. The end portion 100 of the cable has been prepared such that a portion 101 of an inner portion of the cable protrudes in a forward direction from an outer portion of the cable, and from that a plurality of umbilical cores, which may each be electrical or optical, also protrude in a forward direction. Those electrical and/or optical cores are connected by (or at) connectors (or connector terminals, plugs, or sockets) 401, 402, 403 to the connection means 4 of the pulling head. The connection means 4 passes through a penetrator, feedthrough, or water block member 400, also through a base wall 611 of the coupling member 61, and into the interior volume 60. Here, the connection means 4 connects to the measuring means 5 which is operable to perform measurements on the attached cores of the cable. Again, the pulling head assembly further comprises strain measurement modules 582, this time attached to an inner surface of the generally cylindrical wall 610 of the coupling means body 61, and via these strain measurement modules 582 the measurement means 5 is able to measure and monitor tensile strain and or bending strain of the pulling head during use. Again the coupling means comprises an eye coupling for engagement by a suitable source of pulling force. However, it will be appreciated that in alternative embodiments the coupling means may have a different form, and the present invention is not limited to pulling heads comprising pulling eyes.

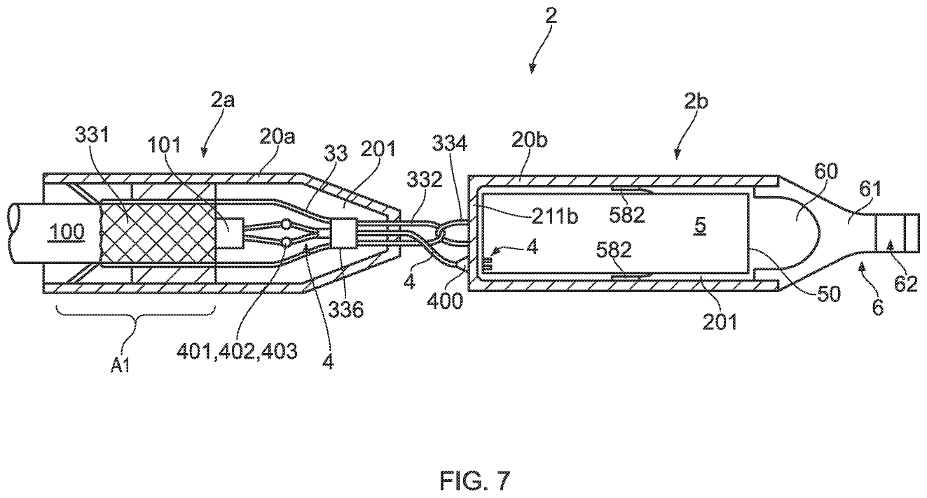

Referring now to FIG. 7, this shows a pulling head or pulling head assembly in accordance with another embodiment. Here the pulling head comprises a plurality of body portions 20a and 20b. The forward body portion 20b generally houses the measurement means 5 and is closed at a forward end by the coupling means 6. A rear housing portion 20a of the pulling head assembly defines an interior volume 201 into which the end 100 of the cable to be pulled is inserted or received. The attachment means 3 again comprises a woven mesh of wires 331 arranged to tightly grip an outer surface of the cable as tension is applied to the woven mesh by means of a loop 332 formed from its wires at a forward end, and coupled to a suitably arranged loop 334 (or other suitable attachment member) attached to a rear surface of a base wall 211b of the forward portion 20b of the housing. Again, the tubular mesh 33 is constricted at a forward position by a collar 336, and in this example the connection means 4 (arranged to connect the measuring means 5 to the cores, waveguides, and/or bores of the attached cable) passes through the collar 336. The connection means 4 terminates at terminals, plugs, or sockets 401, 402, 403, to which the umbilical cores are suitably connected. The connection means 4 passes through a feed through arrangement 400 and through a base wall 211b of the forward housing section 20b and connects to the measuring means 5. Again, strain sensors 582 are attached to the forward housing portion 20b to enable tensile strain and/or bending strain to be monitored. Umbilical stabilisation and bend restriction is again provided by a suitably arranged mechanism, indicated by A1 in the figure. In this example, there is provided a coupling arrangement between a portion of the pulling head 2a providing a pulling grip, and a portion of the pulling head 2b housing the measurement means. The pulling head thus comprises first and second housing sections 20a, 20 b, with an articulated joint connecting them together.

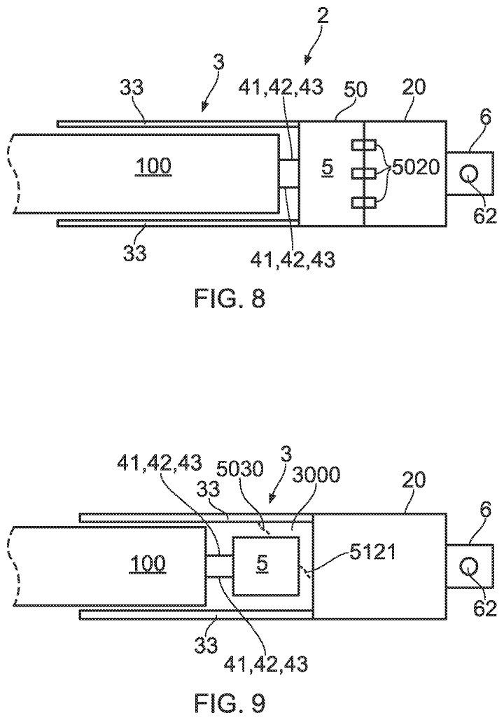

Referring now to FIG. 8, this shows in highly schematic form another pulling head assembly arranged to pull a cable. In this example, attachment means 3, comprising a pulling sock 33 for example, is attached to a housing 50 of measuring means 5. The arrangement, the details of which are not shown in the figure, is such that as the pulling head assembly is pulled in the direction to the right of this figure, the pulling sock 33 grips an outer surface of the inserted portion 100 of the cable. A plurality of connectors 41, 42, 43 are arranged to connect conductive cores, waveguides, and or fluid bores of the cable to the measuring means 5. The housing of the measuring means 50 is connected, in this example via a plurality of bolts 5020, to a housing 20 which itself is attached to, or comprises, coupling means 6 providing a coupling aperture 62 for insertion of a hook, pulling wire, or rope. In this example, the housing 50 of the measuring means experiences (i.e. is subjected to) the pulling force applied to the assembly, and one or more strain sensors attached to the housing 50 may be used to monitor overall strain and pulling force. The housing 20 and coupling means 6 may be of a conventional type, with the additional functionality of being able to monitor cable components during pulling operation being provided by the module 5, 50.

Referring now to FIG. 9, this shows an alternative arrangement in which attachment means 3, for example comprising a pulling stock 33, is attached to a housing 20 of the pulling head, and coupling means 6 is attached at a forward position to the housing 20. A measuring module 5 is housed within a volume 3000 defined inside the attachment means 3, and is attached to components of the pulled cable by means of suitable electrical, optical, and fluid connectors 41, 42, 43. The measuring means 5 is flexibly attached to the attachment means 3 and housing 20 by means of connection arrangements 5030 and 5121. The overall arrangement is such that the pulling force applied to the cable is not directly experienced by the housing of the measuring means 5, although it can be monitored if the measuring means is attached to suitably arranged strain sensors.

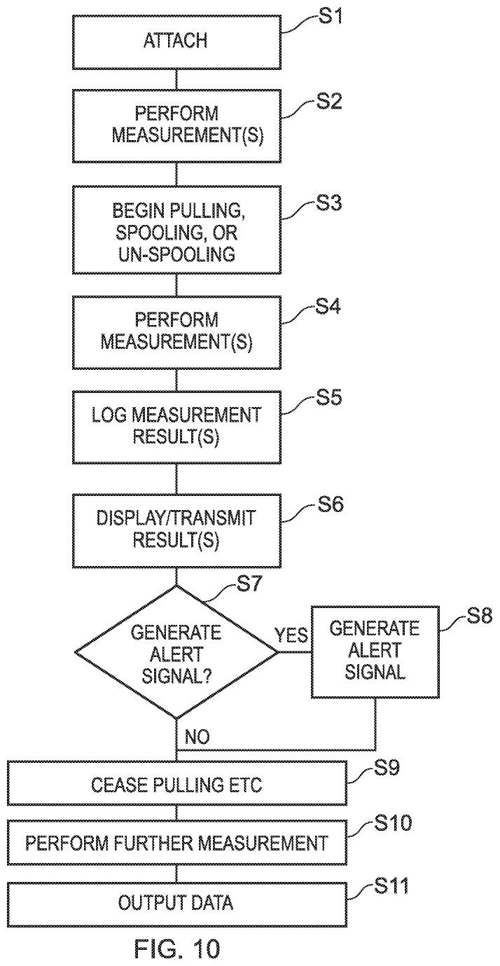

Referring now to FIG. 10, this shows steps in a method embodying an aspect of the present invention. In step S1, a pulling head or pulling head assembly is attached to an end portion of a cable to be pulled. This step includes attaching the measuring means of the pulling head to at least one core, waveguide, or bore of the cable (by suitable connection means) and also attaching the attachment means of the pulling head to the end portion of the cable. Then, in step S2, at least one measurement is performed on the attached cable using the measuring means. In step S3, the cable is pulled using the pulling means, spooled, or unspooled. In step S4, at least one measurement is performed on the attached cable by the measuring means while pulling or spooling or unspooling. Optionally, this step may also include measuring a pulling force applied to the cable, cable tension, and or bending of the cable or pulling head while performing the pulling, spooling, or unspooling. In step S5, the results of the at least one measurement logged, for example in a memory of the pulling head. Then, in step S6, the measurement results may be displayed and/or transmitted wirelessly, for reception at a remote location, while performing the pulling, spooling, or unspooling. Next, in step S7, a determination is made according to the measurement results, weather to generate an alert signal, for example if one or more of the measurements has exceeded a predetermined threshold value. if the determination Is positive, then the method proceeds to step S8, and an alert signal is generated and or emitted. Next, in step S9, the pulling, spooling, or unspooling is ceased. This is followed by step S10 in which at least one further measurement is performed on the attached cable by the measuring means, and then finally in step S11 the measurement data is output.

It will be appreciated that in certain alternative embodiments of the invention, the method may omit some of the steps described above, or may include additional steps, based on the functionality of the pulling head or pulling head assemblies described elsewhere in this specification.

Returning again to FIGS. 5, 6, 7, 8, and 9, it will be appreciated that these figures illustrate examples of a pulling head (which may also be described as a pulling head assembly), the pulling head comprising means for performing a measurement (test) on an attached cable, in accordance with embodiments of the present invention.

Referring again to FIG. 5, a pulling head 2 is shown attached to (or coupled to) the end 100 of an interconnection cable 1. The cable 1 in this example is an umbilical, such as a sub-sea umbilical. However, in other embodiments, the cable 1 may be one of a pipe, tube, rope, hawser, interconnector, or other such elongate member. The cable 1 for attachment to the pulling head 2 comprises an outer portion (typically comprising an outer jacket and armour), and an inner core portion (i.e. an umbilical core), protected by the outer portion, and the core portion comprises at least one electrical core 11 for carrying an electrical current, and at least one waveguide 12 (e.g. an optical fibre, cable, or optical core) for conveying an electromagnetic (e.g. optical) signal along the cable 1. Additionally, the cable 1 may additionally comprise at least one hose, pipe, or suitable tube, having a bore for transporting fluids or gases.

The pulling head 2 in certain embodiments is dry-mateable to the cable 1, by means of an attachment arrangement such as illustrated in FIG. 5 or other figures, or by another suitable arrangement that might be apparent to a person skilled in this field. (It will be appreciated that in certain embodiments the pulling head may additionally, or alternatively, be wet-mateable to the cable, but in general a wet-mateable capability is less frequently required than dry-mateable capability). The attachment arrangement enables the cable 1 to be secured (i.e. coupled, fixed, installed) into the pulling head 2, wherein the cable 1 is secured (fastened) to a housing 20 (or body) of the pulling head 2. The cable 1 may be further secured within the pulling head 2 by stabilization means A1 that contact and extend from the cable 1 to contact an inside of the housing 20 of the pulling head 2. The stabilization means A1 thus acts to restrict movement and/or bend of the cable 1 attached within the pulling head 2.

The pulling head 2 comprises a main body, or housing 20. In certain embodiments, such as that of FIG. 5, the housing may be sub-divided (i.e. separated) into housing portions. Referring to FIG. 5, the housing 20 is divided by a transverse wall 203 into a first (forward) housing portion, and a second (rear) housing portion. However, in further embodiments, the below-described features of the pulling head 2 may be comprised within a single housing (i.e. without sub-division).

In the example of FIG. 5, the first housing portion (defining volume 201) receives, at a first end, the cable 1, and a second end feeds (conveys) at least one core (i.e. an electrical and/or optical core) of the cable 1 through to the second housing portion e.g. via a feedthrough 400 (waterblock; penetrator), wherein the second portion (defining volume 202) houses (stores) a measurement module 5. In other words, the measurement module 5 is housed separately from the first housing portion where the cable 1 is inserted. This arrangement addresses a potential problem: if cable integrity fails at some point, resulting in water leakage into the cores, then this could otherwise get into the electronics of the measurement means and cause electrical/electronic failure. By separating the cable from the electronics (measurement means) by locating the electronics in a separate interior volume, sealed from the cable-receiving volume 201, this problem is avoided, and installation may also be made easier. In certain embodiments the measurement means (comprising electronic components) is flooded with dry nitrogen, and may be sealed in the volume 202, to retain high levels of insulation. Thus, in certain embodiments, the measuring means is sealed and isolated, separate from the connections to the cable components, etc.

In certain embodiments, the termination (connection to the cable components) may be done outside of a housing using probes protruding from the measurement housing and sealing elements that create a water barrier between the electrical cores (or similar) and the probes. Ends of electrical components of the cable may, in certain embodiments, be isolated from water by applying a sealing cap over the end of the conductive core(s). Certain embodiments employ electrical connectors in the form of a cap that has an integrated probe (for making electrical connection to the core) that is wired to the measurement housing/measurement means.

The body portion, or housing, 20 of the pulling head 2 in certain embodiments is rigid, and may comprise the form of a metal tube or similar. In such embodiments, the attachment arrangement is any such mechanical arrangement capable to secure, attach, or lock the cable 1 into the tube, so that the space within the rigid arrangement can be utilised to protect the end of the cable 1 (e.g. by the stabilization means). In further embodiments, the housing 20 may be articulated, wherein it is formed of a number of rigid parts, or articulated units, forming an interconnected caterpillar arrangement. Alternatively, in certain embodiments the housing 20 of the pulling head 2 is flexible, or comprises flexible portions, wherein the flexible housing may be in the form of a flexible tube or similar. Similarly, the space within the flexible tube can be used to protect the end of the cable 1.

The cable end portion 100 in FIG. 5 comprises at least one core 11, 12 for carrying electrical and/or optical signals along the cable 1 (i.e. via at least one umbilical core). In addition, the cable may comprise at least one bore (pipe, hose, or tubing) suitable for transporting, or conveying, a fluid along the cable 1 (i.e. along a hose, pipe or tube). In certain alternative embodiments, however, the cable may comprise no conductive cores or waveguides. just one or more bores.

The at least one core 11, 12 of the cable portion 100 comprises at least one electrically conductive core 11 for carrying electrical current along the cable 1, wherein the electrically conductive core may be an electrical conductor, a wire, cable, or a plurality of conductors, cables, wires, or similar feature that is able to carry electrical current. Additionally, or alternatively, the at least one core 11, 12 of the cable may comprise an electromagnetic waveguide 12 such as an optical fibre, a cable, or a plurality (bunch) of optical fibres or cables, for carrying electromagnetic signals along the cable 1.

The pulling head 2 comprises connection means 4, or joining means, for connection of the measurement module 5 to the respective cores 11, 12 and/or bores 13 of the cable 1. A first portion of the connection means 4 is positioned within the first housing portion defining volume 201, and provides at least one of electrical, optical or fluid connection to the cable end portion 100. A second portion of the connection means 4 passes through a sealing member 400 and transverse wall 203 into the forward volume 202, where it connects to the measuring means.

The measurement module 5, provides measurement, or monitoring, means, and may be comprised within a volume 202 defined by a second housing portion, as is illustrated in FIG. 5. The measurement module 5 is operable to perform such measurement either when submerged under-water, or additionally/alternatively, when out of water when operating in a measurement mode (i.e. a test mode, or monitoring mode) and performing at least one measurement (i.e. at least one test) on the attached cable 1 via the connection means 4.

The pulling head 2 of FIG. 5 further comprises a sealing means 400 arranged to form a seal around the connection means 4, and thus prevents or inhibits the ingress of water to the measuring means components, even if water is able to enter the other volume 201).

The pulling head 2 comprises coupling means 6 attached to, or integral to the housing (e.g. attached to an outside of the housing 20). Such coupling means 6 may comprise a pulling eye, for coupling to (i.e. attaching to) pulling means by which a pulling force may be applied to pull (deploy) the pulling head 2 with attached cable 1. Such pulling means may comprise a hook for coupling (attachment) to the pulling eye, enabling deployment (pulling) of the pulling head 2 and attached cable.

Referring again to FIG. 6, this illustrates a pulling head 2 having an alternative arrangement for connecting/attaching the cable 1 within the pulling head 2, to that described with reference to FIG. 5. The cable 1 may be an umbilical cable, or otherwise, such as that discussed above. FIG. 7 illustrates a pulling head 2 that is connected to, or attached to, the cable 1. The pulling head 2 comprises a housing, comprising a first housing portion 20 for receiving the cable 1, and a second housing portion 610, housing measurement means 5, such as a measurement module. The pulling head 2 comprises coupling means 6 attached to the housing 20, and a portion of the coupling means provides the second housing portion 610.

The pulling head 2 comprises connection means 4 connected to at least two components 11, 12, 13 of the cable at connection terminals, plugs, or sockets 401, 402, 403. The connection means 4 passes from volume 201 to volume 60 through a base wall 61 of the coupling means and through a sealing member 400 (which may also be referred to as a feedthrough 400 (waterblock/penetrator). The measurement module 5 is operable to perform a plurality of measurements (tests) on the at least one cable components 11, 12, 13 via the connection means 4.

Specifically, and alternatively to FIG. 5, FIG. 6 illustrates that a cable end portion (i.e. the cable end inserted into the pulling head 2) may be enclosed by a pulling grip arrangement 3, 33, 331, 336. The pulling grip arrangement may comprise (or may be connected to) coupling means 332, 334 for attaching (connecting, coupling) the cable 1 within the first housing portion of the pulling head 2. In certain embodiments, the pulling grip arrangement 3, 33, 331, 336 may be a Kellems Grip (e.g. an endless-weave grip), or a similar suitable cable grip arrangement, able to connect (or couple) to an outer surface of the cable end portion and an inside of first housing portion.

Referring again to FIG. 7, this illustrates a pulling head assembly 2, the pulling head assembly comprising a first module 2a, being connected (or attached) via a coupling arrangement 332, 334 to a second module 2b, which may be described as a measurement body. The measurement body comprises a measurement module 5, such as a measurement module 5 as described with reference to any one of the other figures.

The pulling head 2 illustrated in FIG. 7 thus comprises a main body, or housing, 20a. The housing 20a is open at a first end to receive the cable 1 (i.e. such as an umbilical cable, as described previously). The pulling head 2 comprises attachment means 33, 331, 336, 332 for attaching (fixing) the cable 1 within the pulling head 2. The attachment means may, in certain embodiments, also comprise stabilization means A1, arranged so as to contact the housing 20a of the pulling head 2, and act to restrict movement and/or bend of the cable when attached within the pulling head 2.

The pulling head body 20a encloses, in a volume 201, connections 401, 402, 403 to at least one core, waveguide, and core (i.e. component) of the cable 1. The connected components are further connected to the measurement body 2b, via extension outward of connection means 4 through a second end of the pulling head housing 20a, and connection to the measurement body, e.g. via feedthrough 400, as illustrated.

An end 100 of the cable 1, as received (attached) within the pulling head 2a, is enclosed by a pulling grip arrangement 33. In certain embodiments, as illustrated, the pulling grip arrangement 33 may be a Kellems Grip, or any suitable arrangement. The pulling grip arrangement 33 encloses the inserted cable end portion and the connections 401, 402, 402 to the cable components. A pulling eye (or similar) 332 of the cable grip 33 extends outwardly from the pulling head 2a and attaches, via a coupling arrangement 334, to the measurement body 2b. The coupling arrangement 320, may comprise a receiving arrangement positioned to interlock (link) to the pulling eye of the cable grip. However, in certain embodiments, alternative mechanical arrangements to couple the measurement body 2b to the pulling head module 2a may be employed. The measurement module 5, comprised within measurement body 2b, is operable to perform at least one measurement (i.e. at least one test) on the attached cable 1 via the connection means 4.

Referring again to FIG. 8, this illustrates an alternative modular system of a pulling head assembly 2. The pulling head assembly 2 comprises a first module 5 being a measurement module (i.e. such as measurement module 2b, as described above), which is connected to (attached), and detachable from, a pulling head module 20. In such an example, the connection, or attachment, may be by bolts 5020 or other strong attachments means.

In other embodiments, such as shown in FIG. 9, the measurement module 5 is secured (connected) at one end to the pulling head module 20, and connected to—cable end portion 100. It will be appreciated that the measuring means 5 or measurement module described in the above-detailed aspects of the invention may detect and/or perform at least one or, or all of, the measurements discussed in detail as below.

In a first example, a measurement may comprise determining a pulling tension (i.e. a strain) between the cable 1 and the pulling or deployment means attached (arranged) via the coupling means. The measurement may comprise a measurement of bending, or twisting force, between the cable and the pulling means. The strain measurement may be performed by a strain sensor comprised within, or connected to, the measurement module 5. For example, as illustrated in FIG. 5 (and as applicable to FIGS. 6 and 7) a strain measurement module (i.e. strain measurement transducer) 582 may be in contact with an inside of the housing 30 and the transducer may be connected to measurement module 5. The measurement module 5 in certain embodiments is operable to measure the at least one strain measurement during deployment (i.e. pulling) of the cable 1 via the pulling means.

In a further example, measurement data may additionally, or alternatively, comprise a measurement of electrical resistance, capacitance, and/or inductance between (or of) a plurality of electrically conductive cores of the attached cable 1. The measurement data may further comprise a measurement of electrical resistance/capacitance/inductance between at least one electrically conductive core of the cable 1 and a terminal (electrode) provided on the pulling head, and arranged to make electrical connection to a fluid (i.e. seawater) to which the pulling head may be immersed.

In further examples, the measurement data may additionally, or alternatively comprise measuring a continuity of at least one core, waveguide, or bore, of the attached cable. In further examples, the measurement data may additionally or alternatively comprise a Time Domain Reflectometry (TDR) measurement on at least one core, waveguide, or bore of an attached cable.

The measurement may comprise obtaining data on temperature, strain, and/or another parameter at at least one position along the attached cable by means of a temperature, strain, or other sensor. In further embodiments, the temperature/strain/other measurements may be obtained by means of sending an electromagnetic signal along a waveguide to interact with a respective sensor (e.g. Bragg grating) at the position.

The measurement(s) may also include at least one a pressure measurement, for example wherein pressure is applied via the hydraulic connection to a bore of an attached cable, and measuring the fluid pressure within the bore. Alternatively/additionally, pressure ‘locked’ or sealed within a bore from an earlier process/test may be measured.

Such measurements (as described above) may be performed on either a permanent (i.e. recurring) basis, on a transient basis, and/or when receiving an instruction (trigger) to perform the measurement. The above-described measurements may be performed (i.e. measurement data may be obtained) on the connected cable during deployment (i.e. when the attached cable is being pulled via the pulling means coupled to the pulling head), before deployment, after deployment, and/or during storage.

Inside the housing of the pulling head, in certain embodiments, there is further provided a power source, or energy storage means, such as e. a battery, rechargeable battery, fuel cell, connected to, and providing power to, the measurement module 5. The power source may be comprised within the same housing portion as the measurement module, within the measurement module itself, and/or may be provided at some other location within the pulling head or pulling head assembly. For example, the power source may be provided separately, and connected to the measurement module.

In embodiments consistent with the above-detailed aspects of the invention, the measurement means (i.e. measurement module 5) is connected to a display, and transmits measurement data to be displayed to an external user. The display may be provided on the pulling head and visible to an external user, diver, or ROV camera. Alternatively, the measurement module 5 may comprise data transmission means for transmitting measurement data (i.e. wirelessly, via radio link, capacitive link, magnetic link, optical link, inductive link, and/or acoustic link), wherein such measurement data may be arranged, when received, to be displayed on a separate unit such as PC or laptop. The measurement means may comprise, or be connected to, a storage unit, or memory unit, for storing measurement data. The storage unit (or memory) may be integral to (i.e comprised within) the pulling head in accordance with any of the above-detailed embodiments.

In further embodiments, the measurement means in accordance with the above-detailed aspects of the invention is further arranged to monitor results of the at least one measurement as obtained, or stored in the memory. In other embodiments, the stored data could be recovered in real time during the process of pulling in the cable to enable improved operational efficiency or warn of conditions within, or forces applied to, the umbilical cable that could result in premature failure of the cable. The data from the monitoring means could be stored for later recovery. Recovery of the data could be after the pull-in operation but prior to connection in order to ascertain umbilical cable condition in a timely manner prior to further procedures on the cable.

Alternatively, or additionally, the measurement data could be stored for later recovery. Recovery of the data could be during a wet storage phase such that umbilical cable condition could be monitored prior to a subsequent pull-in operation. This would prevent resources being expended on an umbilical that exhibited signs of failure.

The measurement means may be further arranged to generate an alert signal according to the measurement data obtained. For example, should the strain measurement module may measure at least one strain measurement which exceeds a pre-defined threshold data for generating a strain alert signal. The strain alert signal may be indicated by means of an indication provided at the pulling head (i.e. a visual indication on the display) and/or may be transmitted (via data transmission means) to a remote location. The transmitted (or indicated) alert signal may, optionally, comprise the results of the measurement data obtained. Whilst an alert signal is thus described with reference to a strain alert, it will be appreciated that an alert signal may be similarly generated (transmitted, displayed) with reference to any such measurement described above.

In further embodiments consistent with the above-detailed aspects of the invention, the measurement means (i.e. measurement module 30) is connected to, and controllable via, a user interface. Such a user interface may be provided on the display described above (i.e. as part of the pulling head or remotely). The user interface may incorporate settings for controlling (triggering, initiating) the monitoring means (i.e. in order to perform a test, or measurement), for adjusting measurement types and parameters, and/or settings for collecting (retrieving, recovering) stored measurement data.

When cable 1 is attached to the pulling head, as detailed in any of the above-detailed embodiments, the measurement means (measurement module) may be operated to perform a measurement on the attached cable before spooling (i.e. onto the cable lay vessel for positioning). Additionally, or alternatively, the measurement module may be operated to perform a measurement (or test) during spooling. In such cases, the data could be obtained and recovered during the spooling process to ensure (or test) that the cable remained in as manufactured condition prior to transit to the installation site, If the monitoring means was installed after the manufacture of the umbilical cable but prior to the cable lay vessel transit to the lay point then data could be obtained and recovered during the transit voyage to ensure that the umbilical cable remained in as manufactured condition prior to overboarding and deployment subsea.

Alternatively, the pulling head and cable may be attached (connected) after the cable is spooled (i.e. the spooled cable on the cable lay vessel or other infrastructure). In such cases, the measurement module 5 may perform testing before un-spooling (or pulling), during un-spooling (or pulling). Additionally (or alternatively), the measurement (or testing) may be performed after un-spooling, and before disconnecting (removing) the pulling head and connecting to the offshore infrastructure.

In further examples, the measurement(s) may performed after a cable is left (stored), for example in an underwater (subsea) position, for an extended time period, for example after a wet storage phase.

The monitoring means may be arranged to interact with other monitoring systems of a similar or different type to create a measurement system array.

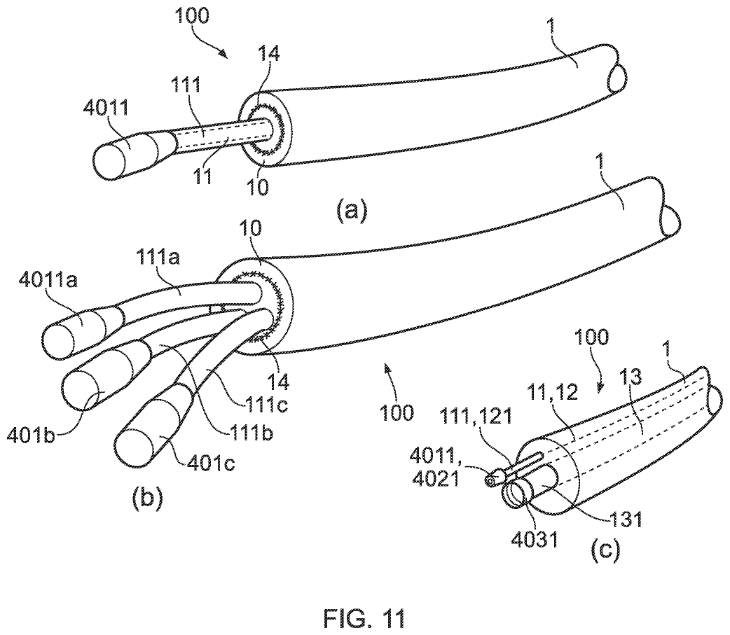

It will be appreciated that cables maybe terminated with one or more connectors prior to connection to a smart pulling head, smart protection cap, or measurement apparatus embodying the invention in order to facilitate that connection. This termination will typically comprise providing one or more of a mechanical termination or connector, an electrical termination or connector, a waveguide terminal or connector, and a hydraulic or fluidic terminal or connector. FIG. 11 is a highly schematic representation of three terminated cable ends, each cable being terminated but with no mechanical termination. In FIG. 11(a) the cable is a power cable with no mechanical termination. The armour layer 14 (which may also be described as comprising a plurality of strength members) can be seen inside the outer layer 10 of the cable. This power cable comprises a single conductive core 11. In the termination process a portion of the outer layer and armour layer has been stripped back to expose a portion of the length of the single conductive core and it's insulation 111. An electrical connector 4011 has been attached to the end of the conductive core 11 and this connector is arranged to mate with a corresponding connector of measurement apparatus (or smart protection cap, or smart pulling head). In this example the electrical termination or electrical connector 4011 is adapted to dry-mate with the corresponding connector of the measurement apparatus. In other embodiments, connectors able to mate in a wet environment may be used, but there are advantages in attaching measurement apparatus to the cable in a dry environment, in that the integrity of the connections may be improved, and ingress of water into the cable end can be avoided (the measurement apparatus or smart pulling head or protection cap can be arrange to form at least one seal to the cable to prevent water ingress). Referring to FIG. 11(b), this shows the end of another power cable with no mechanical termination. This cable comprises a plurality of conductive cores (three of them in this example, one for each phase of a three phase electrical supply). The cable can be regarded as comprising three electrical sub-cables, each with a respective conductive core and surrounding insulation 111a,b,c. Each sub-cable has been terminated with a respective electrical connector (e.g. male or female, or other suitable form) for mating with a corresponding connector of measurement apparatus). Again, the connectors 4011a, b, c are dry-mate connectors (dry-mate electrical terminations). Referring now to FIG. 11(c), in this example the cable 1 comprises a bore 13 for carrying a fluid (i.e. a gas or a liquid), in particular for carrying hydrogen. In this example the bore (which may also be referred to as a pipe or tube component of the cable) is for carrying gaseous hydrogen along the cable. This hydrogen may, for example, be a product of a renewable energy system, in which generated electricity has been used to split water into hydrogen and oxygen by electrolysis. It will be appreciated that, although not shown in the figure, the cable may comprise more than one such bore, which could be used to carry the same or a different gas and/or liquid (e.g. to carry the oxygen obtained from electrolysis of water). The cable also comprises an electrical core 11 or waveguide 12 for carrying signals along the cable. The bore 13 is inside a tube 131, and this tube has been terminated with a hydraulic or fluidic connector 4031. In this example the hydraulic connector 4031 comprises an internal thread for mating with the external thread of a corresponding connector on measurement apparatus. The conductive core 11 or waveguide 12 has also being terminated with an electrical connector 4011 or waveguide connector 4021 as appropriate. The cable is therefore able to carry gas, and signals, and measurement apparatus embodying the invention may be attached to it, to provide monitoring of at least one of its components.

With regard to cables for carrying hydrogen, they may be adapted to carry hydrogen in its gaseous state, as mentioned above. Alternatively, or additionally, cables may be adapted to carry liquid hydrogen. The cables may, for example, be highly insulated (and may include vacuum insulation) to enable liquids at very low temperatures to be carried, and/or may include heating means (e.g. heating traces) operable to inhibit or prevent conveyed liquids and/or gases from solidifying/freezing and blocking the cable. In certain embodiments, the cables may comprise at least one bore (or pipe or tube) for carrying ammonia, for example in liquid form.

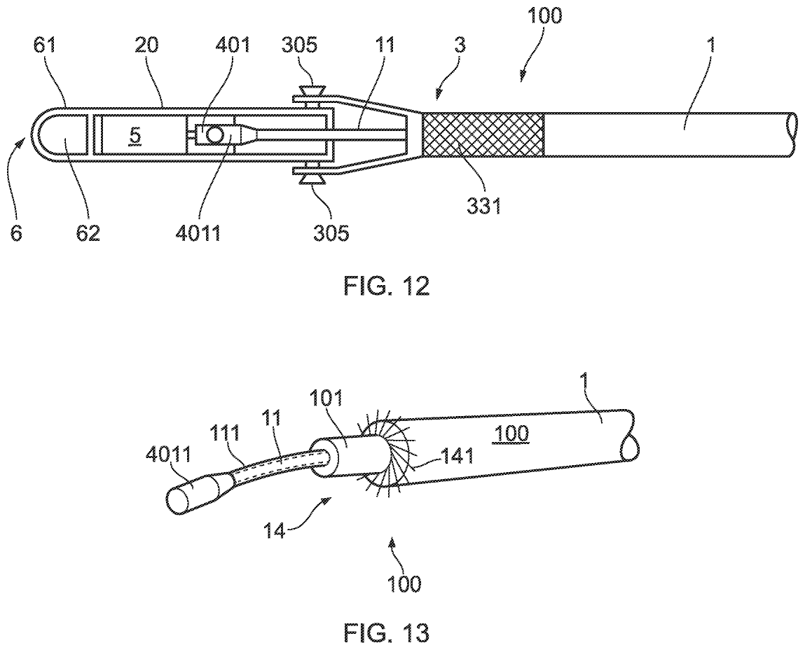

Referring now to FIG. 12, this shows a pulling head attached to the end of a terminated cable. The cable has been terminated with at least one electrical connector 4011 to provide easy connexion to at least one conductive core 11. However, there is no mechanical termination to the cable end. Smart functionality is provided within the pulling head in the form of smart monitoring means or measurement apparatus 5 either located in a space within the pulling head housing 20 or installed within the pulling head. The mechanical attachment between the pulling head and cable end is provided by a pulling sock or sleeve 3, which may also be referred to as a Kellems grip, comprising a plurality of woven members 331. This woven mesh or sock of members 331 engages an external surface of the outer portion of the cable 1 and provides temporary mechanical termination. Lugs 305 are provided on the pulling head to secure the Kellems grip (pulling sleeve or sock, e.g. woven). The pulling head comprises a housing 20 inside which there is provided smart monitoring means or measurement apparatus 5 electrically connected to the conductive core 11 by means of an electrical connector 401 dry mated with the electrical termination or connector 4011 provided on the cable. Although only one terminated electrical core 11 is shown in the figure, it will be appreciated that in alternative embodiments the cable may comprise a plurality of conductive cores, each terminated by a respective electrical connector 4011. The body 20 of the pulling head provides protection for the measurement apparatus 5 inside and for the electrically terminated end of the cable. The pulling head also comprises attachment or coupling means 6, for attaching/coupling to pulling means, in the form of a loop 61 providing an eye 62.

Referring now to FIG. 13, this shows the terminated end of another cable. The cable has been terminated so as to expose some of its armour or other strength members, but has not been provided with any mechanical pre-terminations. A portion of the end of the cable has been stripped back to expose a portion of an electrical sub-cable 111 and a portion of an inner layer or section 101 of the cable. Part of the armour layer 14 has been exposed, such that a plurality of armour components or strength members 141 are exposed; they are no longer encapsulated by the outer layer of the cable. In other words an outer sheath of the cable has been stripped back to expose the armour or other strength members. The cable is again a power cable with at least one conductive core 11, but only one sub-cable 11, 111 is illustrated in the figure for simplicity. The electrical sub-cable has been terminated with a dry mate electrical termination or connector 4011. Again, in embodiments where there are a plurality of electrical sub-cables, each will typically be provided with its own electrical connector.

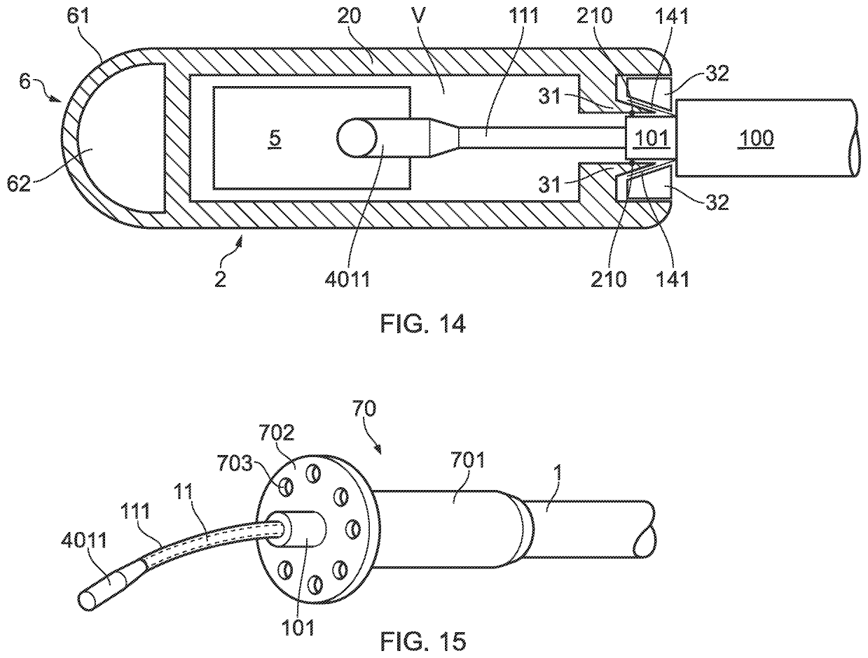

Referring now to FIG. 14, this shows the terminated end of a cable, such as that shown in FIG. 13, mechanically attached to, and electrically connected to, a pulling head. Smart functionality is provided within the pulling head for attachment to cables with no mechanical pre termination. The mechanical attachment between the pulling head and cable end is provided by clamping the exposed armour or strength members 141 between clamping members 31, 32 of the pulling head. Thus, although the cable is provided with no permanent mechanical termination, the pulling head is able to firmly grip the cable end via the exposed armour members 141. The clamping member 32 in this example is in the form of a screw in locking ring. The locking ring screws in (to a suitably threaded recess in the end of the pulling head body 20) to clamp the armour or strength members against a tapering surface provided in the pulling head body (as part of that recess). The pulling head is also arranged to provide a seal 210 between its housing 20 and the exposed inner portion 101 of the terminated cable end so as to prevent the ingress of water to the internal volume V of the housing 20 in which the measurement apparatus 5 is located. This water blocking seal can take a variety of forms, and for simplicity in the figure is shown in a form of just a single O-ring 210. Other embodiments may employ alternative sealing arrangements. As mentioned, the body 20 of the pulling head houses smart monitoring means or measurement apparatus 5 which may be in the form of either a module located within the pulling head or installed within the pulling head. In other words, the measurement apparatus 5 maybe an integral part of the pulling head, or may be a module insertable inside the pulling head housing. The measurement apparatus includes at least one dry mate electrical termination or connector for mating with the corresponding electrical termination 4011 on the terminated cable end. Again, although only a single try mate connector 4011 is shown in the figure, in alternative embodiments there may be a plurality of dry mate electrical connectors (e.g. plugs or sockets) and/or one or more dry mate waveguide connectors and hydraulic or fluidic connectors. For simplicity, the electrical connector of the measurement apparatus 5 that mates with the electrical connector or termination 4011 of the terminated cable is not shown in this figure. The pulling head also comprises attachment means 6 for attachment two or coupling with suitable pulling means.

Referring now to FIG. 15, this shows the end of a cable that has been terminated both electrically and mechanically. The cable is again a power cable with at least one electrical sub cable 11, 111 and it has been provided with a mechanical termination. The mechanical termination is intended to be permanent (it is a permanent, or final fit), in the sense that it remains on the cable end during its storage, deployment, recovery, and subsequent connection to other apparatus. In the termination process, the cable end has been provided with a termination structure 70 (which may also be referred to as a termination head), comprising a mechanical connector in the form of a flange 702 provided with an array of holes 703 for bolting the flange to other apparatus. The termination head 70 also comprises an elongate body portion 701, which encloses/encapsulates a portion of the cable end. It will be appreciated that the cable end is mechanically connected to the flange 702 by suitable means (which may comprise connection to the armour or strength members, or other arrangements). In addition to the mechanical pre-termination, the electrical sub-cable 11, 111 has been terminated with an electrical connector 4011. The electrically-terminated sub-cable (or sub-cables in other embodiments) extends forwards from the flange 702, as does an exposed portion of the inner section 101 of the cable.

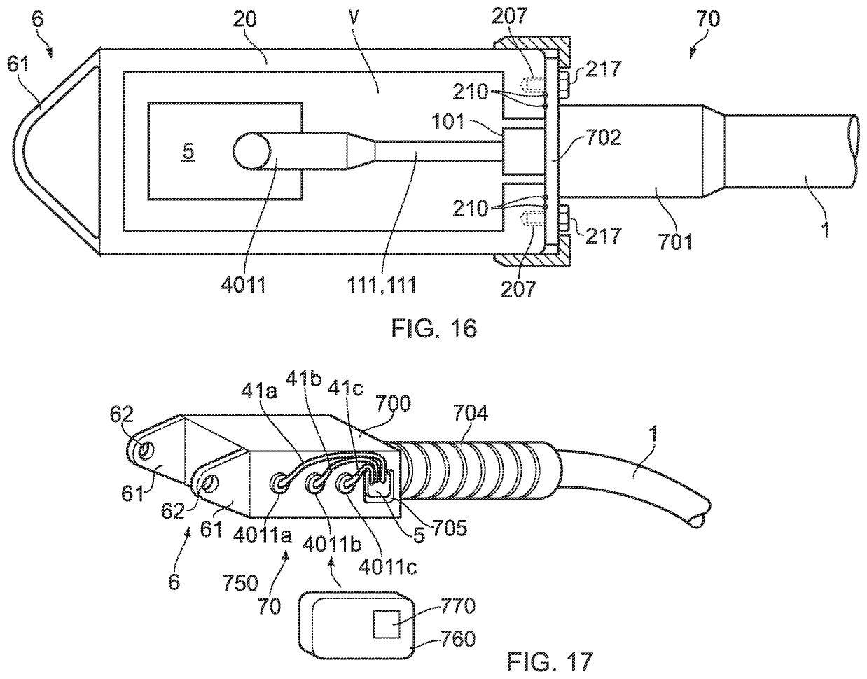

Referring now to FIG. 16, this shows the terminated end of a cable such as that in FIG. 15, mechanically and electrically connected to a smart pulling head embodying an aspect of the invention. Again, smart functionality is provided within the pulling head for attachment to cables with pre-installed mechanical terminations, such as the flange 702. The cable end has been pre terminated, electrically and mechanically, and the mechanical termination is intended to be a permanent fit or permanent fixture. In other words the cable is provided with permanent pre-installed mechanical termination. Mechanical attachment of the terminated cable end to the smart pulling head is provided, in part, by bolting the flange 702 against the corresponding surface of the pulling head body or housing 20, with a plurality of bolts 217, each passing through a respective flange hole 703 and received in a respective blind threaded hole 207 in the housing 20. Additional clamping force is provided by a locking ring which has an internal thread adapted to engage an external thread on the housing 20. The locking ring provides an additional strain path from the termination means to the pulling head. The locking ring is screwed onto the housing 20 and exerts a clamping force distributed around the circumference or perimeter of the flange 702, and this provides a distributed clamping in addition to the discrete clamping provided by the plurality of bolts 217. A seal is provided between the flange 702 and the housing 20 in this example in the form of a dual O-ring water blocking seal 210. Thus, with the flange 702 clamped to the housing 20, an interior volume V of the housing is a sealed enclosure and water is inhibited from passing into it by the seal 210. In alternative embodiments, the interior volume of the housing 20 may be arranged to be free flooding. The terminated electrical sub cable 11, 111 and the exposed section of the inner part 101 of the cable extend from the flange 702 into the interior volume V. The measurement apparatus 5 is electrically connected to the electrical sub cable 11, 111 by means of an electrical connector (not shown) mating with the connector 4011. In this example, just one electrical sub-cable and connector 4011 is shown, but in alternative embodiments the apparatus 5 may be connected to a plurality of cable components via a plurality of suitable connectors (electrical, optical, and/or fluid). The connectors 4011 in this example are dry-mate, but may be wet-mate in other embodiments. The measurement apparatus 5 which may also be referred to as smart monitoring means may again be provided either in the form of a removable/insertable module located within the pulling head, or may be an integral part of the pulling head.

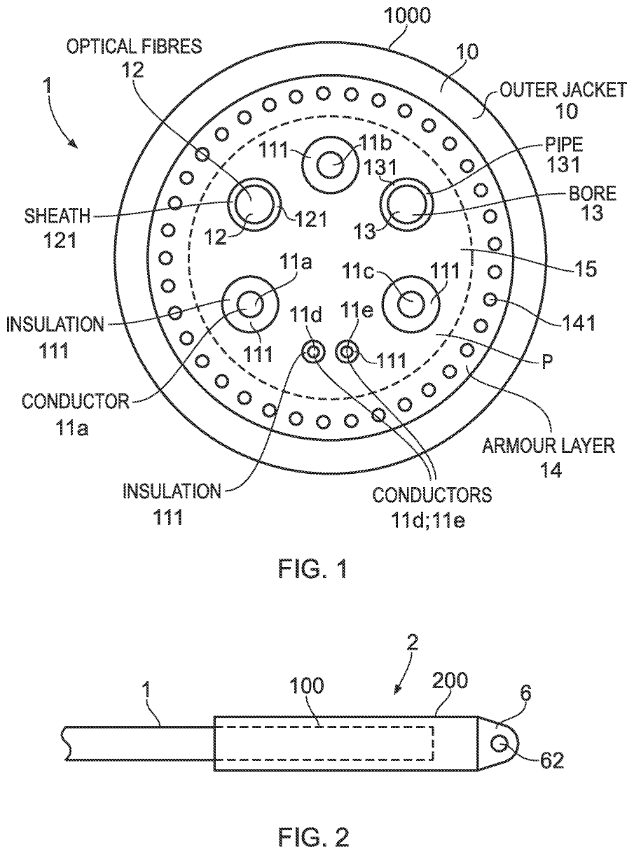

It will be appreciated that the measurement apparatus 5 illustrated and described with reference to any of FIGS. 12 to 35 may incorporate any feature or any combination of features of the measurement apparatus or monitoring means described elsewhere in this specification, for example with reference to any one of FIGS. 1 to 11.

Referring now to FIG. 17, this shows the end of a cable 1 (a sub-sea umbilical in this example) terminated by (i.e. fitted with) a permanent termination head, and connected to smart monitoring means 5 (measurement apparatus). The permanent termination head 70 provides permanent electrical and mechanical termination of the cable end. The termination head 70 comprises a housing 700 with integral flanges 61, each providing a respective pulling eye 62 for coupling to pulling means. The housing 700 is also connected to a bend restrictor 704 which encloses and provides mechanical support to a portion of the end of the cable 1. The bend restrictor may in certain embodiments be moulded or articulated. Although not shown in the figure, internal components of the cable 1 pass into the housing 700 where they are terminated by suitable connectors. In this example the cable comprises three conductive cores, or three electrical sub-cables, and each is terminated by a respective electrical connector 4011a, b, c in the termination head structure 70. In this example these electrical connectors 4011 are accessible at an outer wall 750 of the housing 700. The wall 750 is also provided with a recess 705 in which measurement apparatus 5 is housed. The measurement apparatus may be secured in this recess 705 by any suitable means. A plurality of electrical connections 41a, b, c connect the measurement apparatus 5 to the connectors 4011 and so enable the measurement apparatus to perform measurements on the electrical sub-cables, for example while the cable end and attached termination head 70 are being stored, deployed, recovered from a subsea location, pulled, or otherwise being stored or handled. Thus, the measurement apparatus or smart monitoring means 5 is housed within a recess 705 in the termination head for protection, and a plurality of connections are provided to the electrical cores of the umbilical cable 1. The cable has been provided with a permanent termination head, and after a pulling or recovery operation and interrogation of the measurement apparatus 5, the measurement apparatus 5 can be disconnected and removed from the recess 705, and then the terminated end of the cable may be attached to other apparatus by means of the easily accessible connectors 4011 on the exterior surface 760 of the housing 700. In certain embodiments the apparatus may further comprise a cover 760 and means for attaching the cover 760 to the housing 700, e.g. to the sidewall 750, to provide mechanical protection to the connections 41 and measurement apparatus 5 during handling of the terminated cable end. The housing 760 may comprise a transparent window 770 to facilitate viewing of a display of the measurement apparatus 5, for example, and/or to facilitate transmission of wireless signals to and from the measurement apparatus 5.

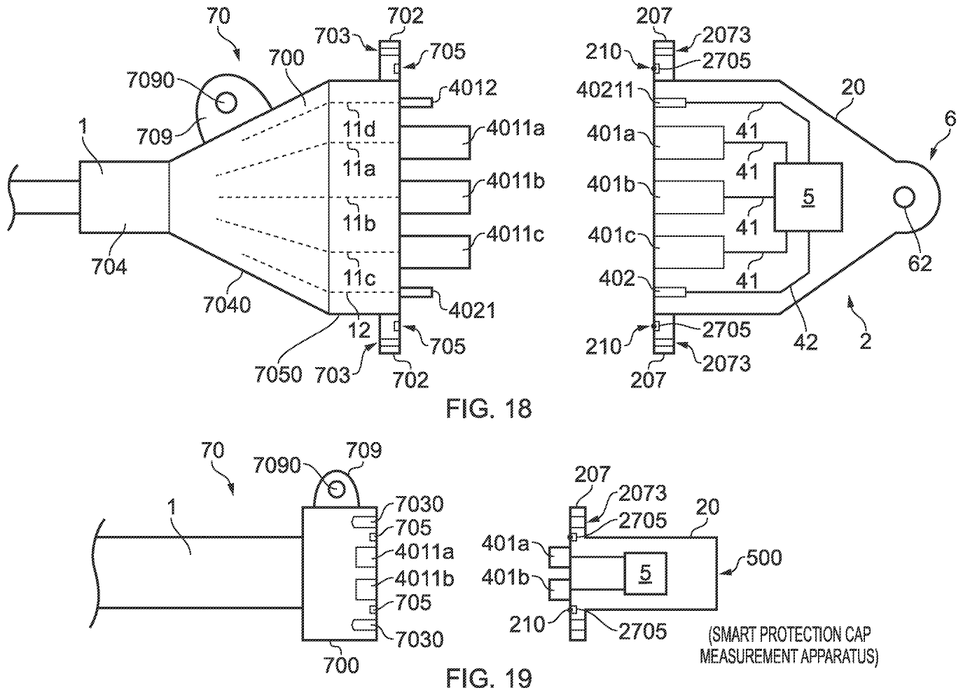

Referring now to FIG. 18, this shows in highly schematic form the end of a cable 1 terminated by a termination head or termination structure 70. The termination head 70 comprises a housing 700 comprising a first cylindrical portion 704, an outwardly tapering portion 7040, and a second cylindrical portion 7050. A flange or lug 709 is attached to the housing 700 and provides an eye 7090 for pulling and/or lifting the termination structure and attached cable. The termination head 70 includes mechanical termination comprising a flange 702 provided with a plurality of holes 703 and a groove 705 for receiving an O-ring. The cable in this example comprises three conductive power cores 11a,b,c, or three electrical power sub-cables, each for carrying a respective electrical phase. The cable also comprises an electrical signal wire 11d and an optical fibre 12. The termination head comprises three respective power connectors 4011a,b,c, each electrically terminating a respective power core, an electrical signal connector 4012 terminating the signal wire 11d, and an optical connector 4021 terminating the optical fibre. The figure also shows monitoring apparatus 2 (in the form of a smart protection cap or smart pulling means) comprising a housing 20 with an integral a flange 207, with holes 2073 for bolting to the flange 702, a groove 2705 and O-ring 210 for forming a seal when clamped to the flange 703. The monitoring apparatus also comprises a plurality of electrical power connectors 401a,b,c for dry-mating with the corresponding power connectors of the terminated cable, an electrical signal connector 40211 for dry-mating with the signal connector 4012, and an optical connector 402 for dry-mating with the optical connector 4021. Inside the housing 20 there is provided measurement apparatus 5, connected to the electrical connectors by suitable electrical connections 41 and to the optical connector by optical connection 42, and operable to perform a plurality of measurements on the components of the terminated cable (when attached/connected to the apparatus 2), in both dry and wet environments (e.g. above water, and sub-sea). The measurement apparatus may comprise any feature or combination of features described elsewhere in this specification. The housing 20 is also provided with means 6, 62 for attaching to pulling or lifting means, but in other embodiments that means 6 may be omitted. In this example, the connectors on the termination head are general indicated as male connectors, to be received in corresponding female connectors of the monitoring apparatus. However, in alternative embodiments, other forms of connectors may be used. Thus, the termination head and monitoring apparatus may each comprise at least one male connector, at least one female connector, at least one other form of connector, or any combination of male, female, and other connectors.

Referring now to FIG. 19, this shows another cable end terminated by a termination head 70, and a smart protection cap 500 for attaching to it. The termination head 70 comprises a housing 700 and two electrical connectors 4011a,b, each in the form of a female socket and terminating a respective power core of the cable. The head 70 thus provides electrical termination, and also mechanical termination; the housing is rigid and comprises threaded holes 7030 for receiving bolts. An end surface of the housing 700 is also provided with a groove 705 to receive an O-ring, and the head 70 includes a lifting flange 709 and eye 7090. The smart protection cap 500 comprises a rigid housing 20 with an integral flange 207 and bolt holes 2073, for bolting/clamping the flange to the head 70 (bolts being received in the threaded holes 7030). A groove 2705 is provided in the face of the housing adapted to mate with the corresponding face of the head 7, and an O-ring 210 is also provided, seated in the groove 2705. The cap 500 includes male electrical connectors 401a,b for mating with the corresponding connectors 4011a,b of the head, and measurement apparatus 5 is electrically connected to those electrical connectors (and is housed in the housing 20). Lifting/pulling of the terminated cable end and attached cap is achieved by engaging with the flange/eye 709/7090 of the termination head, not by engaging the cap 500. In this example, the cap provides a seal to the termination head, and provides protection to the electrically terminated power cores, as well as monitoring capabilities, during storage and/or handling.

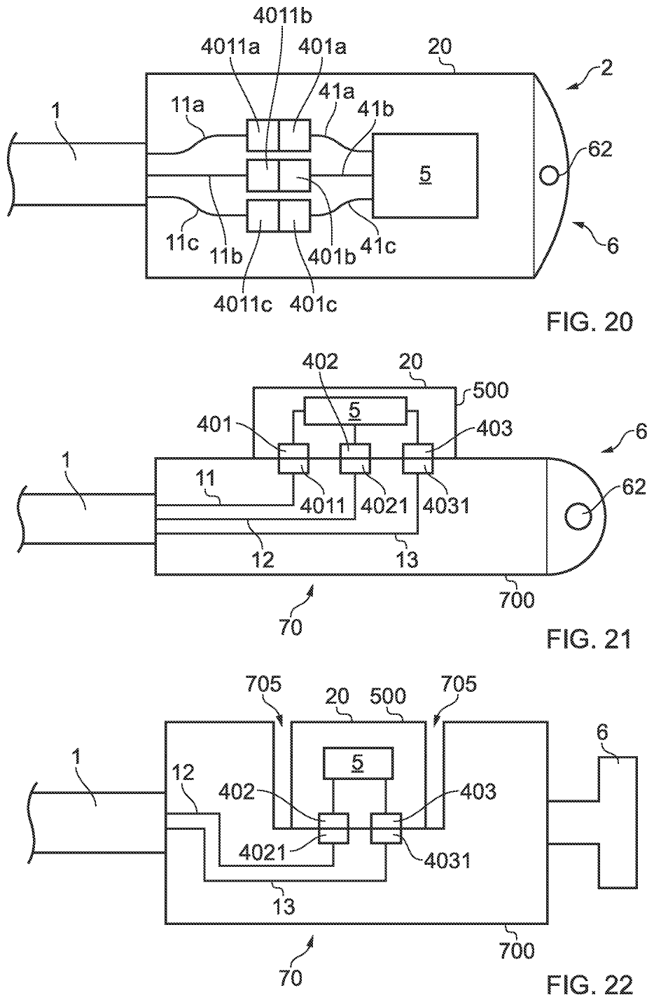

Referring now to FIG. 20, this illustrates a smart pulling head embodying the invention and attached to a terminated cable end. In this example the cable end has been terminated with a plurality of electrical connectors 4011a,b,c, each terminating a respective conductive core 11a,b,c. The smart pulling head 2 comprises a corresponding plurality of electrical connectors, 401a,b,c, each mating with a respective electrical connector of the terminated cable, and connected to measurement apparatus 5 by suitable electrical connections (wiring, cabling, conductive tracks etc.). The measurement apparatus is operable to perform measurements on the attached cable at any time, and in particular while pulling the cable via the coupling/attachment means 6. The housing 20 provides mechanical protection, and protection against water ingress, to the apparatus 5 and to the terminated ends of the cable cores.

Referring now to FIG. 21, this shows a terminated end of a cable, with a smart protection cap attached. The cable 1 has been terminated with a termination head/structure 70 that comprises a housing and integral attachment means/coupling means 6 for attachment to a meand of providing a pulling force. Thus, the cable is to be pulled via its termination head 70. The termination head also comprises a plurality of connectors 4011, 4021, 4031 respectively terminating a power core 11, an optical cable 12, and a gas-carrying pipe 13 of the cable. These connectors are accessible at a surface of the housing. A smart protection cap 500 is attached to the housing, providing a degree of protection to the connectors. The cap 500 includes a corresponding plurality of connectors 401, 402, 403, shown mated with the connectors of the termination head 70, and measurement apparatus 5 operable to perform a variety of measurements on the attached cable, e.g. while it is being handled/pulled via the termination head.

FIG. 22 shows another cable 1 terminated by a termination head 70. The head 70 provides mechanical termination and coupling means 6 in the form of a rigid member (e.g. bar or T-bar) for attaching a pulling rope or cable. The head 70 includes an optical connector 4021 terminating an optical sub-cable 12, and a gas connector 4031 terminating a sub-pipe 13 for carrying hydrogen. The head's housing 700 provides a recess 705 or enclosure, inside which is located smart monitoring apparatus 500, including optical and gas connectors 402, 403 mated with the connectors of the head. The apparatus 500 includes measurement apparatus 5, operable to perform measurement son the attached cable's optical sub-cable 12 and hydrogen pipe 13 in a variety of environments (including sub-sea, while being pulled).

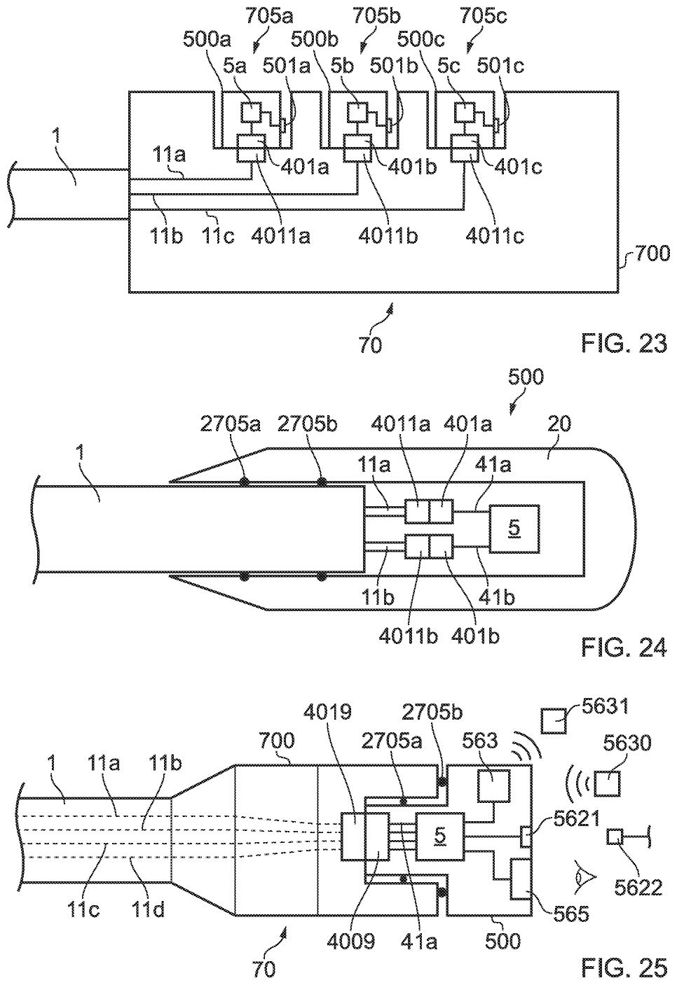

FIG. 23 shows another cable 1 terminated by a termination head 70 comprising a housing 700, and a plurality of electrical connectors 4011a,b,c each terminating a respective conductive core 11a,b,c of the cable. The housing provides a plurality of recesses 705a,b,c, with one of the connectors 4011a,b,c accessible within a respective recess. Inside each recess is located a respective measurement module 500a,b,c, each module comprising a respective electrical connector 401a,b,c mated with one of the head connectors 4011a,b,c. Each module 500 also comprises a respective contact or terminal 501a,b,c for contacting fluid in which the apparatus is immersed (e.g. sea water), and respective measurement apparatus 5a,b,c connected to the connector 401a,b,c and terminal 501a,b,c. In use, each module is operable to make measurements on a respective one of the cable cores 11a,b,c, such as resistance and/or capacitance between core and sea-water. In certain embodiments, the modules 500a,b,c are arranged to communicate with one another by suitable means, e.g. by wireless communication, but in other embodiments the modules operate in isolation of one another. It will be appreciated that each module 500a.b,c may incorporate any feature or any combination of features of any of the measurement apparatus (or measuring means, or monitoring means) described elsewhere in this specification.

The termination head may also be described as a termination assembly. Termination Assembly and Termination Head are names used in the subsea oil and gas industry (e.g. ‘umbilical termination assembly/head’, commonly abbreviated to UTA or UTH).

Thus, in certain embodiments the cable is be pre-terminated, and the termination head 70 comprises one or more sockets and/or one or more plugs. Monitoring/measurement apparatus in the form of small plug-in/plug-on module (device) for each plug/socket may be used. Each device may be adapted to log test measurements, and although certain embodiments are adapted to provide an indication of results while sub-sea, other embodiments may not be, and instead may be adapted to be interrogated (to recover data from the measurements) when recovered to the surface, for example. These individual, self-contained, and self-powered (e.g. by battery) modules or devices in certain embodiments are arranged also to communicate with each other. Providing measurement results by a display to divers/ROVs is an optional feature. Another optional feature is that the devices may be adapted for communication to divers/ROVs, or other sub-sea apparatus via acoustic, optical or subsea radio signals, for example for subsequent transmission to the surface.

In examples where the cables are umbilicals (e.g. for applications <1 kV), the connectors may have a plurality of cores (e.g. 2 cores, between 3 and 12 cores, or more), and the measurement apparatus may be configured to test between the cores (e.g. measure resistance and/or capacitance between them) and also from each to seawater. For high power cables (e.g. for renewable energy generation applications) it might be necessary for the cable (or its termination head) to have one connector per core to handle the power, so three high power connectors for a three phase system. However, in alternative examples these three phases/connectors may be grouped together into a single unit. If separate connectors are used for each power core, an individual measurement module/device/unit may be provided for each connector, and may only be able to perform electrical tests from its respective core to earth (not from core-to-core). To test core to core the measurement apparatus may comprise one test unit with a plurality (e.g. three) connectors, or may comprise a plurality of (e.g. three) test units which may be connected together and cooperate. Again, a built-in display in an optional feature of certain embodiments, and the test units may be able to export data wirelessly and/or via a physical connector (e.g. plug/socket), so that they can be interrogated after recovery.

It will be appreciated that a plug/socket in a termination head may be a connector for just one cable component (e.g. conductor core), or alternatively may be a connector to a plurality of components. For high power cables, a single (i.e. dedicated) plug/socket may be provided for each power core. Each cable could, for example, be a single-core cable with considerable cross sectional area, but in alternative examples the cable could be multi-core. Some inter-array cables are three phase cables. For high voltage operation, the cores may be split out to individual connectors due to the power transmission (and heat) requirements. Thus, a three-phase cable may have three connectors, one for each power core. One known cable (rated for 8 kV) has all three phases in one connector, whereas others (rated for 10 kV and 45 kV) have single connectors per core. The fibre-optic components of certain embodiments may have separate connectors for each waveguide, or may have a plurality of waveguides/channels coming through a single connector (or a pair of connectors for redundancy), as there are not the same power/heating factors/problems as with high electrical power transmission.

In examples where each power core has its own plug/socket and its own plug-in/plug-on measurement apparatus, each measurement apparatus may be configured to test resistance of its respective connected core, capacitance to sea water, and/or make TDR measurements on that core. However, in alternative examples, individual measurement modules/devices may be interconnected to other cores and apparatus via interconnections using data cables or other forms of data interconnections (ultrasonic, optical, or subsea radio/wireless, for example). If individual test modules, connected to just one respective core, are used to measure individual core properties, they may not be able to test insulation between cores, or continuity around the loop (depending on if open-circuit or short-circuit at the far end). This could be overcome, however, by a physical interconnection between the modules/units (and may need a common potential as a reference to allow measurement).

FIG. 24 illustrates the terminated end of a cable attached to and protected by a smart protection cap embodying an aspect of the invention. The smart protection cap 500 includes electrical connectors 401a,b mated with corresponding electrical connectors 4011a,b terminating electrical power sub-cables 11a,b of the cable 1. The smart protection cap includes measurement apparatus 5, connected by suitable means 41a,b to the electrical connectors 401a,b, and operable during use to perform measurements on the power sub-cables 11a,b of the attached cable 1 in a variety of environments, including subsea. The smart protection cap 500 includes first and second seals 2705a,b arranged to provide a watertight seal between the cap and exterior surface of the cable end to prevent the ingress of water into an interior volume and so provide a degree of protection, both mechanical and from sea water, to the terminated ends of the sub-cables 11a,b and to the measurement apparatus 5.

FIG. 25 illustrates a terminated end of a cable 1 attached to smart monitoring apparatus 500, which may also be referred to as a smart protection cap, embodying the invention. The cable 1 comprises a plurality of conductive cores 11a,b,c,d and all four of these cores are terminated by a single connector 4019. In other words, the connector 4019 provides for individual, separate electrical connection to each of the cores 11a,b,c,d by mating with a corresponding connector 4009 of the cap 500. The cap is shown inserted (i.e. plugged) into an end of the termination head, with a portion of the cap 500 received within a recess in the housing 700. In this position, the multi-connector 4009 of the cap 500 mates with the multi-connector 4019, and provides individual, separate connection of the cap's measurement apparatus 5 to the plurality of cores 11a,b,c,d. The arrangement includes two seals 2705a, 2705b between the cap 500 and head 70. A portion of the cap not inside the recess houses a wireless transceiver 563 for communicating wirelessly with external equipment (such as data receiver 5631 and controller 5630), a data connector 5621 to enable direct connection to a suitable external connector 5622 for receiving and/or exporting data, and a display or indicating means 563 for providing a visible indication of measurement results and/or alert signals to a user in close proximity (and/or to a diver, or ROV).

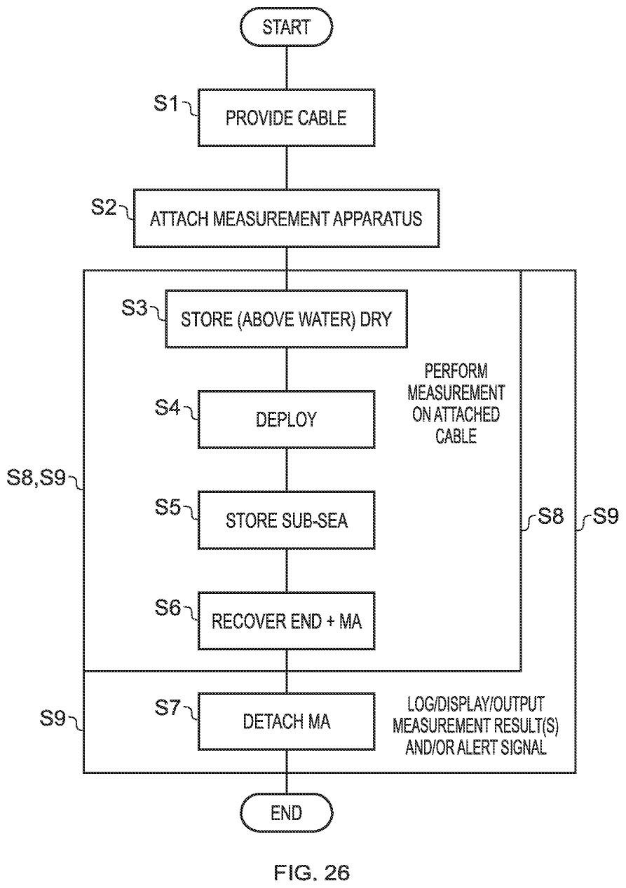

FIG. 26 illustrates steps in a method embodying the invention. In step S1 a cable is provided, and this can be terminated or unterminated. Then, in step S2, measurement apparatus is attached to the end of the cable so as to make connection to at least one component of the cable. Step S3 is an optional step, in which the cable with measurement apparatus attached may be stored in a dry (e.g. above water or out of water) environment for a period of time. Then in step 4 the cable is deployed (or laid), in the sense that the cable end with measurement apparatus attached is located in a sub-sea environment. Step S5 is another optional step, where at least the end of the deployed cable with attached measurement apparatus remains at the subsea location for a period of time. Then in step S6, the end of the cable with measurement apparatus attached is recovered, typically by pulling, to place the cable end and attached measurement apparatus in an above water environment, such as on a ship, or other floating or anchored platform, on some structure rigidly attached to the sea bed, or to dry land. Then, in step S7, the measurement apparatus is detached. At any time while the measurement apparatus is attached to the cable, it may be operated to perform one or more measurements on the attached cable (step S8). Similarly, at any time after the first measurement has been made on the attached cable, the measurement apparatus may be operated (step S9) to log, display, or output the measurement results, an/or to generate and log, display, or output an alert signal.

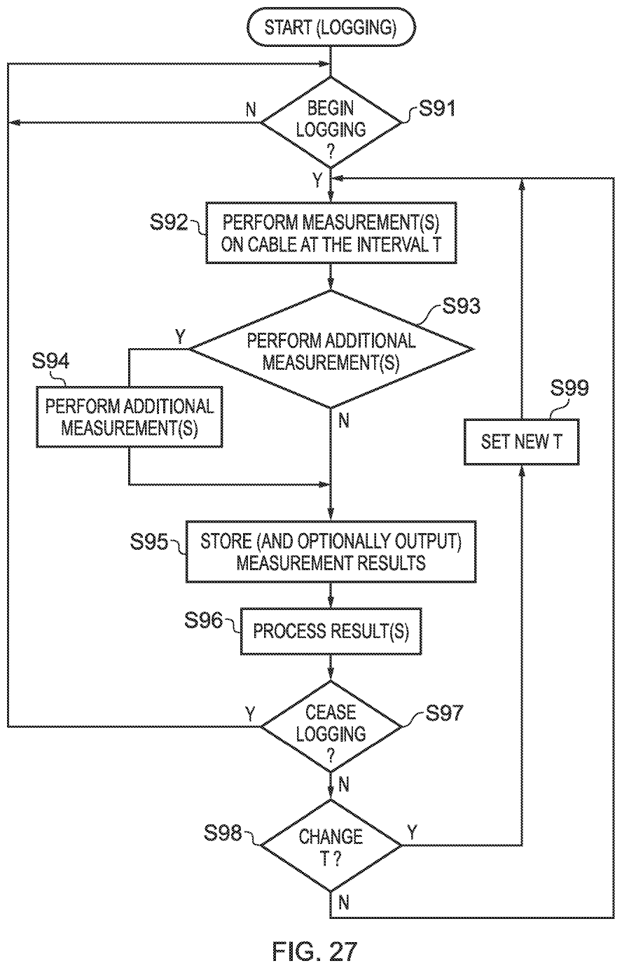

FIG. 27 illustrates steps in a data logging method which may be incorporated in embodiments of the invention. In step S91 The measurement apparatus makes an assessment of whether it should begin making measurements on an attached cable and logging the measurement results. This assessment may comprise determining whether a control signal has been received to initiate measurement and data logging, for example from an external source such as a remote operator or operator in close proximity, sending a wireless control signal to the measurement apparatus. Alternatively, or additionally, this assessment may comprise determining whether or not the measurement apparatus has been pre-programmed to begin measurements and data logging at this time. Additionally or alternatively, this determination may comprise monitoring external conditions or making measurements on the attached cable and monitoring the measurement results, although not necessarily logging them yet, to determine whether those measurements indicate that data logging should commence. For example, if the measuring means determines that deployment of the cable and/or pulling of the cable has begun, that could be the trigger for the measurement apparatus to begin logging measurement results. This detection of deployment or detecting of a pulling operation can be achieved in a variety of ways, for example by detecting immersion of the measurement apparatus in water and/or monitoring of signals from a strain sensor provided in the measurement apparatus or smart pulling head. If step S91 determines that logging of data should begin, the method proceeds to step S92 in which at least one measurement is performed on the attached cable at a regular time interval T. In other words the measurements are made at a particular frequency. Instep S93 a determination is made whether to perform additional measurements, i.e. measurements not necessarily on the attached cable components. Such measurements may comprise measurements of strain sensors, measurements of environmental conditions such as temperature or pressure, and/or measurements of internal conditions of the measurement apparatus, such as battery condition (charge state). For example, if the battery charge level is low, the apparatus may wish to reduce the frequency of measurements (i.e. increase the time interval between measurements) to conserve power. If measurements of strain indicate high pulling forces being applied, which could damage the cable, the frequency of measurements may be increased, to provide more results during this period. So, additional measurements may optionally be made (step S94). In step S95 the measurement results (from measurements on the attached cable and optionally from the additional measurements) are stored (i.e. logged) in suitable memory of the apparatus, and those results may optionally be output. Then, in step S96 the measurement results are processed (automatically, by the measurement apparatus). In S97, a determination is made whether to cease data logging (e.g. has a signal to cease been received, is the apparatus programmed to cease at this time, do the measurement results indicate that logging can cease?). If logging should continue, a determination is made of whether to change the frequency of taking measurements (i.e. to change time interval T (and this can take account of various factors, including those discussed above). If T should be changed, it is re-set in S99, and measurements continue at the new time interval.

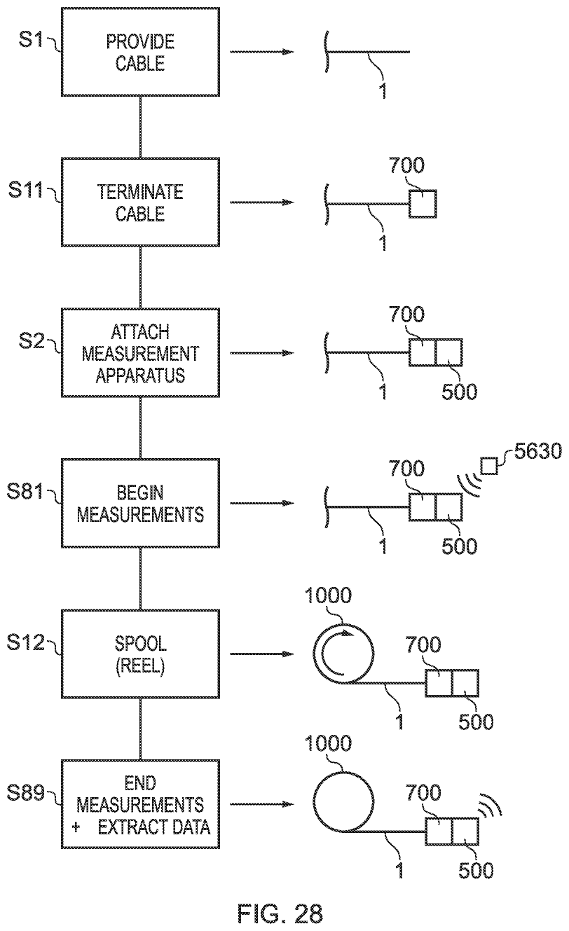

FIG. 28 illustrates steps in a method in which the measurement apparatus is used to perform measurements on the cable during a spooling operation (i.e. while the cable is being wound onto a reel 1000 for storage/transport and/or prior to deployment). The cable is provided unterminated and un-spooled initially (S1). The cable is then terminated, with a termination head 700 (S11), then measurement apparatus 500 is attached (S2). Before spooling, the apparatus 500 begins making measurements on the attached cable (S81), for example in response to a control signal transmitted from a controller 5630, or triggered by/in response to some other means. Spooling is then performed (S12) and the measurements continue during that process. When spooling is complete, measurements may cease and measurement data may be extracted or transmitted. This method enables cable condition to ne monitored, and damage spotted, during the spooling process.

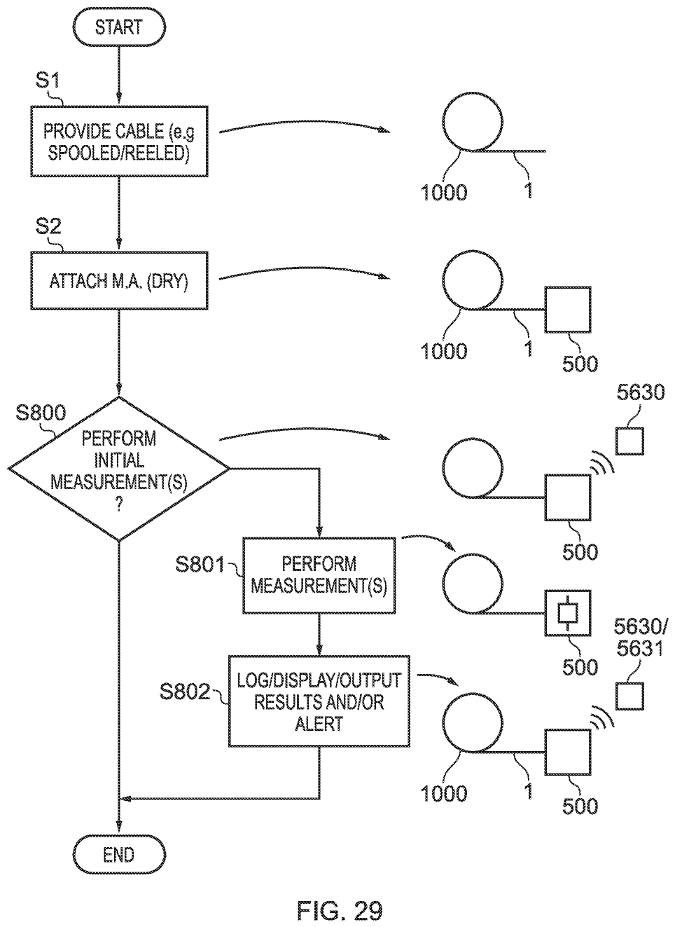

FIG. 29 illustrates a method in which the cable is provided pre-spooled (S1) and unterminated. The measurement apparatus is then attached (S2). Before any storage, handling, deployment etc., a determination is made whether to make initial measurements (S800). If “yes”, the measurement apparatus performs initial measurements (S801), then logs, displays, or outputs the results and/or an alert signal (S802). Advantageously, deployment of an already-defective cable may thus be avoided.

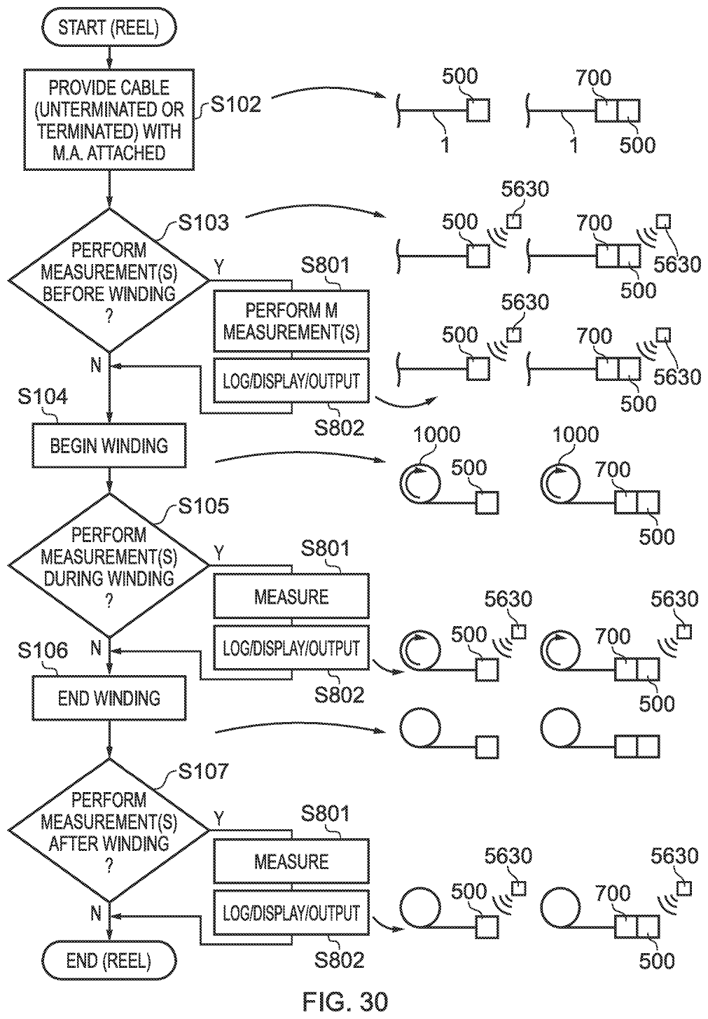

FIG. 30 illustrates steps in a method of using the measurement apparatus to monitor a cable before, during, and/or after a spooling/reeling operation.

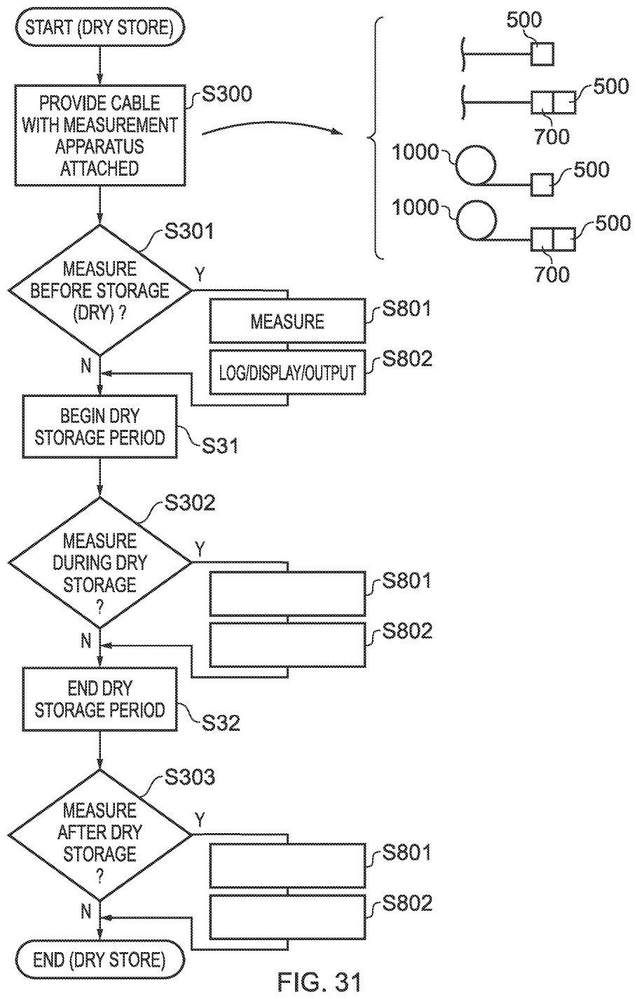

FIG. 31 illustrates steps in a method of using the measurement apparatus to monitor a cable before, during, and/or after a dry-storage operation.

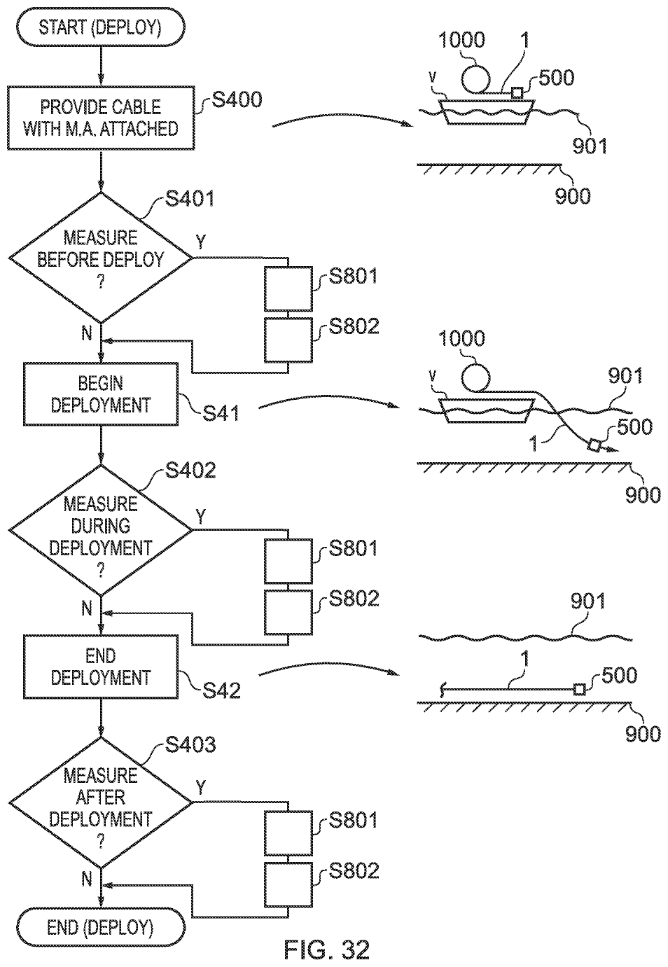

FIG. 32 illustrates steps in a method of using the measurement apparatus to monitor a cable before, during, and/or after a deployment operation. The cable is provided on a reel 100, with measurement apparatus 500 attached, and transported to a deployment position on a floating vessel (sea bed 900 and sea surface 901 indicated in the figure).

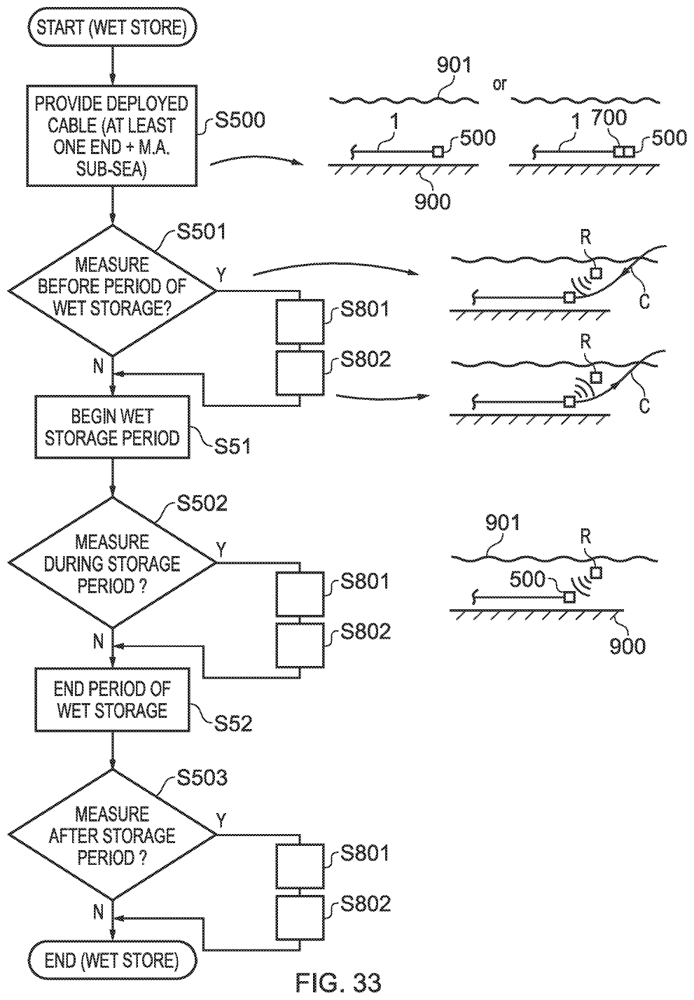

FIG. 33 illustrates steps in a method of using the measurement apparatus to monitor a cable before, during, and/or after a sub-sea storage (wet storage) period. The cable has been deployed with measurement apparatus 500 attached, and may be pre-terminated 700. Instructions to perform measurements may be transmitted to the cable via an attached cable or communication link C, or wirelessly from an ROV or diver R for example. Measurement results may be transmitted via link C, or transmitted wirelessly, for example by reception by a diver or ROV R.

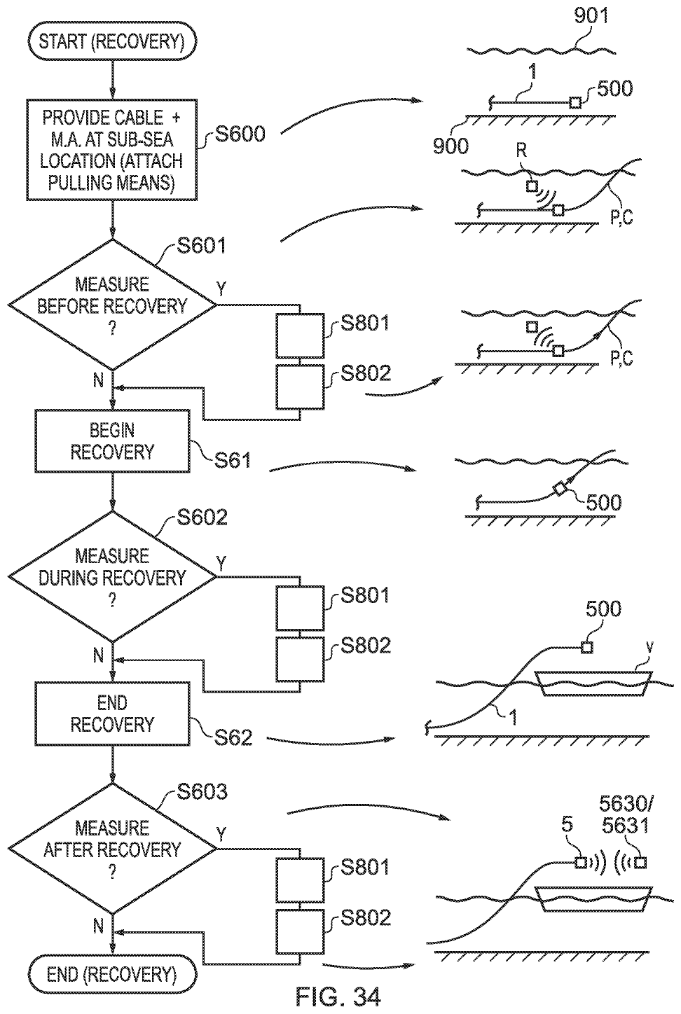

FIG. 34 illustrates steps in a method of using the measurement apparatus to monitor a cable before, during, and/or after a recovery process (to an above-water location). The cable may be recovered by attaching a pulling means or cable P, C and pulling. Measurement results may be logged, displayed, and/or output while pulling (while sub-sea or above-water), and/or when recovered onto a vessel or platform, for example.

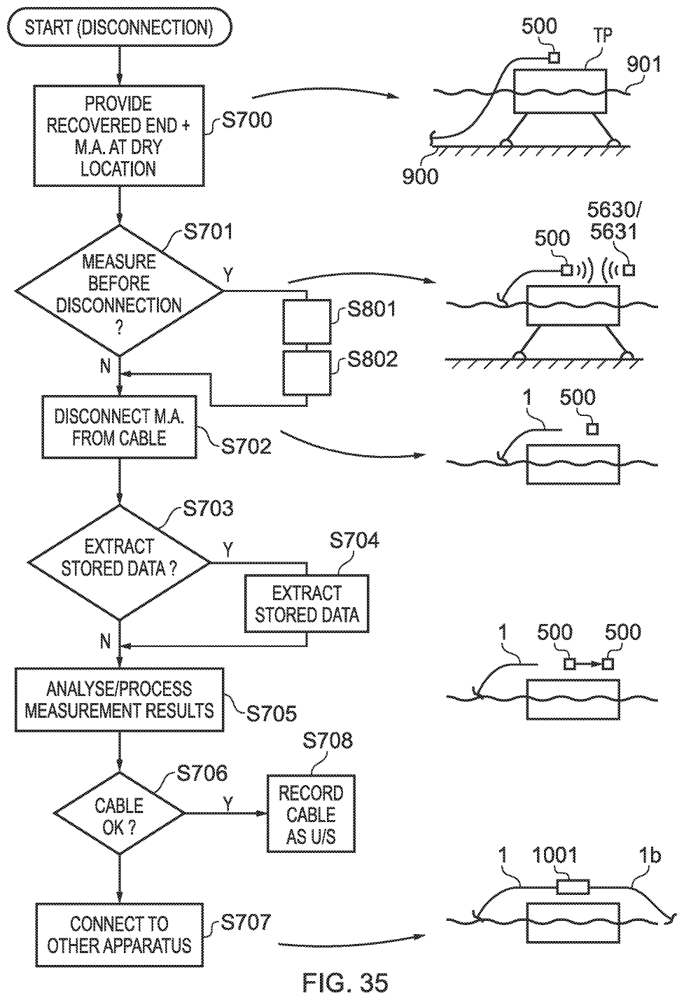

FIG. 35 illustrates steps in a method of using the measurement apparatus to monitor a cable after recovery (e.g. to a tethered platform TP), but before disconnection, and then extracting data and using the measurement results to determine whether to connect the cable to other apparatus (e.g. to second cable 1b, using connection means 1001) or to record the cable an un-usable.

Features of various aspects and embodiments of the invention will now be summarised. It will be appreciated that any feature and/or any combination of features of any aspect (or embodiment thereof) may be incorporated in any other aspect (or embodiment thereof), and provide corresponding advantage(s).

### Aspect 1 of the Invention

It will be appreciated that a first aspect of the invention provides subject matter in accordance with the following numbered paragraphs:

Paragraph 1. A pulling head (2) for attachment to, and pulling of, a cable (1) having at least one of: an electrically conductive core (11) for carrying electrical current and/or electrical signals along the cable; an electromagnetic waveguide (12) for carrying electromagnetic signals along the cable; and a bore (13) for conveying a fluid along the cable, the pulling head comprising:
attachment means (3) for mechanically attaching the pulling head to the cable to enable a pulling force to be applied to the cable via the pulling head;
connection means (4) for making at least one of an electrical connection (41) to said core, a waveguide connection (42) to said waveguide for sending an electromagnetic signal along the waveguide, and a hydraulic connection (43) to said bore;
measuring means (5) connected to the connection means and operable to perform at least one measurement, via the connection means, on a connected said cable; and
coupling means (6) for coupling to a means for providing a pulling force.

Paragraph 2. A pulling head in accordance with Paragraph 1, wherein the connection means is adapted to provide a plurality of electrical connections to a respective plurality of electrically conductive cores of an attached said cable.

Paragraph 3. A pulling head in accordance with Paragraph 2, wherein said at least one measurement comprises measuring an electrical resistance between a respective pair of said cores.

Paragraph 4. A pulling head in accordance with Paragraph 2 or Paragraph 3, wherein said at least one measurement comprises measuring an electrical capacitance between a respective pair of said cores.

Paragraph 5. A pulling head in accordance with any preceding Paragraph, comprising a terminal (electrode) arranged to make electric connection to a fluid in which the pulling head may be immersed.

Paragraph 6. A pulling head in accordance with Paragraph 5, wherein said at least one measurement comprises measuring an electrical resistance between a said core and said terminal.

Paragraph 7. A pulling head in accordance with Paragraph 5 or Paragraph 6, wherein said at least one measurement comprises measuring an electrical capacitance between a said core and said terminal.

Paragraph 8. A pulling head in accordance with any preceding Paragraph, wherein said at least one measurement comprises measuring a continuity of at least one core, waveguide, or bore of an attached cable.

Paragraph 9. A pulling head in accordance with any preceding Paragraph, wherein said at least one measurement comprises a Time Domain Reflectometry (TDR) measurement on at least one core, waveguide, or bore of an attached cable.

Paragraph 10. A pulling head in accordance with any preceding Paragraph, wherein said at least one measurement comprises measuring temperature at least one position along an attached cable by means of a sending an electromagnetic signal along said waveguide to interact with a respective temperature sensor (e.g. Bragg grating) at each said position.

Paragraph 11. A pulling head in accordance with any preceding Paragraph, wherein said at least one measurement comprises measuring strain at least one location along an attached cable by means of a sending an electromagnetic signal along said waveguide to interact with a respective strain sensor (e.g. Bragg grating) at each said location.

Paragraph 12. A pulling head in accordance with any preceding Paragraph, wherein said at least one measurement comprises applying a pressure via said hydraulic connection to a bore of an attached said cable and measuring pressure of fluid within said bore.

Paragraph 13. A pulling head in accordance with any preceding Paragraph, wherein the measuring means is operable to perform said at least one measurement on a connected said cable while said cable is being pulled via the pulling head.

Paragraph 14. A pulling head in accordance with any preceding Paragraph, wherein the pulling head further comprises a memory and the pulling head is further arranged to store results of at least one said measurement, and optionally results of each said measurement, in the memory.

Paragraph 15. A pulling head in accordance with any preceding Paragraph, wherein the measuring means is arranged to monitor results of at least one said measurement, and optionally results of each said measurement, and generate an alert signal according to said results.

Paragraph 16. A pulling head in accordance with Paragraph 15, further comprising indicating means for indicating, at the pulling head, generation of said alert signal, and/or means for transmitting said alert signal to a remote location.

Paragraph 17. A pulling head in accordance with any preceding Paragraph, further comprising data transmission means for transmitting results of at least one said measurement, and optionally results of each said measurement, to a remote location.

Paragraph 18. A pulling head in accordance with any preceding Paragraph, further comprising at least one strain sensor arranged to sense at least one of a strain resulting from a pulling force applied to the coupling means and a strain resulting from a bending of the pulling head, and wherein the measuring means is connected to the at least one strain sensor and is operable to perform at least one strain measurement of at least one of said strains.

Paragraph 19. A pulling head in accordance with Paragraph 18, wherein the measuring means is operable to perform said at least one strain measurement while the pulling head is being pulled via the coupling means.

Paragraph 20. A pulling head in accordance with Paragraph 18 or Paragraph 19, wherein the pulling head further comprises a memory and the pulling head is further arranged to store results of at least one said strain measurement, and optionally results of each said strain measurement, in the memory.

Paragraph 21. A pulling head in accordance with any one of Paragraphs 18 to 20, wherein the measuring means is arranged to monitor results of at least one said strain measurement, and optionally results of each said strain measurement, and generate a strain alert signal according to said strain measurement results.

Paragraph 22. A pulling head in accordance with any one of Paragraphs 18 to 21, further comprising indicating means for indicating, at the pulling head, generation of said strain alert signal, and/or means for transmitting said strain alert signal to a remote location.

Paragraph 23. A pulling head in accordance with any one of Paragraphs 18 to 22, further comprising data transmission means for transmitting results of at least one said strain measurement, and optionally results of each said strain measurement, to a remote.

Paragraph 24. A pulling head in accordance with any preceding Paragraph, further comprising a housing, the measuring means being housed inside said housing.

Paragraph 25. A pulling head in accordance with Paragraph 24, wherein at least a portion of said housing is flexible.

Paragraph 26. A pulling head in accordance with Paragraph 24 or Paragraph 25, wherein at least a portion of said housing is rigid.

Paragraph 27. A pulling head in accordance with Paragraph 24, wherein said housing comprises a plurality of housing sections, the measuring means being housed inside at least one of said sections.

Paragraph 28. A pulling head in accordance with Paragraph 27, wherein at least one said housing section is flexible.

Paragraph 29. A pulling head in accordance with Paragraph 27 or Paragraph 28, wherein at least one said housing section is rigid.

Paragraph 30. A pulling head in accordance with any one of Paragraphs 27 to 29, further comprising at least one articulated connection connecting an adjacent pair of said housing sections.

Paragraph 31. pulling head in accordance with any one of Paragraphs 24 to 26, wherein said housing is waterproof, arranged to prevent water contacting the measuring means when the pulling head is submerged (for example at a depth of 10 m, 100 m, 1000 m or more).

Paragraph 32. A pulling head in accordance with any one of Paragraphs 27 to 30, wherein at least one of said housing sections is waterproof, arranged to prevent water contacting the measuring means when the pulling head is submerged (for example at a depth of 10 m, 100 m, 1000 m or more).

Paragraph 33. A pulling head in accordance with any preceding Paragraph, further comprising sealing means arranged to form a seal to an attached said cable to prevent or inhibit ingress of water into at least one component of an attached cable (for example into an end of the attached cable) when submerged (for example at a depth of 10 m, 100 m, 1000 m or more).

Paragraph 34. A pulling head in accordance with any preceding Paragraph, further comprising energy storage means (e.g. at least one battery, rechargeable battery, fuel cell) arranged to power the measuring means).

Paragraph 35. A pulling head in accordance with any preceding Paragraph, wherein the measuring means comprising a programmable processor, the processor being operable to control said measurements.

Paragraph 36. A pulling head in accordance with Paragraph 30, further comprising an input socket (wired interface) and/or a data receiver (wireless interface) for receiving data to program said processor.

Paragraph 37. A pulling head in accordance with any preceding Paragraph, wherein the attachment means is arranged to grip a surface (e.g. an outer surface) of an end portion of the cable or of a component of said end portion.

Paragraph 38. A pulling head in accordance with Paragraph 37, wherein the attachment means comprises a woven tubular mesh for gripping said surface, and at least a portion of the connection means is arranged to extend axially, along a portion of a length of the woven tubular mesh, inside said woven tubular mesh.

Paragraph 39. A pulling head in accordance with any preceding Paragraph, wherein the attachment means is arranged to grip at least one internal component of the cable.

Paragraph 40. A pulling head in accordance with Paragraph 39, wherein the attachment means is arranged to grip at least a portion of a layer of armour of said cable.

Paragraph 41. An assembly comprising a pulling head, in accordance with any preceding Paragraph, attached to a said cable.

Paragraph 42. A pulling head assembly for attachment to, and pulling of, a cable having at least one of: an electrically conductive core for carrying electrical current along the cable; an electromagnetic waveguide for carrying electromagnetic signals along the cable; and a bore for conveying a fluid along the cable, the pulling head assembly comprising:
a pulling module comprising attachment means, for mechanically attaching the pulling head to the cable to enable a pulling force to be applied to the cable via the pulling head, and coupling means, for coupling to a means for providing a pulling force; and
a measurement module comprising connection means, for making at least one of: an electrical connection to said core; a connection to said waveguide for sending an electromagnetic signal along the waveguide; and a hydraulic connection to said bore, and measuring means connected to the connection means and operable to perform at least one measurement, via the connection means, on a connected said cable.

Paragraph 43. A measurement module for a pulling head assembly in accordance with Paragraph 42.

Paragraph 44. A method of handling a cable (1) having at least one of: an electrically conductive core (11) for carrying electrical current and/or electrical signals along the cable; an electromagnetic waveguide (12) for carrying electromagnetic signals along the cable; and a bore (13) for conveying a fluid along the cable, the method comprising:
providing a said cable;
making, with connection means, at least one of an electrical connection (41) to said core, a connection (42) to said waveguide for sending an electromagnetic signal along the waveguide, and a hydraulic connection (43) to said bore at an end of said cable;
connecting measuring means (5) to the connection means, the measuring means being operable to perform at least one measurement, via the connection means, on the connected said cable;
pulling, spooling, or un-spooling said cable; and
performing, at least one of before, after, and while performing said pulling, spooling, or unspooling, said at least one measurement, via the connection means, on the connected said cable.

Paragraph 45. A method in accordance with Paragraph 44, further comprising at least one of: storing results of said at least one measurement in memory means of the measuring means;
transmitting results of said at least one measurement for reception at a remote location;
comparing results of said at least one measurement with at least one criteria; and
generating an alert signal depending on the results of said comparing.

Paragraph 46. A method in accordance with Paragraph 44 or Paragraph 45, further comprising:
deploying said end of said cable with connected measuring means to a sub-sea location;
keeping said end of said cable with connected measuring means in said location for a period of time; and
operating said measuring means to perform said at least one measurement on the attached cable at said location, after said period of time, before moving said end of said cable from said location or connecting said end to other apparatus.

Paragraph 47. A method in accordance with any one of Paragraphs 44 to 46, wherein said connection means and measuring means are components of a pulling head in accordance with any one of Paragraphs 1 to 40 or a pulling head assembly in accordance with Paragraph 42, the method further comprising attaching the attachment means to said cable.

Paragraph 48. A method in accordance with Paragraph 47, wherein said pulling, spooling, or un-spooling of said cable comprises applying a pulling force to said coupling means.

Paragraph 49. A method of handling a cable (1) having at least one of: an electrically conductive core (11) for carrying electrical current and/or electrical signals along the cable; an electromagnetic waveguide (12) for carrying electromagnetic signals along the cable; and a bore (13) for conveying a fluid along the cable, the method comprising:
providing a said cable;
attaching and connecting a pulling head in accordance with any one of Paragraphs 1 to 40, or a pulling head assembly in accordance with Paragraph 42, to said cable;
pulling, spooling, or un-spooling said cable; and
performing with the measuring means, at least one of before, after, and while performing said pulling, spooling, or unspooling, said at least one measurement, via the connection means, on the connected said cable.

Paragraph 50. A method in accordance with any one of Paragraphs 44 to 49, wherein said performing of at least one measurement comprises performing, while pulling, spooling, or un-spooling said cable, a plurality of said measurements (e.g. at regular intervals).

Paragraph 51. A method in accordance with Paragraph 50, wherein said plurality of measurements comprise a first plurality of measurements of strain and/or bending of the cable.

Paragraph 52. A method in accordance with Paragraph 51, wherein said plurality of measurements comprise a second plurality of measurements, said second plurality of measurements being on parameters/characteristics other than strain or bending.

Paragraph 53. A method in accordance with any one of Paragraphs 44 to 52, further comprising performing, while pulling, spooling, or un-spooling said cable, measurements of strain and/or bending of the pulling head or pulling head assembly.

Paragraph 54. A method in accordance with any one of Paragraphs 51 to 53, further comprising increasing a frequency of said plurality of measurements according to the results of said measurements of strain and/or bending of the cable and/or of the pulling head or pulling head assembly.

### Aspect 2 of the Invention

It will be appreciated that a second aspect of the invention provides subject matter in accordance with the following numbered paragraphs:

Paragraph 1. A method of handling a cable (1) (e.g. a cable for subsea transmission of electrical power) having at least one of: at least one electrically conductive core (11) for carrying electrical current and/or electrical signals along the cable; at least one electromagnetic waveguide (12) for carrying electromagnetic signals along the cable; and at least one bore (13) for conveying a fluid along the cable, the method comprising:
providing a said cable having an end;
attaching measurement apparatus to said end in an above-water or out-of-water (e.g. dry) environment such that the measurement apparatus makes at least one of: at least one respective electrical connection to at least one said core; at least one respective connection to at least one said waveguide for sending an electromagnetic signal along the waveguide; and at least one respective fluid or hydraulic connection to at least one said bore;
deploying (e.g. laying) the cable such that said end, with the measurement apparatus attached, is submerged in water (i.e. is underwater) for a period of time;
after said period of time, recovering (e.g. pulling) said end and attached measurement apparatus to an above-water or out-of-water (e.g. dry) location; and
while the measurement apparatus is attached to said end, operating the measurement apparatus to perform at least one measurement on the attached cable (e.g. performing a measurement at at least one time before, during, and/or after said deploying, and/or before, during, and/or after said recovering, such as between deploying and recovering, and/or during said recovering, or after a period of storage (e.g. at a sub-sea deployed location) then before and during a pulling operation to take the cable end up to a surface vessel or installation for dry-connection to other apparatus).

Paragraph 2. A method in accordance with Paragraph 1, wherein said providing comprises providing said cable at least partly on a reel (or spool).

Paragraph 3. A method in accordance with any preceding Paragraph, and further comprising, before said attaching of the measurement apparatus, terminating said end with at least one of: at least one mechanical connector; at least one respective electrical connector attached to at least one said core; at least one respective waveguide connector attached to at least one said waveguide; and at least one respective fluid or hydraulic connector attached to at least one said bore, wherein attaching the measurement apparatus comprises connecting at least one of said connectors to a corresponding connector of the measurement apparatus (e.g. if the cable comprises a plurality of cores, said terminating may comprise terminating one or more cores, or each core, with a respective electrical connector; if the cable comprises a plurality of waveguides, said terminating may comprise terminating one or more waveguides, or each waveguide, with a respective waveguide connector; and if the cable comprises a plurality of bores, said terminating may comprise terminating one or more bores, or each bore, with a respective fluid or hydraulic connector).

Paragraph 4. A method in accordance with Paragraph 3, wherein said terminating is performed in an above-water or out-of-water (e.g. dry) environment.

Paragraph 5. A method in accordance with Paragraph 3 or Paragraph 4, wherein said terminating comprises terminating said end with a mechanical connector, the measurement apparatus comprises a housing having a corresponding mechanical connector, and said attaching comprises connecting the mechanical connector of the cable to the mechanical connector of the housing.

Paragraph 6. A method in accordance with Paragraph 5, wherein the housing further comprises coupling means (6) for coupling to a means for providing a pulling force, and at least one of said deploying and said recovering comprises applying a pulling force to said coupling means.

Paragraph 7. A method in accordance with any one of Paragraphs 1 to 4, wherein said attaching comprises clamping or gripping at least one of: the cable end; a portion of the cable; an end portion of the cable (e.g. at, or proximate said end); and at least one component of the cable (e.g. clamping or gripping with at least one component of the measurement apparatus).

Paragraph 8. A method in accordance with Paragraph 7, wherein the measurement apparatus further comprises coupling means (6) for coupling to a means for providing a pulling force, and at least one of said deploying and said recovering comprises applying a pulling force to said coupling means.

Paragraph 9. A method in accordance with any preceding Paragraph, wherein said attaching comprises forming a seal between the measurement apparatus and said cable to inhibit ingress of water to at least one of: at least one said core (11); at least one said waveguide (12); and at least one said bore.

Paragraph 10. A method in accordance with any preceding Paragraph, wherein said deploying comprises at least one of: unspooling; laying a length of said cable (e.g. underwater, such as on a sea bed); leaving or storing a length of said cable at a subsea location for a length of time; and pulling said cable.

Paragraph 11. A method in accordance with any preceding Paragraph, wherein said recovering comprises at least one of: pulling; lifting said end from a sub-sea location; pulling said end through a guide hole, guide element, or guide structure (e.g. a J-tube); and pulling said end onto a floating, anchored, fixed, or above-water vessel, structure or part thereof (e.g. for connection to other apparatus in a dry environment).

Paragraph 12. A method in accordance with any preceding Paragraph, wherein said operating comprises
operating the measurement apparatus to perform at least one said measurement on the attached cable at at least one time before, during, and/or after said deploying, and/or before, during, and/or after said recovering (and the method may comprise performing a plurality of measurements at the same time, and/or at a plurality of different times).

Paragraph 13. A method in accordance with any preceding Paragraph, wherein said operating comprises operating the measurement apparatus at at least one sub-sea location to perform at least one said measurement on the attached cable.

Paragraph 14. A method in accordance with any preceding Paragraph, wherein the cable comprises a plurality of said cores, and said attaching is arranged such that the measurement apparatus makes a respective electrical connection to each said core (e.g. by means of a plurality of electrical connectors, each arranged to connect to a respective electrical connector terminating a respective core of the cable).

Paragraph 15. A method in accordance with Paragraph 14, wherein said at least one measurement comprises measuring an electrical resistance between a respective pair of said cores.

Paragraph 16. A method in accordance with Paragraph 14 or Paragraph 15, wherein said at least one measurement comprises measuring an electrical capacitance between a respective pair of said cores.

Paragraph 17. A method in accordance with any preceding Paragraph, wherein the measurement apparatus comprises a terminal (electrode) arranged to make electric connection to water when the measurement apparatus is submerged.

Paragraph 18. A method in accordance with Paragraph 17, wherein said at least one measurement comprises measuring an electrical resistance between a said core and said terminal.

Paragraph 19. A method in accordance with Paragraph 17 or Paragraph 18, wherein said at least one measurement comprises measuring an electrical capacitance between a said core and said terminal.

Paragraph 20. A method in accordance with any preceding Paragraph, wherein said at least one measurement comprises measuring a continuity of at least one core, waveguide, or bore of the attached cable.

Paragraph 21. A method in accordance with any preceding Paragraph, wherein said at least one measurement comprises a Time Domain Reflectometry (TDR) measurement on at least one core, waveguide, or bore of the attached cable.

Paragraph 22. A method in accordance with any preceding Paragraph, wherein said at least one measurement comprises measuring temperature at least one position along the attached cable by means of a sending an electromagnetic signal along a said waveguide to interact with a respective temperature sensor (e.g. Bragg grating) at each said position.

Paragraph 23. A method in accordance with any preceding Paragraph, wherein said at least one measurement comprises measuring strain at least one location along the attached cable by means of a sending an electromagnetic signal along a said waveguide to interact with a respective strain sensor (e.g. Bragg grating) at each said location.

Paragraph 24. A method in accordance with any preceding Paragraph, wherein said at least one measurement comprises applying a pressure via a fluid or hydraulic connection to a bore of the attached said cable and measuring pressure of fluid within said bore.

Paragraph 25. A method in accordance with any preceding Paragraph, comprising operating the measurement apparatus to perform said at least one measurement on the attached cable while said cable is being pulled (e.g. via the coupling means).

Paragraph 26. A method in accordance with any preceding Paragraph, wherein the measurement apparatus comprises a memory, and the method further comprises storing results of at least one said measurement, and optionally results of each said measurement, in the memory.

Paragraph 27. A method in accordance with any preceding Paragraph, further comprising operating the measurement apparatus to monitor results of at least one said measurement, and optionally results of each said measurement, and generating an alert signal according to said results.

Paragraph 28. A method in accordance with Paragraph 27, further comprising indicating, by the measurement apparatus, generation of said alert signal, and/or transmitting said alert signal to a remote location.

Paragraph 29. A method in accordance with any preceding Paragraph, further comprising transmitting results of at least one said measurement, and optionally results of each said measurement, to a remote location.

Paragraph 30. A method in accordance with any preceding Paragraph, further comprising operating the measurement apparatus to measure at least one strain of the attached cable and/or at least one strain of the measurement apparatus during at least one of said deploying and said recovering.

Paragraph 31. A method in accordance with any preceding Paragraph, further comprising at least one of:
storing results of said at least one measurement in a memory (e.g. a memory of the measurement apparatus);
providing an indication of said results from the measurement apparatus (e.g. by means of a visible indicator of the measurement apparatus, to a nearby diver or ROV in a sub-sea location, or operator at a surface or above-water location)
transmitting results of said at least one measurement from the measurement apparatus for reception at a remote location; and
comparing (e.g. by the measurement apparatus) results of said at least one measurement with at least one criteria, and generating an alert signal depending on the results of said comparing.

Paragraph 32. A method in accordance with any preceding Paragraph, wherein said deploying comprises:
deploying said end of said cable with connected measurement apparatus to a sub-sea location and keeping said end of said cable with connected measurement in said location for said period of time;
and the method further comprises:
operating said measuring means to perform said at least one measurement on the attached cable at said location, after said period of time, before said recovering (i.e. before moving said end of said cable from said location or connecting said end to other apparatus).

Paragraph 33. A method in accordance with any preceding Paragraph, wherein said performing of at least one measurement comprises performing (e.g. at at least one time before, during, and/or after said deploying, and/or before, during, and/or after said recovering, such as while pulling, spooling, or un-spooling said cable) a plurality of said measurements (e.g. at regular intervals).

Paragraph 34. A method in accordance with Paragraph 33, wherein said plurality of measurements comprise a first plurality of measurements of strain and/or bending of the cable.

Paragraph 35. A method in accordance with Paragraph 34, wherein said plurality of measurements comprise a second plurality of measurements, said second plurality of measurements being on parameters/characteristics other than strain or bending.

Paragraph 36. A method in accordance with any preceding Paragraph, further comprising performing (e.g. at at least one time before, during, and/or after said deploying, and/or before, during, and/or after said recovering, such as while pulling, spooling, or un-spooling said cable) measurements of strain and/or bending of the measurement apparatus.

Paragraph 37. A method in accordance with any one of Paragraphs 33 to 36, further comprising increasing a frequency of said plurality of measurements according to the results of said measurements of strain and/or bending of the cable and/or of the measurement apparatus.

Paragraph 38. A method in accordance with any preceding Paragraph, further comprising using the results of said measurements to determine whether or not to disconnect the measurement apparatus from said end and connect said end to further apparatus.

Paragraph 39. A method in accordance with any preceding Paragraph, wherein the measurement apparatus is a smart pulling head or a smart protective end cap.

Paragraph 40. A method in accordance with any one of Paragraphs 1 to 39, further comprising attaching a pulling head to the cable.

Paragraph 41. A method in accordance with Paragraph 40, further comprising housing said measurement apparatus inside (e.g. inside a housing of) said pulling head.

Paragraph 42. A method in accordance with Paragraph 40 or Paragraph 41, further comprising attaching said pulling head to said measurement apparatus.

### Aspect 3 of the Invention

It will be appreciated that a third aspect of the invention provides subject matter in accordance with the following numbered paragraphs:

Paragraph 1. Measurement (e.g. monitoring) apparatus for connection to an end of a cable (1) (e.g. to an unterminated end, or to an already-terminated end (e.g. terminated by a termination assembly or structure, and/or at least one connector), of a cable for subsea transmission of electrical power) having at least one of: at least one electrically conductive core (11) for carrying electrical current and/or electrical signals along the cable; at least one electromagnetic waveguide (12) for carrying electromagnetic signals along the cable; and at least one bore (13) for conveying a fluid along the cable, the measurement apparatus comprising:
connection means (4) for connecting to said end in an above-water or out-of-water (e.g. dry) environment to make at least one of: at least one respective electrical connection (41) to at least one said core, at least one respective waveguide connection (42) to at least one said waveguide for sending an electromagnetic signal along the waveguide, and at least one respective fluid or hydraulic connection (43) to at least one said bore; and
measuring means (5) connected to the connection means and operable to perform at least one measurement, via the connection means, on a connected said cable,
wherein the measurement apparatus is deployable, when connected to an end of said cable, with said cable end to an underwater location for a period of time, and recoverable with said connected cable end after said period of time to an above-water or out-of-water (e.g. dry) location, and
wherein the measuring means is operable to perform said at least one measurement while the measurement apparatus is connected to said cable end and at least while submerged with said connected cable end and/or after recovery with said connected cable end from said underwater location to said above-water or out-of-water location.

Paragraph 2. Measurement apparatus in accordance with Paragraph 1, wherein the connection means comprises at least one electrical connector for connection to a corresponding electrical connector terminating a said core (i.e. at the end of the cable).

Paragraph 3. Measurement apparatus in accordance with Paragraph 2, wherein the connection means comprises a plurality of electrical connectors, each for connection to a corresponding connector terminating a respective said core.

Paragraph 4. Measurement apparatus in accordance with any preceding Paragraph, wherein the connection means comprises at least one waveguide connector for connection to a corresponding waveguide connector terminating a said waveguide (i.e. at the end of the cable).

Paragraph 5. Measurement apparatus in accordance with Paragraph 4, wherein the connection means comprises a plurality of waveguide connectors, each for connection to a corresponding waveguide connector terminating a respective said waveguide.

Paragraph 6. Measurement apparatus in accordance with any preceding Paragraph, wherein the connection means comprises at least one fluid or hydraulic connector for connection to a corresponding fluid or hydraulic connector terminating a said bore (i.e. at the end of the cable).

Paragraph 7. Measurement apparatus in accordance with Paragraph 6, wherein the connection means comprises a plurality of fluid or hydraulic connectors, each for connection to a corresponding fluid or hydraulic connector terminating a respective said bore.

Paragraph 8. Measurement apparatus in accordance with any preceding Paragraph, further comprising attachment means (3) for mechanically attaching the measurement apparatus to the cable end.

Paragraph 9. Measurement apparatus in accordance with Paragraph 8, wherein the attachment means comprises locking means for inhibiting mechanical detachment of the measurement apparatus from the cable end.

Paragraph 10. Measurement apparatus in accordance with Paragraph 8 or Paragraph 9, wherein the attachment means comprises at least one mechanical connector for connection to a corresponding mechanical connector provided at, or proximate, said cable end.

Paragraph 11. Measurement apparatus in accordance with any one of Paragraphs 8 to 10, wherein the attachment means comprises means for clamping or gripping at least one of: the cable end; a portion of the cable; an end portion of the cable (e.g. at, or proximate said end); and at least one component of the cable. (The attachment means may be arranged to grip a surface (e.g. an outer surface) of an end portion of the cable or of a component of said end portion)

Paragraph 12. Measurement apparatus in accordance with any one of Paragraphs 8 to 11, further comprising coupling means (6) for coupling to a means for providing a pulling force to enable a pulling force to be applied, via the measurement apparatus, to a said cable mechanically attached to the measurement apparatus (the coupling means may, for example, be a pulling eye, or other coupling, attached to, or provided by, a housing of the measurement apparatus).

Paragraph 13. Measurement apparatus in accordance with any preceding Paragraph, further comprising sealing means arranged to form a seal between the measurement apparatus and said cable to inhibit ingress of water to at least one of: at least one said core (11); at least one said waveguide (12); and at least one said bore of a said cable having an end connected to the measurement apparatus. (Alternatively, or additionally, the measurement apparatus may comprise protection means or shielding means, arranged to provide mechanical protection of the cable end (e.g. protection of at least one component therein). Thus, the measurement apparatus may be a smart protection cap, or smart terminal/termination)

Paragraph 14. Measurement apparatus in accordance with any preceding Paragraph, wherein the connection means is adapted to provide a plurality of electrical connections to a respective plurality of electrically conductive cores of a connected said cable.

Paragraph 15. Measurement apparatus in accordance with Paragraph 14, wherein said at least one measurement comprises measuring an electrical resistance between a respective pair of said cores.

Paragraph 16. Measurement apparatus in accordance with Paragraph 14 or Paragraph 15, wherein said at least one measurement comprises measuring an electrical capacitance between a respective pair of said cores.

Paragraph 17. Measurement apparatus in accordance with any preceding Paragraph, comprising a terminal (electrode) arranged to make electric connection to a fluid in which the measurement apparatus is immersed.

Paragraph 18. Measurement apparatus in accordance with Paragraph 17, wherein said at least one measurement comprises measuring an electrical resistance between a said core and said terminal.

Paragraph 19. Measurement apparatus in accordance with Paragraph 17 or Paragraph 18, wherein said at least one measurement comprises measuring an electrical capacitance between a said core and said terminal.

Paragraph 20. Measurement apparatus in accordance with any preceding Paragraph, wherein said at least one measurement comprises measuring a continuity of at least one core, waveguide, or bore of a connected cable.

Paragraph 21. Measurement apparatus in accordance with any preceding Paragraph, wherein said at least one measurement comprises a Time Domain Reflectometry (TDR) measurement on at least one core, waveguide, or bore of a connected cable.

Paragraph 22. Measurement apparatus in accordance with any preceding Paragraph, wherein said at least one measurement comprises measuring temperature at least one position along a connected cable by means of a sending an electromagnetic signal along a said waveguide to interact with a respective temperature sensor (e.g. Bragg grating) at each said position.

Paragraph 23. Measurement apparatus in accordance with any preceding Paragraph, wherein said at least one measurement comprises measuring strain at least one location along a connected cable by means of a sending an electromagnetic signal along a said waveguide to interact with a respective strain sensor (e.g. Bragg grating) at each said location.

Paragraph 24. Measurement apparatus in accordance with any preceding Paragraph, wherein said at least one measurement comprises applying a pressure via a said fluid or hydraulic connection to a bore of a connected cable and measuring pressure of fluid within said bore.

Paragraph 25. Measurement apparatus in accordance with any preceding Paragraph, wherein the measuring means is operable to perform said at least one measurement on a connected said cable while said cable is being pulled (e.g. via the measurement apparatus itself, if the apparatus is a smart pulling head, or by a pulling head, if the measurement apparatus is separate from the pulling head, housed within a pulling head, and/or attached to a pulling head).

Paragraph 26. Measurement apparatus in accordance with any preceding Paragraph, further comprising a memory, and the measurement apparatus is further arranged to store results of at least one said measurement, and optionally results of each said measurement, in the memory.

Paragraph 27. Measurement apparatus in accordance with any preceding Paragraph, wherein the measuring means is arranged to monitor results of at least one said measurement, and optionally results of each said measurement, and generate an alert signal according to said results.

Paragraph 28. Measurement apparatus in accordance with Paragraph 27, further comprising indicating means for indicating, at the measurement apparatus, generation of said alert signal, and/or further comprising means for transmitting (e.g. at least one transmitter, or transceiver) said alert signal to a remote location.

Paragraph 29. Measurement apparatus in accordance with any preceding Paragraph, further comprising data transmission means for transmitting results of at least one said measurement, and optionally results of each said measurement, to a remote location.

Paragraph 30. Measurement apparatus in accordance with any preceding Paragraph, further comprising coupling means for coupling to a means for providing a pulling force to enable a pulling force to be applied, via the measurement apparatus, to a said cable connected to the measurement apparatus, the measurement apparatus further comprising at least one strain sensor arranged to sense at least one of a strain resulting from a pulling force applied to the coupling means and a strain resulting from a bending of the measurement apparatus or at least one component thereof (e.g. of a housing of the measurement apparatus), and wherein the measuring means is connected to the at least one strain sensor and is operable to perform at least one strain measurement of at least one of said strains.

Paragraph 31. Measurement apparatus in accordance with Paragraph 30, wherein the measuring means is operable to perform said at least one strain measurement while the measurement apparatus is being pulled via the coupling means.

Paragraph 32. Measurement apparatus in accordance with Paragraph 30 or Paragraph 31, further comprising a memory and the measurement apparatus is further arranged to store results of at least one said strain measurement, and optionally results of each said strain measurement, in the memory.

Paragraph 33. Measurement apparatus in accordance with any one of Paragraphs 30 to 32, wherein the measuring means is arranged to monitor results of at least one said strain measurement, and optionally results of each said strain measurement, and generate a strain alert signal according to said strain measurement results.

Paragraph 34. Measurement apparatus in accordance with any one of Paragraphs 30 to 33, further comprising indicating means for indicating, at the measurement apparatus, generation of said strain alert signal, and/or further comprising means for transmitting said strain alert signal to a remote location.

Paragraph 35. Measurement apparatus in accordance with any one of Paragraphs 30 to 34, further comprising data transmission means for transmitting results of at least one said strain measurement, and optionally results of each said strain measurement, to a remote location.

Paragraph 36. Measurement apparatus in accordance with any preceding Paragraph, further comprising a housing, the measuring means being housed inside said housing.

Paragraph 37. Measurement apparatus in accordance with Paragraph 36, wherein at least a portion of said housing is flexible.

Paragraph 38. Measurement apparatus in accordance with Paragraph 36 or Paragraph 37, wherein at least a portion of said housing is rigid.

Paragraph 39. Measurement apparatus in accordance with Paragraph 36, wherein said housing comprises a plurality of housing sections, the measuring means being housed inside at least one of said sections.

Paragraph 40. Measurement apparatus in accordance with Paragraph 39, wherein at least one said housing section is flexible.

Paragraph 41. Measurement apparatus in accordance with Paragraph 39 or Paragraph 40, wherein at least one said housing section is rigid.

Paragraph 42. Measurement apparatus in accordance with any one of Paragraphs 39 to 41, further comprising at least one articulated connection connecting an adjacent pair of said housing sections.

Paragraph 43. Measurement apparatus in accordance with any one of Paragraphs 36 to 38, wherein said housing is waterproof, arranged to prevent water contacting the measuring means when the measurement apparatus is submerged (for example at a depth of 10 m, 100 m, 1000 m or more).

Paragraph 44. Measurement apparatus in accordance with any one of Paragraphs 39 to 42, wherein at least one of said housing sections is waterproof, arranged to prevent water contacting the measuring means when the measurement apparatus is submerged (for example at a depth of 10 m, 100 m, 1000 m or more).

Paragraph 45. Measurement apparatus in accordance with any one of Paragraphs 36 to 44, further comprising coupling means (e.g. at least one coupling) for coupling to a means for providing a pulling force to enable a pulling force to be applied, via the measurement apparatus, to a said cable connected to the measurement apparatus, wherein the coupling means is attached to said housing or said housing comprises the coupling means (e.g. the coupling may be an integral part of the housing; the housing may provide the coupling).

Paragraph 46. Measurement apparatus in accordance with any preceding Paragraph, further comprising sealing means arranged to form a seal to a connected said cable to prevent or inhibit ingress of water into at least one component of a connected cable (for example into an end of the attached cable) when submerged (for example at a depth of 10 m, 100 m, 1000 m or more).

Paragraph 47. Measurement apparatus in accordance with any preceding Paragraph, further comprising energy storage means (e.g. at least one battery, rechargeable battery, fuel cell etc.) arranged to power the measuring means. (The energy storage means may be housed in a housing of the measurement apparatus, and/or may provide all of the power needed for operation of the apparatus to perform measurements, store results, process results, transmit results, and/or receive and process instructions/code from a remote location; the measurement apparatus my thus be power self-sufficient, needing, and having, no external power supply).

Paragraph 48. Measurement apparatus in accordance with any preceding Paragraph, wherein the measuring means comprising a programmable processor, the processor being operable to control said measurements.

Paragraph 49. Measurement apparatus in accordance with Paragraph 48, further comprising an input socket (wired interface) and/or a data receiver (wireless interface) for receiving data to program said processor.

Paragraph 50. An assembly comprising measurement apparatus, in accordance with any preceding Paragraph, attached to a said cable.

Paragraph 51. A pulling head assembly for attachment to, and pulling of, a cable having at least one of: at least one electrically conductive core for carrying electrical current along the cable; at least one electromagnetic waveguide for carrying electromagnetic signals along the cable; and at least one bore for conveying a fluid along the cable, the pulling head assembly comprising:
a pulling module comprising attachment means, for mechanically attaching the pulling head to the cable to enable a pulling force to be applied to the cable via the pulling head, and coupling means, for coupling to a means for providing a pulling force; and
measurement apparatus in accordance with any one of Paragraphs 1 to 49, for connection to an end of said cable.

Paragraph 52. A pulling head assembly in accordance with Paragraph 51, wherein the pulling module comprises a housing, and the measurement apparatus is at least partly housed within the pulling module housing and/or is attached to the pulling head housing.

### Aspect 4 of the Invention

It will be appreciated that a fourth aspect of the invention provides subject matter in accordance with the following numbered paragraphs:

Paragraph 1. An assembly comprising:
subsea apparatus comprising a connector designed to mate in a dry environment with a corresponding connector of other subsea apparatus to provide at least one of electrical, optical, and fluid connection between the two; and
subsea test apparatus having a connector mated with the connector of the subsea apparatus so as to provide at least one of electrical, optical, and fluid connection between the subsea apparatus and the subsea test apparatus, the subsea test apparatus being deployable at a subsea location to perform a measurement at the subsea location on the subsea apparatus and provide an indication of a result of the measurement from the subsea location to an underwater vehicle or diver,
the test apparatus further comprising:
measuring means connected to the test apparatus's connector and operable underwater in a measurement mode;
a power supply comprising a battery or a fuel cell or other power source arranged to power the measuring means; and
disconnection means for disconnecting the test apparatus's connector from the subsea apparatus's connector in a dry environment (the disconnection means may be adapted to prevent or inhibit accidental disconnection in a sub-sea or other wet environment),
wherein the measuring means, in said measurement mode, is arranged to perform at least one measurement, via the mated connectors, on the subsea apparatus, and the test apparatus further comprises indicating means operable underwater to provide an indication of a result of the or each measurement from the subsea location to an underwater vehicle or diver,
whereby the assembly may be provided at a subsea location, and the measuring means may be operated at said location to perform at least one measurement on the connected apparatus

Paragraph 2. An assembly in accordance with Paragraph 1, wherein the test apparatus further comprises triggering means for triggering the measuring means to operate in said measurement mode, whereby the assembly may be provided at said subsea location, the measuring means may be triggered at said location to perform at least one measurement on the connected apparatus.

Paragraph 3. An assembly in accordance with any preceding Paragraph, wherein the indicating means is arranged to provide said indication only when the measuring means is in said measurement mode.

Paragraph 8. An assembly in accordance with any preceding Paragraph, wherein the subsea apparatus comprises an electrical conductor, and the mated connectors provide an electrical connection between the measuring means and the electrical conductor.

Paragraph 9. An assembly in accordance with Paragraph 8, wherein the measuring means, in said measurement mode, is arranged to measure an electrical impedance between said electrical conductor and seawater.

Paragraph 10. An assembly in accordance with Paragraph 8, wherein the measuring means, in said measurement mode, is arranged to transmit an electrical impulse along the electrical conductor and to monitor any reflected or returned signal.

Paragraph 11. An assembly in accordance with any preceding Paragraph, wherein the subsea apparatus comprises a plurality of electrical conductors, the mated connectors provide a respective electrical connection between the measuring means and each of the plurality of electrical conductors, and the measuring means, in said measurement mode, is arranged to measure an electrical impedance between one of said plurality of electrical conductors and another one of said plurality of electrical conductors.

Paragraph 12. An assembly in accordance with Paragraph 11, wherein said plurality of electrical conductors comprises at least three electrical conductors, and the measuring means is arranged, in said measurement mode, to measure an electrical impedance between at least one selected pair of the at least three conductors.

Paragraph 13. An assembly in accordance with Paragraph 12, wherein the measuring means comprises means for selecting a pair of the at least three conductors, means for applying a test voltage between the selected pair, and means for determining a current flowing between the selected pair.

Paragraph 14. An assembly in accordance with Paragraph 13, wherein the means for selecting comprises controllable switch means.

Paragraph 15. An assembly in accordance with any one of Paragraphs 8 to 14, wherein the measuring means comprises switch means controllable to electrically isolate the test apparatus's connector from the power supply.

Paragraph 16. An assembly in accordance with any preceding Paragraph, wherein the subsea apparatus comprises an optical waveguide, and the mated connectors provide an optical connection between the measuring means and the optical waveguide.

Paragraph 17. An assembly in accordance with Paragraph 16, wherein the measuring means, in said measurement mode, is arranged to transmit an optical pulse along said optical waveguide via the mated connectors and to monitor any reflected or returned optical signal.

Paragraph 18. An assembly in accordance with any preceding Paragraph, wherein the subsea apparatus comprises a fluid conduit, and the mated connectors provide fluid connection between the conduit and the measuring means.

Paragraph 19. An assembly in accordance with Paragraph 18, wherein the measuring means, in said measurement mode, is arranged to apply pressure to fluid contained in the conduit, via the mated connectors.

Paragraph 20. An assembly in accordance with any preceding Paragraph, wherein the mated connectors comprise at least one pair of mated electrical contacts and sealing means arranged to prevent contact between sea water and the mated electrical contacts.

Paragraph 23. An assembly in accordance with Paragraph 2 or any one of Paragraphs 3 to 20 as depending from Paragraph 2, wherein said triggering means comprises a light detector and is arranged to trigger the measuring means to operate in said measurement mode in response to detection of light by the light detector.

Paragraph 24. An assembly in accordance with any preceding Paragraph, wherein the indicating means comprises a visual display.

Paragraph 27. Subsea test apparatus for deployment at a subsea location to perform a measurement at the subsea location on subsea apparatus and provide an indication of a result of the measurement from the subsea location to an underwater vehicle or diver, the subsea test apparatus comprising:
a connector for mating with a corresponding connector of subsea apparatus to provide at least one of electrical, optical, and fluid connection between the test apparatus and the subsea apparatus;
measuring means connected to the test apparatus's connector and operable underwater in a measurement mode;
a power supply comprising a battery or a fuel cell or other power source arranged to power the measuring means; and
disconnection means for disconnecting the test apparatus's connector from a mated subsea apparatus's connector,
wherein the measuring means, in said measurement mode, is arranged to perform at least one measurement, via the mated connectors, on connected subsea apparatus, and the test apparatus further comprises indicating means operable underwater to provide an indication of a result of the or each measurement from the subsea location to an underwater vehicle or diver.

Paragraph 28. Apparatus in accordance with Paragraph 27, further comprising triggering means for triggering the measuring means to operate in said measurement mode.

Paragraph 29. Apparatus in accordance with any one of Paragraphs 27 or 28, wherein the indicating means is arranged to provide said indication only when the measuring means is in said measurement mode.

Paragraph 32. Apparatus in accordance with any one of Paragraphs 27 to 29, wherein the test apparatus's connector comprises at least one electrical contact for forming an electrical connection to a corresponding electrical contact of a corresponding connector, the electrical contact being connected to the measuring means.

Paragraph 33. Apparatus in accordance with Paragraph 32, wherein the measuring means, in said measurement mode, is arranged to measure an electrical impedance between said electrical contact and seawater.

Paragraph 34. Apparatus in accordance with Paragraph 32, wherein the measuring means, in said measurement mode, is arranged to apply a voltage pulse to the electrical contact and to monitor a voltage of the electrical contact following the pulse.

Paragraph 35. Apparatus in accordance with any one of Paragraphs 27 to 34, wherein the connector comprises a plurality of electrical contacts, each for forming an electrical connection to a corresponding electrical contact of a corresponding connector, and each being connected to the measuring means, and wherein the measuring means, in said measurement mode, is arranged to measure an electrical impedance between one of said plurality of electrical contacts and another one of said plurality of electrical contacts.

Paragraph 36. Apparatus in accordance with Paragraph 35, wherein said plurality of electrical contacts comprises at least three electrical contacts, and the measuring means is arranged, in said measurement mode, to measure an electrical impedance between at least one selected pair of the at least three contacts.

Paragraph 37. Apparatus in accordance with Paragraph 36, wherein the measuring means comprises means for selecting a pair of the at least three contacts, means for applying a test voltage between the selected pair, and means for determining a current flowing between the selected pair. (Alternatively, some high-power dry-mate connectors may have only a single contact so measurement may be between the single contact (e.g. single pin) and seawater)

Paragraph 38. Apparatus in accordance with Paragraph 37, wherein the means for selecting comprises controllable switch means.

Paragraph 39. Apparatus in accordance with any one of Paragraphs 32 to 38, wherein the measuring means comprises switch means controllable to electrically isolate the or each electrical contact from the power supply.

Paragraph 40. Apparatus in accordance with any one of Paragraphs 32 to 39, wherein the test apparatus comprises switch means controllable to electrically isolate the or each electrical contact from the measuring means.

Paragraph 41. Apparatus in accordance with any one of Paragraphs 27 to 40, wherein the connector comprises an optical element for forming an optical connection to a corresponding optical element of a corresponding connector, the optical element being connected to the measuring means.

Paragraph 42. Apparatus in accordance with Paragraph 41, wherein the measuring means, in said measurement mode, is arranged to transmit an optical pulse from said optical element.

Paragraph 43. Apparatus in accordance with any one of Paragraphs 27 to 42, wherein the connector comprises a fluid connector for forming a fluid connection to a corresponding fluid connector of a corresponding connector, the fluid connector being connected to the measuring means.

Paragraph 44. Apparatus in accordance with Paragraph 43, wherein the measuring means, in said measurement mode, is arranged to apply pressure to fluid contained in the fluid connector.

Paragraph 47. Apparatus in accordance with Paragraph 28, or with any one of Paragraphs 29 to 44 as depending from Paragraph 28, wherein said triggering means comprises a light detector and is arranged to trigger the measuring means to operate in said measurement mode in response to detection of light by the light detector.

Paragraph 48. Apparatus in accordance with any one of Paragraphs 27 to 47, wherein the indicating means comprises a visual display.

Paragraph 50. Apparatus in accordance with any one of Paragraphs 27 to 48, comprising a rigid housing, the connector being rigidly coupled to said housing, and the measuring means being contained within said housing.

Paragraph 51. An assembly or subsea test apparatus in accordance with any preceding Paragraph, wherein the indicating means is arranged to provide said indication by means of at least one of: a visual display; optical, electrical, magnetic, electromagnetic or other physical signals; and a subsea mateable data connector.

Paragraph 52. A method of handling subsea apparatus having a connector for mating in a sea-water environment with a corresponding connector of other subsea apparatus to provide at least one of electrical, optical, and fluid connection between the two, the method comprising:
connecting subsea test apparatus to the subsea apparatus by mating a connector of the test apparatus to the connector of the subsea apparatus, the subsea test apparatus comprising a battery or fuel cell or other power source;
providing the subsea apparatus and connected test apparatus at a subsea location;
operating, at said subsea location, electrically powered measuring means of the test apparatus to perform at least one measurement on the connected subsea apparatus via the mated connectors, the operation of the measuring means being powered by the battery or fuel cell or other power source;
providing, with the test apparatus at said subsea location, an indication of a result of the or each measurement to an underwater vehicle or diver;

Paragraph 53. A method in accordance with Paragraph 52, further comprising triggering, at said subsea location, the measuring means to perform said at least one measurement.

Paragraph 58. A method in accordance with Paragraph 53, wherein said triggering comprises triggering the measuring means using a remotely operated vehicle (ROV) or diver.

Paragraph 59. A method in accordance with Paragraph 58, wherein said triggering comprises emitting light from a light source, and detecting the emitted light with a light detector provided on the test apparatus.

Paragraph 60. A method in accordance with any one of Paragraphs 52 to 59, wherein providing said indication comprises providing a visible indication using a visual display.

Paragraph 61. A method in accordance with Paragraph 60, further comprising viewing said visible indication using a camera of an ROV.

Paragraph 62. A method in accordance with any one of Paragraphs 52 to 61, wherein said disconnecting comprises pulling handle means (e.g. using an ROV).

Paragraph 63. A method in accordance with any one of Paragraphs 52 to 62, wherein said at least one measurement comprises an electrical impedance measurement.

Paragraph 64. A method in accordance with any one of Paragraphs 52 to 63, wherein said at least one measurement comprises a time domain reflectometry measurement.

Paragraph 65. A method in accordance with any one of Paragraphs 52 to 64, wherein said at least one measurement comprises a measurement of an attenuation of an electrical or optical signal.

Paragraph 66. A method in accordance with any one of Paragraphs 52 to 65, wherein said at least one measurement comprises a pressure measurement.

Paragraph 67. A method in accordance with any one of Paragraphs 52 to 66, comprising operating the connected test apparatus in a dormant mode until operating the measuring means to perform said at least one measurement, the dormant mode being a mode in which the measuring means is not performing any measurement on the attached apparatus.

Paragraph 68. A method in accordance with Paragraph 67, wherein said dormant mode further comprises isolating electrical contacts of the test apparatus connector from the test apparatus power supply.

Paragraph 69. A method in accordance with any one of Paragraphs 52 to 68, wherein said connecting by mating comprises forming at least one seal between the connector of the test apparatus and the connector of the subsea apparatus, the at least one seal preventing seawater from contacting at least one of an electrical connection, an optical connection, or a fluid connection between the connectors.

Paragraph 70. A method in accordance with any one of Paragraphs 52 to 69, wherein providing said indication comprises providing said indication by means of at least one of: a visual display; optical, electrical, magnetic, electromagnetic or other physical signals; and a subsea mateable data connector.

Paragraph 71. An assembly or subsea test apparatus in accordance with any preceding Paragraph, wherein the test or sequence of tests is automated in a pre-determined fashion. This automation is predetermined by a sequence of instructions stored within the apparatus.

Paragraph 72. An assembly or subsea test apparatus in accordance with any preceding Paragraph, wherein the results of any or all tests are stored within the apparatus for recall at a later time (e.g. later date).

Paragraph 73. An assembly or subsea test apparatus in accordance with any preceding Paragraph, wherein data regarding errors and/or influencing factors are stored along with the results of any tests to inform a later user as to the possible validity or corrections required of the test results.

1. Measurement apparatus for connection to an end of a cable (1) having at least one of: at least one electrically conductive core (11) for carrying electrical current and/or electrical signals along the cable; at least one electromagnetic waveguide (12) for carrying electromagnetic signals along the cable; and at least one bore (13) for conveying a fluid along the cable, the measurement apparatus comprising:
connection means (4) for connecting to said end in an above-water or out-of-water environment to make at least one of: at least one respective electrical connection (41) to at least one said core, at least one respective waveguide connection (42) to at least one said waveguide for sending an electromagnetic signal along the waveguide, and at least one respective fluid or hydraulic connection (43) to at least one said bore; and
measuring means (5) connected to the connection means and operable to perform at least one measurement, via the connection means, on a connected said cable,
wherein the measurement apparatus is deployable, when connected to an end of said cable, with said cable end to an underwater location for a period of time, and recoverable with said connected cable end after said period of time to an above-water or out-of-water location, and
wherein the measuring means is operable to perform said at least one measurement while the measurement apparatus is connected to said cable end and at least while submerged with said connected cable end and/or after recovery with said connected cable end from said underwater location to said above-water or out-of-water location.

2. Measurement apparatus in accordance with claim 1, wherein the connection means comprises at least one electrical connector for connection to a corresponding electrical connector terminating a said core.

3. Measurement apparatus in accordance with claim 2, wherein the connection means comprises a plurality of electrical connectors, each for connection to a corresponding connector terminating a respective said core.

4. Measurement apparatus in accordance with any preceding claim, wherein the connection means comprises at least one waveguide connector for connection to a corresponding waveguide connector terminating a said waveguide.

5. Measurement apparatus in accordance with claim 4, wherein the connection means comprises a plurality of waveguide connectors, each for connection to a corresponding waveguide connector terminating a respective said waveguide.

6. Measurement apparatus in accordance with any preceding claim, wherein the connection means comprises at least one fluid or hydraulic connector for connection to a corresponding fluid or hydraulic connector terminating a said bore (i.e. at the end of the cable).

7. Measurement apparatus in accordance with claim 6, wherein the connection means comprises a plurality of fluid or hydraulic connectors, each for connection to a corresponding fluid or hydraulic connector terminating a respective said bore.

8. Measurement apparatus in accordance with any preceding claim, further comprising attachment means (3) for mechanically attaching the measurement apparatus to the cable end.

9. Measurement apparatus in accordance with claim 8, wherein the attachment means comprises locking means for inhibiting mechanical detachment of the measurement apparatus from the cable end.

10. Measurement apparatus in accordance with claim 8 or claim 9, wherein the attachment means comprises at least one mechanical connector for connection to a corresponding mechanical connector provided at, or proximate, said cable end.

11. Measurement apparatus in accordance with any one of claims 8 to 10, wherein the attachment means comprises means for clamping or gripping at least one of: the cable end; a portion of the cable; an end portion of the cable; and at least one component of the cable.

12. Measurement apparatus in accordance with any one of claims 8 to 11, further comprising coupling means (6) for coupling to a means for providing a pulling force to enable a pulling force to be applied, via the measurement apparatus, to a said cable mechanically attached to the measurement apparatus.

13. Measurement apparatus in accordance with any preceding claim, further comprising sealing means arranged to form a seal between the measurement apparatus and said cable to inhibit ingress of water to at least one of: at least one said core (11); at least one said waveguide (12); and at least one said bore of a said cable having an end connected to the measurement apparatus.

14. Measurement apparatus in accordance with any preceding claim, wherein the connection means is adapted to provide a plurality of electrical connections to a respective plurality of electrically conductive cores of a connected said cable.

15. Measurement apparatus in accordance with claim 14, wherein said at least one measurement comprises measuring an electrical resistance between a respective pair of said cores.

16. Measurement apparatus in accordance with claim 14 or claim 15, wherein said at least one measurement comprises measuring an electrical capacitance between a respective pair of said cores.

17. Measurement apparatus in accordance with any preceding claim, comprising a terminal (e.g. electrode) arranged to make electric connection to a fluid in which the measurement apparatus is immersed.

18. Measurement apparatus in accordance with claim 17, wherein said at least one measurement comprises measuring an electrical resistance between a said core and said terminal.

19. Measurement apparatus in accordance with claim 17 or claim 18, wherein said at least one measurement comprises measuring an electrical capacitance between a said core and said terminal.

20. Measurement apparatus in accordance with any preceding claim, wherein said at least one measurement comprises measuring a continuity of at least one core, waveguide, or bore of a connected cable.

21. Measurement apparatus in accordance with any preceding claim, wherein said at least one measurement comprises a Time Domain Reflectometry (TDR) measurement on at least one core, waveguide, or bore of a connected cable.

22. Measurement apparatus in accordance with any preceding claim, wherein said at least one measurement comprises measuring temperature at least one position along a connected cable by means of a sending an electromagnetic signal along a said waveguide to interact with a respective temperature sensor (e.g. Bragg grating) at each said position.

23. Measurement apparatus in accordance with any preceding claim, wherein said at least one measurement comprises measuring strain at least one location along a connected cable by means of a sending an electromagnetic signal along a said waveguide to interact with a respective strain sensor (e.g. Bragg grating) at each said location.

24. Measurement apparatus in accordance with any preceding claim, wherein said at least one measurement comprises applying a pressure via a said fluid or hydraulic connection to a bore of a connected cable and measuring pressure of fluid within said bore.

25. Measurement apparatus in accordance with any preceding claim, wherein the measuring means is operable to perform said at least one measurement on a connected said cable while said cable is being pulled.

26. Measurement apparatus in accordance with any preceding claim, further comprising a memory, and the measurement apparatus is further arranged to store results of at least one said measurement, and optionally results of each said measurement, in the memory.

27. Measurement apparatus in accordance with any preceding claim, wherein the measuring means is arranged to monitor results of at least one said measurement, and optionally results of each said measurement, and generate an alert signal according to said results.

28. Measurement apparatus in accordance with claim 27, further comprising indicating means for indicating, at the measurement apparatus, generation of said alert signal, and/or further comprising means for transmitting said alert signal to a remote location.

29. Measurement apparatus in accordance with any preceding claim, further comprising data transmission means for transmitting results of at least one said measurement, and optionally results of each said measurement, to a remote location.

30. Measurement apparatus in accordance with any preceding claim, further comprising coupling means for coupling to a means for providing a pulling force to enable a pulling force to be applied, via the measurement apparatus, to a said cable connected to the measurement apparatus, the measurement apparatus further comprising at least one strain sensor arranged to sense at least one of a strain resulting from a pulling force applied to the coupling means and a strain resulting from a bending of the measurement apparatus or at least one component thereof, and wherein the measuring means is connected to the at least one strain sensor and is operable to perform at least one strain measurement of at least one of said strains.

31. Measurement apparatus in accordance with claim 30, wherein the measuring means is operable to perform said at least one strain measurement while the measurement apparatus is being pulled via the coupling means.

32. Measurement apparatus in accordance with claim 30 or claim 31, further comprising a memory and the measurement apparatus is further arranged to store results of at least one said strain measurement, and optionally results of each said strain measurement, in the memory.

33. Measurement apparatus in accordance with any one of claims 30 to 32, wherein the measuring means is arranged to monitor results of at least one said strain measurement, and optionally results of each said strain measurement, and generate a strain alert signal according to said strain measurement results.

34. Measurement apparatus in accordance with any one of claims 30 to 33, further comprising indicating means for indicating, at the measurement apparatus, generation of said strain alert signal, and/or further comprising means for transmitting said strain alert signal to a remote location.

35. Measurement apparatus in accordance with any one of claims 30 to 34, further comprising data transmission means for transmitting results of at least one said strain measurement, and optionally results of each said strain measurement, to a remote location.

36. Measurement apparatus in accordance with any preceding claim, further comprising a housing, the measuring means being housed inside said housing.

37. Measurement apparatus in accordance with claim 36, wherein at least a portion of said housing is flexible.

38. Measurement apparatus in accordance with claim 36 or claim 37, wherein at least a portion of said housing is rigid.

39. Measurement apparatus in accordance with claim 36, wherein said housing comprises a plurality of housing sections, the measuring means being housed inside at least one of said sections.

40. Measurement apparatus in accordance with claim 39, wherein at least one said housing section is flexible.

41. Measurement apparatus in accordance with claim 39 or claim 40, wherein at least one said housing section is rigid.

42. Measurement apparatus in accordance with any one of claims 39 to 41, further comprising at least one articulated connection connecting an adjacent pair of said housing sections.

42. Measurement apparatus in accordance with any one of claims 36 to 38, wherein said housing is waterproof, arranged to prevent water contacting the measuring means when the measurement apparatus is submerged (for example at a depth of 10 m, 100 m, 1000 m or more).

43. Measurement apparatus in accordance with any one of claims 39 to 42, wherein at least one of said housing sections is waterproof, arranged to prevent water contacting the measuring means when the measurement apparatus is submerged (for example at a depth of 10 m, 100 m, 1000 m or more).

44. Measurement apparatus in accordance with any one of claims 36 to 43, further comprising coupling means for coupling to a means for providing a pulling force to enable a pulling force to be applied, via the measurement apparatus, to a said cable connected to the measurement apparatus, wherein the coupling means is attached to said housing or said housing comprises the coupling means.

45. Measurement apparatus in accordance with any preceding claim, further comprising sealing means arranged to form a seal to a connected said cable to prevent or inhibit ingress of water into at least one component of a connected cable when submerged (for example at a depth of 10 m, 100 m, 1000 m or more).

46. Measurement apparatus in accordance with any preceding claim, further comprising energy storage means arranged to power the measuring means.

47. Measurement apparatus in accordance with any preceding claim, wherein the measuring means comprising a programmable processor, the processor being operable to control said measurements.

48. Measurement apparatus in accordance with claim 47, further comprising an input socket and/or a data receiver for receiving data to program said processor.

49. An assembly comprising measurement apparatus, in accordance with any preceding claim, attached to a said cable.

50. A pulling head assembly for attachment to, and pulling of, a cable having at least one of: at least one electrically conductive core for carrying electrical current along the cable; at least one electromagnetic waveguide for carrying electromagnetic signals along the cable; and at least one bore for conveying a fluid along the cable, the pulling head assembly comprising:
a pulling module comprising attachment means, for mechanically attaching the pulling head to the cable to enable a pulling force to be applied to the cable via the pulling head, and coupling means, for coupling to a means for providing a pulling force; and
measurement apparatus in accordance with any one of claims 1 to 48, for connection to an end of said cable.

51. A pulling head assembly in accordance with claim 50, wherein the pulling module comprises a housing, and the measurement apparatus is at least partly housed within the pulling module housing and/or is attached to the pulling head housing.

52. A method of handling a cable (1) having at least one of: at least one electrically conductive core (11) for carrying electrical current and/or electrical signals along the cable; at least one electromagnetic waveguide (12) for carrying electromagnetic signals along the cable; and at least one bore (13) for conveying a fluid along the cable, the method comprising:
providing a said cable having an end;
attaching measurement apparatus to said end in an above-water or out-of-water (e.g. dry) environment such that the measurement apparatus makes at least one of: at least one respective electrical connection to at least one said core; at least one respective connection to at least one said waveguide for sending an electromagnetic signal along the waveguide; and at least one respective fluid or hydraulic connection to at least one said bore;
deploying (e.g. laying) the cable such that said end, with the measurement apparatus attached, is submerged in water (i.e. is underwater) for a period of time;
after said period of time, recovering (e.g. pulling) said end and attached measurement apparatus to an above-water or out-of-water (e.g. dry) location; and
while the measurement apparatus is attached to said end, operating the measurement apparatus to perform at least one measurement on the attached cable.

53. A method in accordance with claim 52, wherein said providing comprises providing said cable at least partly on a reel (or spool).

54. A method in accordance with claim 52 or claim 53, and further comprising, before said attaching of the measurement apparatus, terminating said end with at least one of: at least one mechanical connector; at least one respective electrical connector attached to at least one said core; at least one respective waveguide connector attached to at least one said waveguide; and at least one respective fluid or hydraulic connector attached to at least one said bore, wherein attaching the measurement apparatus comprises connecting at least one of said connectors to a corresponding connector of the measurement apparatus.

55. A method in accordance with claim 54, wherein said terminating is performed in an above-water or out-of-water (e.g. dry) environment.

56. A method in accordance with claim 54 or claim 55, wherein said terminating comprises terminating said end with a mechanical connector, the measurement apparatus comprises a housing having a corresponding mechanical connector, and said attaching comprises connecting the mechanical connector of the cable to the mechanical connector of the housing.

57. A method in accordance with claim 56, wherein the housing further comprises coupling means (6) for coupling to a means for providing a pulling force, and at least one of said deploying and said recovering comprises applying a pulling force to said coupling means.

58. A method in accordance with any one of claims 52 to 55, wherein said attaching comprises clamping or gripping at least one of: the cable end; a portion of the cable; an end portion of the cable; and at least one component of the cable.

59. A method in accordance with claim 58, wherein the measurement apparatus further comprises coupling means (6) for coupling to a means for providing a pulling force, and at least one of said deploying and said recovering comprises applying a pulling force to said coupling means.

60. A method in accordance with any one of claims 52 to 59, wherein said attaching comprises forming a seal between the measurement apparatus and said cable to inhibit ingress of water to at least one of: at least one said core (11); at least one said waveguide (12); and at least one said bore.

61. A method in accordance with any one of claims 52 to 60, wherein said deploying comprises at least one of: unspooling; laying a length of said cable (e.g. underwater, such as on a sea bed); leaving or storing a length of said cable at a subsea location for a length of time; and pulling said cable.

62. A method in accordance with any one of claims 52 to 61, wherein said recovering comprises at least one of: pulling; lifting said end from a sub-sea location; pulling said end through a guide hole, guide element, or guide structure (e.g. a J-tube); and pulling said end onto a floating, anchored, fixed, or above-water vessel, structure or part thereof.

63. A method in accordance with any one of claims 52 to 62, wherein said operating comprises operating the measurement apparatus to perform at least one said measurement on the attached cable at at least one time before, during, and/or after said deploying, and/or before, during, and/or after said recovering.

64. A method in accordance with any one of claims 52 to 63, wherein said operating comprises operating the measurement apparatus at at least one sub-sea location to perform at least one said measurement on the attached cable.

65. A method in accordance with any one of claims 52 to 64, wherein the cable comprises a plurality of said cores, and said attaching is arranged such that the measurement apparatus makes a respective electrical connection to each said core.

66. A method in accordance with claim 65, wherein said at least one measurement comprises measuring an electrical resistance between a respective pair of said cores.

67. A method in accordance with claim 65 or claim 66, wherein said at least one measurement comprises measuring an electrical capacitance between a respective pair of said cores.

68. A method in accordance with any one of claims 52 to 67, wherein the measurement apparatus comprises a terminal (electrode) arranged to make electric connection to water when the measurement apparatus is submerged.

69. A method in accordance with claim 68, wherein said at least one measurement comprises measuring an electrical resistance between a said core and said terminal.

70. A method in accordance with claim 68 or claim 69, wherein said at least one measurement comprises measuring an electrical capacitance between a said core and said terminal.

71. A method in accordance with any one of claims 52 to 70, wherein said at least one measurement comprises measuring a continuity of at least one core, waveguide, or bore of the attached cable.

72. A method in accordance with any one of claims 52 to 71, wherein said at least one measurement comprises a Time Domain Reflectometry (TDR) measurement on at least one core, waveguide, or bore of the attached cable.

73. A method in accordance with any one of claims 52 to 72, wherein said at least one measurement comprises measuring temperature at least one position along the attached cable by means of a sending an electromagnetic signal along a said waveguide to interact with a respective temperature sensor (e.g. Bragg grating) at each said position.

74. A method in accordance with any one of claims 52 to 73, wherein said at least one measurement comprises measuring strain at least one location along the attached cable by means of a sending an electromagnetic signal along a said waveguide to interact with a respective strain sensor (e.g. Bragg grating) at each said location.

75. A method in accordance with any one of claims 52 to 74, wherein said at least one measurement comprises applying a pressure via a fluid or hydraulic connection to a bore of the attached said cable and measuring pressure of fluid within said bore.

76. A method in accordance with any one of claims 52 to 75, comprising operating the measurement apparatus to perform said at least one measurement on the attached cable while said cable is being pulled (e.g. via the coupling means).

77. A method in accordance with any one of claims 52 to 76, wherein the measurement apparatus comprises a memory, and the method further comprises storing results of at least one said measurement, and optionally results of each said measurement, in the memory.

78. A method in accordance with any one of claims 52 to 77, further comprising operating the measurement apparatus to monitor results of at least one said measurement, and optionally results of each said measurement, and generate an alert signal according to said results (e.g. if a result exceeds or falls below a predetermined threshold, or satisfies a predetermined criterion).

79. A method in accordance with claim 78, further comprising indicating, by the measurement apparatus, generation of said alert signal, and/or transmitting said alert signal to a remote location.

80. A method in accordance with any one of claims 52 to 79, further comprising transmitting results of at least one said measurement, and optionally results of each said measurement, to (or for reception at) a remote location.

81. A method in accordance with any one of claims 52 to 80, further comprising operating the measurement apparatus to measure at least one strain of the attached cable and/or at least one strain of the measurement apparatus during at least one of said deploying and said recovering.

82. A method in accordance with any one of claims 52 to 81, further comprising at least one of:
storing results of said at least one measurement in a memory (e.g. a memory of the measurement apparatus);
providing an indication of said results from the measurement apparatus (e.g. by means of a visible indicator of the measurement apparatus, to a nearby diver or ROV in a sub-sea location, or operator at a surface or above-water location)
transmitting results of said at least one measurement from the measurement apparatus for reception at a remote location; and
comparing (e.g. automatically, by the measurement apparatus) results of said at least one measurement with at least one criterion, and generating an alert signal depending on the results of said comparing.

83. A method in accordance with any one of claims 52 to 82, wherein said deploying comprises:
deploying said end of said cable with connected measurement apparatus to a sub-sea location and keeping said end of said cable with connected measurement in said location for said period of time;
and the method further comprises:
operating said measuring means to perform said at least one measurement on the attached cable at said location, after said period of time, before said recovering.

84. A method in accordance with any one of claims 52 to 83, wherein said performing of at least one measurement comprises performing a plurality of said measurements (e.g. at regular intervals).

85. A method in accordance with claim 84, wherein said plurality of measurements comprise a first plurality of measurements of strain and/or bending of the cable.

86. A method in accordance with claim 85, wherein said plurality of measurements comprise a second plurality of measurements, said second plurality of measurements being on parameters/characteristics other than strain or bending.

87. A method in accordance with any one of claims 52 to 86, further comprising performing measurements of strain and/or bending of the measurement apparatus.

88. A method in accordance with any one of claims 84 to 87, further comprising increasing a frequency of said plurality of measurements according to the results of said measurements of strain and/or bending of the cable and/or of the measurement apparatus.

89. A method in accordance with any one of claims 52 to 88, further comprising using the results of said measurements to determine whether or not to disconnect the measurement apparatus from said end and connect said end to further apparatus.

90. A method in accordance with any one of claims 52 to 89, wherein the measurement apparatus is a smart pulling head or a smart protective end cap.

91. A method in accordance with any one of claims 52 to 90, further comprising attaching a pulling head to the cable.

92. A method in accordance with claim 91, further comprising housing said measurement apparatus inside (e.g. inside a housing of) said pulling head.

93. A method in accordance with claim 91 or claim 92, further comprising attaching said pulling head to said measurement apparatus.
